(19) United States
(12) Patent Application Publication
(10) Pub. No.: US 2003/0014206 A1
(43) Pub. Date: Jan. 16, 2003

(54) In-circuit testing optimization generator

(75) Inventors: Emanuel Gorodetsky, Afula (IL); Eugeny Knupfer, Holon (IL)

Correspondence Address: Fogg, Slifer & Polglaze, P.A., P.O. Box 581009, Minneapolis, MN, 55458-1009, US

(73) Assignee: ADC Telecommunications Israel Ltd.

(21) Appl. No.: 09/878,513

(22) Filed: Jun. 11, 2001

(51) Int. Cl. G06F 19/00; G01R 27/28; G01R 31/00; G01R 31/14

(52) U.S. Cl. 702/118

(57) ABSTRACT

A method of generating optimized netlists is provided. The method includes providing an input mechanism that is adapted to receive selective test report files from one or more circuit board test generation software programs and adapted to receive in-circuit test restriction parameters. The method further includes generating netlists based on the received test report files and in-circuit test restriction parameters. The netlists comprise one or more of total number of nets for the board, number of nets that do not require in-circuit test pads, number of nets that possibly require in-circuit test pads, number of in-circuit test pads as test points and edge connector terminals, and number of nets that require in-circuit test pads.

### TECHNICAL FIELD

The present invention relates generally to the field of electronic board testing and, in particular, to improvements for in-circuit testing of electronic boards.

### BACKGROUND

In the design of electronic circuit boards, the circuit boards may be designed for in-circuit testing, boundary scan testing via dedicated test access port, on-board programming, and the like. Often these procedures are performed by implementing additional hardware on the boards such as in-circuit test pads, test points, edge connector terminals, dedicated pins, shift registers, test access ports and the like. The amount of hardware and the number of test points required for testing and on-board programming requires designers to make trade-offs in order to balance the amount of space used for this additional hardware.

Currently space on a circuit board is at a premium and designers are forced into optimizing the space on circuit boards to essential hardware. As a result, decisions as to which type of procedures to allot space to are becoming increasingly important. Providing for all the test sites needed for design and debug, structural testing, in-circuit testing, on-board programming production, and/or trouble shooting is often impracticable given the limited space on the board.

When designing a board there are many parameters to be taken into account. Some parameters are required for proper operation while other parameters only provide specific enhancements. In particular, test and design trade-offs are often made. With the increase of testing, on-board programming and fault location programs for circuit boards prioritizing space on the board for test pads and probing points to support these programs has become challenging. The parameters to take into account are multi-dimensional and range from in-circuit test (ICT) restrictions to designer restrictions. Because modern electronic boards are very densely populated, the need to maximize the space on the boards is imperative. Based on the number of restrictions, it is currently very difficult for a board designer to determine how to maximize real estate of a circuit board and to minimize the number of vias between layers.

For the reasons stated above, and for other reasons stated below which will become apparent to those skilled in the art upon reading and understanding the present specification, there is a need in the art for improvements in optimizing the space on electronic circuit boards.

### SUMMARY

The above-mentioned problems with in-circuit test optimization in electronic circuit boards and other problems are addressed by embodiments of the present invention and will be understood by reading and studying the following specification.

In one embodiment, a method of generating optimized netlists is provided. The method includes providing an input mechanism that is adapted to receive selective test report files from one or more circuit board test generation programs and adapted to receive in-circuit test restriction parameters. The method further includes generating netlists based on the received test report files and in-circuit test restriction parameters. The netlists comprise one or more of total number of nets for the board, number of nets that do not require in-circuit test pads, number of nets that possibly require in-circuit test pads, number of in-circuit test pads as test points and edge connector terminals, and number of nets that require in-circuit test pads.

### BRIEF DESCRIPTION OF THE DRAWINGS

FIG. 1 is an illustration of one embodiment of inputs to a netlist generator program according to the teachings of this invention.

FIG. 2 is an illustration of one embodiment of a main input screen for a netlist generator program, according to the teachings of the present invention.

FIG. 3 is an illustration of one embodiment of a customer add-ins screen for a nedist generator program, according to the teachings of the present invention.

### DETAILED DESCRIPTION

In the following detailed description, reference is made to the accompanying drawings that form a part hereof, and in which is shown by way of illustration specific illustrative embodiments in which the invention may be practiced. These embodiments are described in sufficient detail to enable those skilled in the art to practice the invention, and it is to be understood that other embodiments may be utilized and that logical, mechanical and electrical changes may be made without departing from the spirit and scope of the present invention. The following detailed description is, therefore, not to be taken in a limiting sense.

In a logic design, a conductive route from one source logic block or register to one destination logic block or register is called a connection. Frequently a signal generated at one source must be sent to several destinations. The collection of routes from one source to all destinations is called a net. Embodiments of the present invention provide a tool to determine how many of a particular board's nets require in-circuit test pads, particularly test points and edge connector through-hole terminals that can be used as in-circuit test pads, and how many of those nets do not require in-circuit test pads. In addition, embodiments of the present invention determine the number of nets that possibly require in-circuit test pads. This tool aids designers in making trade-offs between one or more parameters based on the number of acceptable in-circuit test pads with respect to existing or desired circuit board restrictions. The terms “boundary scan” and “Joint Test Action Group (JTAG)” are used here as synonyms.

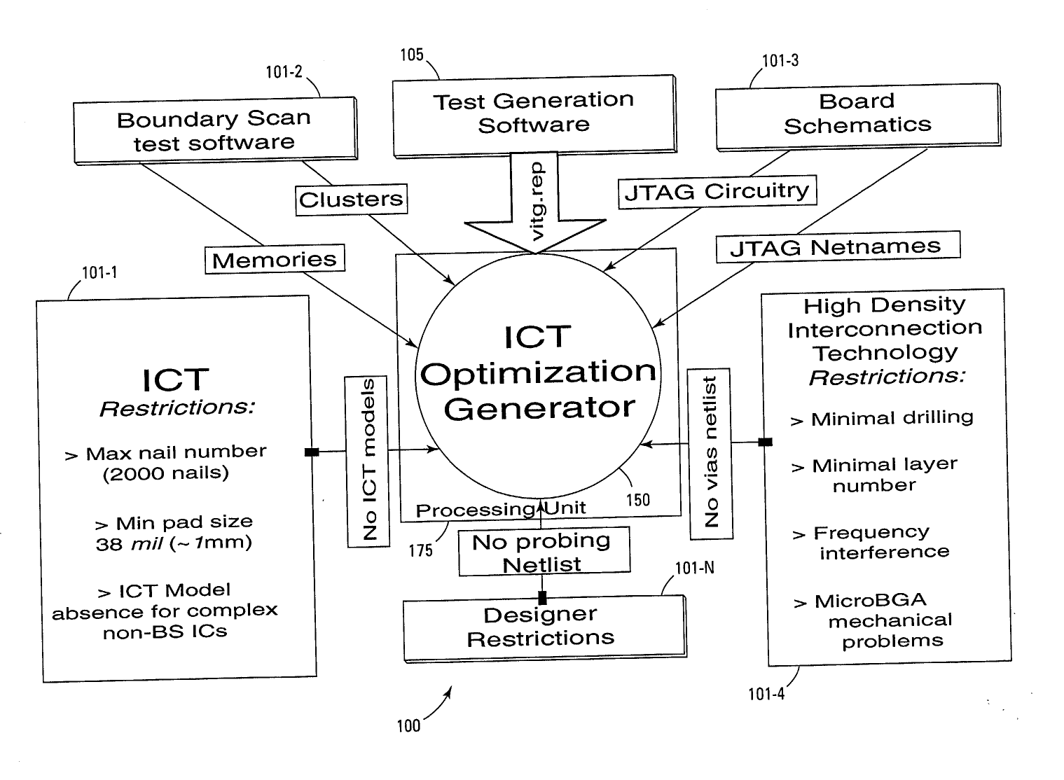

FIG. 1 is an illustration of inputs to an in-circuit test optimization generator shown generally at 100 and constructed according to the teachings of the present invention. The inputs include a number of customer add-ins 101-1 to 101-N and output data from one or more test generation software programs such as interconnect test generation program 105. Customer add-ins 101-1 to 101-N include a plurality of restriction categories such as in-circuit test restrictions 101-1, high-density interconnection technology (HDIT) restrictions 101-4, and designer restrictions 101-N. Any number of restrictions within restriction categories 101-1, 101-4, and 101-N is input into in-circuit test optimization generator 150. In addition, data such as board under test parameters is input to in-circuit test optimization generator 150 from boundary scan test software 101-2 and electronic circuit board schematics 101-3. Data input from boundary scan test software such as 101-2 includes names of clusters and/or memories tested in boundary scan cluster and memory tests, respectively. Further, data is input to in-circuit test optimization generator 150 from board schematics 101-3 such as JTAG circuitry and/or JTAG net names.

In one embodiment, in-circuit test optimization generator 150 operates on a computer-processing unit 175 having an associated storage medium such as a random access memory. In one embodiment, selective parameters of all of the inputs 101-1 to 101-N and 105 are stored in a database on the storage medium.

In one embodiment, in-circuit test restrictions 101-1 include but are not limited to a maximum number of nails (for example 2000 nails), a minimum in-circuit test pad size (for example 38 mil), and the absence of an in-circuit test Model for complex non-boundary scan integrated circuits. The in-circuit test restrictions 101-1 are prepared by test engineering staff in the form of “no in-circuit test models” list and designers can use this input to make trade-offs based on the number of acceptable in-circuit test pads with respect to existing board restrictions. The in-circuit test restrictions 101-1 are specific to each circuit board being optimized.

In one embodiment, High Density Interconnection Technology (HDIT) restrictions 101-4 include but are not limited to minimal drilling, minimal number of layers, frequency interference and micro ball grid array (MicroBGA) mechanical problems. The HDIT restrictions 101-4 are prepared by technology staff in the form of “No-vias netlist.” Designers can use this input to make trade-offs based on the number of acceptable in-circuit test pads with respect to existing board restrictions. The HDIT restrictions are specific to each circuit board being optimized.

In addition, designer restrictions 101-N are included based on the specific circuit board. The designer restrictions are prepared by the research and development staff in the form of “No-probing netlist.” Designers can use this input to make trade-offs based on the number of acceptable in-circuit test pads with respect to existing circuit restrictions. In many cases the designer will request no probing for a particular net or list of nets. One of the main reasons that a designer restricts one or more lines from in-circuit test probing is that the lines(s) should be antenna free. Each attempt to organize access via an in-circuit test pad to some wires (nets) creates a parasitic antenna. The Designer restrictions 101-N are specific to each circuit board being optimized.

In this embodiment, designer restrictions 101-N include a no probing netlist requirement, HDIT restrictions 101-4 include a no vias netlist requirement, and in-circuit test restrictions 101-1 include a non in-circuit test models list requirement.

In one embodiment, in-circuit test optimization generator 150 is adapted to receive information about an electronic circuit board's net level fault coverage data from interconnect test generation software 105. In one embodiment, the test generation software 105 is Teradyne Victory based test generation software. In one embodiment, in-circuit test optimization generator 150 receives information from interconnect test generation software programs 105 in the form of a net level fault coverage report (vitg.rep) file. The vitg.rep file is an ASCII-type file and is accessible from any Teradyne Victory based test generating software (such as Teradyne or ASSET InterTech test platforms) for input into the in-circuit test optimization generator 150. In this embodiment, the specific structure of the vitg.rep file is utilized. An example of one embodiment of a vitg.rep file is included below.

Boundary Scan Interconnect Test Fault Coverage Report

Created by VICTORY VITG V2.40.004 (Windows/DOS) at dd-mmm-yyyy 00:00:00 Current directory: D:\iAN_Proj\ADSL_c\iAN_AD6P\AD6P_master\InterConnect_without_(cont'd) : U9

Test step: vit

Inputs:

Command line: -activity -dlt -nopos -nopis -noisolated -noextra -nomixed Topology database read from:

Current directory

| Command line options: | |
|---|---|
| Parallel access: | none |
| Use multiple tester pins: | yes |
| Assume tristates disabled: | no |
| Target: | SVF |
| Pattern offset: | 0 |

The following is a description of the six different fault coverage classes and the types of faults each class is intended to detect.

Fault Coverage Class 1:

Opens will be detected on the networks listed in this fault class.

Shorts will be detected between the networks listed in this fault class and the networks listed in the following fault classes:

Fault Coverage Class 1

Fault Coverage Class 2

Fault Coverage Class 3

Fault Coverage Class 4

Fault Coverage Class 2:

Opens will be detected on the boundary-scan portion of the networks listed in this fault class, and also on some transparent series component leads.

Shorts will be detected between the networks listed in this fault class and the networks listed in the following fault classes:

Fault Coverage Class 1

Fault Coverage Class 2

Fault Coverage Class 3

Fault Coverage Class 4

Fault Coverage,Class 3:

No opens coverage on the networks listed in this fault class.

Shorts will be detected between the networks listed in this fault class and the networks listed in the following fault classes:

Fault Coverage Class 1

Fault Coverage Class 2

Fault Coverage Class 4:

Opens will be detected on the networks listed in this fault class only if they cause a boundary-scan input or tester pin to float to a logic state that is different from the network's constant state.

Shorts will be detected between the networks listed in this fault class and the networks listed in the following fault classes:

Fault Coverage Class 1

Fault Coverage Class 2

Fault Coverage Class 5:

No fault coverage on the networks listed in this fault class.

Fault Coverage Class 6:

The networks listed in this fault class are Test Access Port data and control networks. Fault coverage is provided on these networks by executing the Test Access Port Integrity Test (TAPIT).

General Notes:

The above discussion about opens coverage does not apply to any connector leads that might be on each net. Opens are not covered on any connector leads unless a tester pin is connected to that lead with a mating connector. Connector leads are listed in the net descriptions, however, and are marked with asterisks (*)

Shorts will not be detected between two networks of any class that are connected together with transparent series components.

Networks that are described as “resistively isolated” may not have the shorts detection described for their class above. This is because these networks are tested through transparent series components whose impedance might be high enough to isolate the effect of a short so that it causes no failure.

Opens coverage on pullups and pulldowns is described as “possible” because opens on these leads can be detected only if the affected inputs float to the complement of their pulled state.

All power nets are in classes 3 and 4.

Fault coverage class 1 nets (fully covered):

Net named ADP_CON0 with device lead U80_31.

Net named ADP_CON1 with device lead U80_32.

Net named ADP_CON2 with device lead U80_33.

Net named ADP_CON3 with device lead U80_56.

Net named AFEA_D0 with device lead U10_N16.

Net named AFEA_D1 with device lead U10_N19.

Net named AFEA_D2 with device lead U10_N18.

Net named AFEA_D3 with device lead U10_N15.

Net named AFEA_D4 with device lead U10_N14.

Net named AFEA_D5 with device lead U10_P19.

Net named AFEA_D6 with device lead U10_P16.

Net named AFEA_D7 with device lead U10_P15.

Net named AFEA_D8 with device lead U10_R18.

Net named AFEA_D9 with device lead U10_R19.

Net named AFEA_D10 with device lead U10_R16.

Net named AFEA_D11 with device lead U10_T18.

Net named AFEA_D12 with device lead U10_T19.

Net named AFEA_D13 with device lead U10_U18.

Net named AFEA_D14 with device lead U10_Ul9.

Net named AFEA_D15 with device lead U10_V19.

Net named AFEC_D0 with device lead U10_J15.

Net named AFEC_D1 with device lead U10_J16.

Net named AFEC_D2 with device lead U10_J18.

Net named AFEC_D3 with device lead U10_J14.

Net named AFEC_D4 with device lead U10_K15.

Net named AFEC_D5 with device lead U10_K16.

Net named AFEC_D6 with device lead U10_K18.

Net named AFEC_D7 with device lead U10_K19.

Net named AFEC_D8 with device lead U10_K14.

Net named AFEC_D9 with device lead U10_L14.

Net named AFEC_D10 with device lead U10_L18.

Net named AFEC_D11 with device lead U10_L19.

Net named AFEC_Dl2 with device lead U10_L16.

Net named AFEC_D13 with device lead U10_M15.

Net named AFEC_D14 with device lead U10_M16.

Net named AFEC_D15 with device lead U10_M18.

Net named AME with device leads U8_A5 and U10_C19.

Net named AREMINUS_1134006 with device leads U8_V24 and U10_T2.

Net named ASPWRN with device leads U46_H23 and U80_19.

Net named AWEMINUS with device leads U8_U23 and U10_R4.

Net named BASPRDN with device leads U46_G26 and U80_20.

Net named BASP_RST with device leads U46_C4 and U80_90.

Net named CS4 with device leads J16_78 (*) and U80_7.

Net named CLKS1 with device leads R507_1 and U8_G1.

Net named DEBUG with device leads R507_2 and U8_F1.

Net named CLKS1_1088260 with device leads R494_1 and U7_G1.

Net named DIN with device lead U80_72.

Net named DSP_INT with device leads U8_W4 and U10_A5.

Net named EA2_1133972 with device leads U8_V26 and U10_R2.

Net named EA3 with device leads U8_T23 and U10_R1.

Net named EA4_1133969 with device leads U8_U25 and U10_P4.

Net named EA5 with device leads U8_T24 and U10_P2.

Net named EA6_1133966 with device leads U8_T25 and U10_N2.

Net named EA7_1133983 with device leads U8_R23 and U10_N4.

Net named EA8_1133938 with device leads U8_R24 and U10_N1.

Net named EA9_1134056 with device leads U8_R25 and U10_M2.

Net named EA10_1134001 with device leads U8_P23 and U10_M4.

Net named EA11 with device leads U8—P24 and U10_L1.

Net named EA12 with device leads U8_N23 and U10_L4.

Net named EA13_1134025 with device leads U8_M25 and U10_L2.

Net named EA14_1133997 with device leads U8_M24 and U10_K1.

Net named EA15 with device leads U8_M23 and U10_K4.

Net named ED0_1133996 with device leads U8_AF21 and U10_V5.

Net named ED1_1134069 with device leads U8_AD19 and U10_T6.

Net named ED2_1133995 with device leads U8_AC18 and U10_V6.

Net named ED3 with device leads U8_AF20 and U10_W6.

Net named ED4_1133984 with device leads U8_AD18 and U10_T7.

Net named ED5_1133947 with device leads U8_AC17 and U10_V7.

Net named ED6_1133956 with device leads U8_AE18 and U10_W8.

Net named ED7_1134070 with device leads U8_AF18 and U10_T8.

Net named ED8_1134003 with device leads U8_AC16 and U10_V8.

Net named ED9_1133934 with device leads U8_AE17 and U10_V9.

Net named ED10_with device leads U8_AD16 and U10_T9.

Net named ED11_1133970 with device leads U8_AE16 and U10_W10.

Net named ED12 with device leads U8_AC15 and U10_T10.

Net named ED13_1134011 with device leads U8_AD15 and U10_V10.

Net named ED14 with device leads U8_AE15 and U10_V11.

Net named ED15_1133994 with device leads U8_AC14 and U10_T11.

Net named ED16 with device leads U8_AD14 and U10_W11.

Net named ED17 with device leads U8_AC13 and U10_T12.

Net named ED18 with device leads U8_AE12 and U10_V12.

Net named ED19_1134007 with device leads U8_AD12 and U10_{—V13.}

Net named ED20 with device leads U8_AC12 and U10_T13.

Net named ED21 with device leads U8_AE11 and U10_W13.

Net named ED22_1134009 with device leads U8_AD11 and U10_T14.

Net named ED23 with device leads U8_AE10 and U10_V14.

Net named ED24_1134012 with device leads U8_AC11 and U10_V5.

Net named ED25 with device leads U8_AF9 and U10_T15.

Net named ED26 with device leads U8_AE9 and U10_W15.

Net named ED27 with device leads U8_AC10 and U10_V16.

Net named ED28 with device leads U8_AD9 and U10_T16.

Net named ED29 with device leads U8_AF7 and U10_W17.

Net named ED30 with device leads U8_AC9 and U10_V17.

Net named ED31_1133982 with device leads U8_AD8 and U10_W18.

Net named FSX1_1088251 with device lead U7_K4.

Net named FSX1 with device lead U8_K4.

Net named IRQ5 with device leads J16_96 (*) and U80_71.

Net named IRQ6 with device leads J16_92 (*) and U80_69.

Net named IRQ7 with device leads J16_90 (*) and U80_67.

Net named MDMCSN_A with device leads U10_H1 and U80_87.

Net named MDMRDY_A with device leads U10_L5 and U80_98.

Net named AOE with device leads R652_1 and U8_V25.

Net named N3591861_1084199 with device leads R652_2 and U10_N6.

Net named ARDY_1134000 with device leads R664_1 and U8_W25.

Net named N3672092_1133907 with device leads R664_2 and U10_P13.

Net named NO_IN_A with device lead U80_96.

Net named NO_IN_B with device lead U80_95.

Net named POTS_CON0 with device lead U80_54.

Net named POTS_CON2 with device lead U80_28.

Net named POTS_CON3 with device lead U80_58.

Net named POTS_CON4 with device lead U80_79.

Net named CEOMINUS_1133952 with device leads R661_1 and U8_AA25.

Net named QCEMINUS_1133904 with device leads R661_2 and U10_U1.

Net named RWN with device leads J16_82 (*) and U80_3.

Net named XBEO_1133961 with device leads U8_C8 and U10_D16.

Net named XBE1_with device leads U8_A6 and U10_A18.

Net named XBE2_1133993 with device leads U8_D8 and U10_B18.

Net named XBE3_1133999 with device leads U8_C7 and U10_D18.

Net named XCNTL_WE_1133977 with device leads U8_B10 and U10_B14.

Net named XCS_DSPMINUS_1133963 with device leads U8_A10 and U10_D14.

Net named XD0_1133990 with device leads U8_K23 and U10_G1.

Net named XD1_1133979 with device leads U8_J24 and U10_G2.

Net named XD2_1133946 with device leads U8_H25 and U10_G4.

Net named XD3 with device leads U8_G26 and U10_E1.

Net named XD4_1133949 with device leads U8_J23 and U10_F2.

Net named XD5_1133980 with device leads U8_G25 and U10_F4.

Net named XD6_1133991 with device leads U8_F26 and U10_D1.

Net named XD7_1134002 with device leads U8_H23 and U10_E2.

Net named XD8_1133958 with device leads U8_G24 and U10_E4.

Net named XD9_1134029 with device leads U8_F25 and U10_D2.

Net named XD10 with device leads U8_E26 and U10_B1.

Net named XD11_1134017 with device leads U8_F24 and U10_B3.

Net named XD12 with device leads U8_E25 and U10_C2.

Net named XD13_1133965 with device leads U8_B22 and U10_A2.

Net named XD14_1133960 with device leads U8_D20 and U10_A3.

Net named XD15_1133940 with device leads U8_A22 and U10_D4.

Net named XD16_1133950 with device leads U8_B21 and U10_B4.

Net named XD17 with device leads U8_C20 and U10_D5.

Net named XD18 with device leads U8_D19 and U10_A4.

Net named XD19 with device leads U8_A21 and U10_B5.

Net named XD20_1134005 with device leads U8_C19 and U10_D6.

Net named XD21_1134013 with device leads U8_D18 and U10_B6.

Net named XD22 with device leads U8_A20 and U10_A6.

Net named XD23_1134015 with device leads U8_C18 and U10_D7.

Net named XD24_1133992 with device leads U8_D17 and U10_B7.

Net named XD25_1133975 with device leads U8_B18 and U10_A8.

Net named XD26_1134062 with device leads U8_A18 and U10_D8.

Net named XD27 with device leads U8_D16 and U10_P8.

Net named XD28 with device leads U8_B17 and U10_A9.

Net named XD29 with device leads U8_A17 and U10_B9.

Net named XD30_1134066 with device leads U8_B16 and U10_A10.

Net named XD31 with device leads U8_D15 and U10_D10.

Net named XWR OE_1133988 with device leads U8_D11 and U10_B15.

Unconnected device lead U7_L25.

Unconnected device lead U7_L24.

Unconnected device lead U7_K25.

Unconnected device lead U7_L23.

Unconnected device lead U7_J26.

Unconnected device lead U7_J25.

Unconnected device lead U7_T2.

Unconnected device lead U7_R4.

Unconnected device lead U8_L25.

Unconnected device lead U8_L24.

Unconnected device lead U8_K25.

Unconnected device lead U8_L23.

Unconnected device lead U8_J26.

Unconnected device lead U8_J25.

Unconnected device lead U8_T2.

Unconnected device lead U8_R4.

Unconnected device lead U80_30.

Fault coverage class 2 nets (partially covered):

Net named AFE_SCLK_1086441:

Faults covered on device leads U7_M2 and U7_M3.

No opens coverage on device lead R475_1.

Net named AFE_SCLK:

Faults covered on device leads U8_M2 and U8_M3.

No opens coverage on device lead R480_1.

Net named AFE_FS:

Faults covered on device leads U8_N3 and U8_N4.

No opens coverage on device leads R467_2, R469_2, and R471_2.

Net named AFE_FS_1086418:

Faults covered on device leads U7_N3 and U7_N4.

No opens coverage on device leads R461_2, R463_2, and R465_2.

Net named BASP_CS:

Faults covered on device leads U46_G25 and U80_29.

Possible opens coverage on pullup device lead R293_2.

Net named BASP_INT:

Faults covered on device leads U46_F25 and U80_14.

Possible opens coverage on pullup device lead R294_2.

Net named BASP_RDY:

Faults covered on device leads U46_H24 and U80_13.

Possible opens coverage on pullup device lead R292_2.

Net named CLKR1:

Faults covered on device leads U7_J3 and U7_H2.

Possible opens coverage on pullup device lead R491_1.

Net named CLKR1_1133953:

Faults covered on device leads U8_J3 and U8_H2.

Possible opens coverage on pullup device lead R504_1.

Net named CS5:

Faults covered on device lead U80_8.

No opens coverage on device leads J16_76 (*) and U4_1.

Net named CS6:

Faults covered on device lead U80_9.

No opens coverage on device leads J16_72 (*) and U4_2.

Net named CS7:

Faults covered on device lead U80_10.

No opens coverage on device leads J16_70 (*) and R150_2.

Net named CS_ID:

Faults covered on device lead U80_18.

Possible opens coverage on pullup device lead RN10_2.

Net named CS_TYPE:

Faults covered on device lead U80_17.

Possible opens coverage on pullup device lead RN10_1.

Net named DEBUG_1088466:

Faults covered on device leads R494_2 and U7_F1.

Possible opens coverage on pullup device lead R495_1.

Net named DR1_1088233:

Faults covered on device leads U7_J2 and U7_L4.

Possible opens coverage on pullup device lead R490_1.

Net named DR1:

Faults covered on device leads U8_J2 and U8_L4.

Possible opens coverage on pullup device lead R503_1.

Net named DSP_RSTMINUS:

Faults covered on device leads U8_K2 and U10_B2.

No opens coverage on device lead R651_2.

Net named EA2:

Faults covered on device lead U7_V26.

No opens coverage on device lead U9—R2.

Net named EA3_1088335:

Faults covered on device lead U7_T23.

No opens coverage on device lead U9_R1.

Net named EA4:

Faults covered on device lead U7_U25.

No opens coverage on device lead U9_P4.

Net named EA5_1088330:

Faults covered on device lead U7_T24.

No opens coverage on device lead U9_P2.

Net named EA6:

Faults covered on device lead U7_T25.

No opens coverage on device lead U9_N2.

Net named EA7:

Faults covered on device lead U7_R23.

No opens coverage on device lead U9_N4.

Net named EA8:

Faults covered on device lead U7_R24.

No opens coverage on device lead U9_N1.

Net named EA9:

Faults covered on device lead U7_R25.

No opens coverage on device lead U9_M2.

Net named EA10:

Faults covered on device lead U7_P23.

No opens coverage on device lead U9_M4.

Net named EA11_1088334:

Faults covered on device lead U7_P24.

No opens coverage on device lead U9_L1.

Net named EA12_1088371:

Faults covered on device lead U7_N23.

No opens coverage on device lead U9_L4.

Net named EA13:

Faults covered on device lead U7_M25.

No opens coverage on device lead U9_L2.

Net named EA14:

Faults covered on device lead U7_M24.

No opens coverage on device lead U9_K1.

Net named EA15_1088393:

Faults covered on device lead U7_M23.

No opens coverage on device lead U9_K4.

Net named FSR2_1088298:

Faults covered on device lead U7_U2.

Possible opens coverage on pullup device lead R484_1.

Net named FSR2:

Faults covered on device lead UB_U2.

Possible opens coverage on pullup device lead R498_1.

Net named FSX2:

Faults covered on device lead U7_T3.

Possible opens coverage on pulldown device lead R576_1.

Net named FSX2_1133945:

Faults covered on device lead U8_T3.

Possible opens coverage on pulldown device lead R578_1.

Net named GL_RESET:

Faults covered on device lead U80_62.

Possible opens coverage on pullup device lead R674_1.

No opens coverage on device lead J16_25 (*).

Net named GPIO2_1133887:

Faults covered on device lead U10_R9.

Possible opens coverage on pullup device lead R604_2.

Net named GPIO3:

Faults covered on device lead U10_P9.

Possible opens coverage on pullup device lead R621_2.

Net named HDLC_EN1:

Faults covered on device lead U80_81.

Possible opens coverage on pullup device lead R212_2.

No opens coverage on device leads U57_5, U58_1, and U58_10.

Net named HDLC_EN2:

Faults covered on device lead U80_78.

Possible opens coverage on pullup device lead R213_2.

No opens coverage on device leads U57_12, U58_4, and U58_13.

Net named M1:

Faults covered on device lead U80_22.

Possible opens coverage on pullup device lead R47_1.

Net named M1PDWN:

Faults covered on device leads U10_P14 and U80_83.

Possible opens coverage on pulldown device lead R557_1.

Net named M2PDWN:

Faults covered on device lead U80_82.

Possible opens coverage on pulldown device lead R552_1.

No opens coverage on device lead U9_P14.

Net named MDMCSN_B:

Faults covered on device lead U80_99.

No opens coverage on device lead U9_H1.

Net named MDMRDN:

Faults covered on device leads U10_G6 and U80_84.

No opens coverage on device lead U9_G6.

Net named MDMRS:

Faults covered on device leads U10_H2 and U80_85.

No opens coverage on device lead U9_H2.

Net named MDMWTN:

Faults covered on device leads U10_H5 and U80_86.

No opens coverage on device lead U9_H5.

Net named MPSIN_A:

Faults covered on device leads U10_GS and U80_15.

Possible opens coverage on pullup device lead RN10_3.

Net named N716152:

Faults covered on device lead U80_94.

No opens coverage on device lead R30_2.

Net named CPU_CLK:

Faults covered on device lead U80_2.

No opens coverage on device lead R154_1.

Net named N2298762_1133862:

Faults covered on device lead U10_R8.

Possible opens coverage on pullup device lead R602_2.

Net named N3786297:

Faults covered on device lead U80_73.

No opens coverage on device lead R20_1.

Net named PP53:

Faults covered on device lead U46_323.

Possible opens coverage on pullup device lead RN46_5.

Net named SELB:

Faults covered on device lead U80_93.

Possible opens coverage on pullup device lead RN22_5.

Net named TXDATA0:

Faults covered on device leads U10_F19 and U46_M24.

No opens coverage on device lead U9_F19.

Net named TXDATA1:

Faults covered on device leads U10_F18 and U46_L25.

No opens coverage on device lead U9_F18.

Net named TXDATA2:

Faults covered on device leads U10_F16 and U46_M26.

No opens coverage on device lead U9_F16.

Net named TXDATA3:

Faults covered on device leads U10_F15 and U46_N24.

No opens coverage on device lead U9_F15.

Net named TXDATA4:

Faults covered on device leads U10_E19 and U46_M25.

No opens coverage on device lead U9_E19.

Net named TXDATA5:

Faults covered on device leads U10_E18 and U46_P24.

No opens coverage on device lead U9_E18.

Net named TXDATA6:

Faults covered on device leads U10_E16 and U46_N26.

No opens coverage on device lead U9_E16.

Net named TXDATA7:

Faults covered on device leads U10₋D19 and U46_N23.

No opens coverage on device lead U9_D19.

Net named XHOLD:

Faults covered on device lead U8_B5.

Possible opens coverage on pulldown device lead R544_2.

Net named XHOLDA:

Faults covered on device lead U8_D7.

Possible opens coverage on pulldown device lead R567_2.

Net named XHOLDA_1088296:

Faults covered on device lead U7_D7.

Possible opens coverage on pulldown device lead R550_2.

Net named XHOLD_1088240:

Faults covered on device lead U7_B5.

Possible opens coverage on pulldown device lead R542_2.

Net named XRDYMINUS:

Faults covered on device lead U7_A5.

No opens coverage on device lead U9_C19.

Fault coverage class 3 nets (shorts covered):

Resistively isolated net named 37 with device lead R475_2.

Resistively isolated net named 37_1085247 with device lead R480_2.

Net named N2521228 with device leads R531_1 and U10_H14.

Resistively isolated net named AFE_CSAN with device lead R531_2.

Net named N2521240 with device leads R524_1 and U10_H19.

Resistively isolated net named AFE_CSBN with device lead R524_2.

Net named N2521252 with device leads R562_1 and U10_R13.

Resistively isolated net named AFE_CSCN with device lead R562_2.

Resistively isolated net named 38_1085250 with device lead R471_1.

Resistively isolated net named 38_1085626 with device lead R467_1.

Resistively isolated net named 38_1084785 with device lead R469_1.

Resistively isolated net named 38_1089228 with device lead R463_1.

Resistively isolated net named 38_with device lead R465_1.

Resistively isolated net named 38_1087004 with device lead R461_1.

Net named AFEOEMINUS_1084193 with device leads R525_1, R526_1, R527_1, and U10_H16.

Resistively isolated net named AFE_OECN with device lead R525_2.

Resistively isolated net named AFE_OEAN with device lead R526_2.

Resistively isolated net named AFE_OEBN with device lead R527_2.

Resistively isolated net named 36_1084727 with device lead R468_1.

Resistively isolated net named 36_with device lead R466_1.

Resistively isolated net named 36_1085248 with device lead R470_1.

Net named AFE_SDI with device leads R466_2, R468_2, R470_2, R558_2, and U8_P4.

Resistively isolated net named 36_1086999 with device lead R460_1.

Resistively isolated net named 36_1087358 with device lead R464_1.

Resistively isolated net named 36_1089235 with device lead R462_1.

Net named AFE_SDI_1086414 with device leads R460_2, R462_2, R464_2, R553_2, and U7_P4.

Resistively isolated net named 35_1084773 with device lead R478_1.

Resistively isolated net named 35_1085234 with device lead R479_1.

Resistively isolated net named 35 with device lead R476_1.

Resistively isolated net named 35_1089219 with device lead R473_1.

Resistively isolated net named 35_1087360 with device lead R474_1.

Resistively isolated net named 35_1086977 with device lead R472_1.

Net named AFESYNC_1084201 with device leads R528_1, R529_1, R530_1, and U10_M19.

Resistively isolated net named AFE_SYNCC with device lead R528_2.

Resistively isolated net named AFE_SYNCB with device lead R529_2.

Resistively isolated net named AFE_SYNCA with device lead R530_2.

Resistively isolated net named AFE_TEST with device lead R456_1.

Resistively isolated net named AFE_TEST_1082376 with device lead R457_1.

Net named AFEWRN_1084191 with device leads R521_1, R522_1, R523_1, and U10_H15.

Resistively isolated net named AFE_WRBN with device lead R521_2.

Resistively isolated net named AFE_WRCN with device lead R522_2.

Resistively isolated net named AFE_WRAN with device lead R523_2.

Net named AREMINUS with device leads U7_V24 and U9_T2.

Net named AWEMINUS_1088322 with device leads U7_U23 and U9_R4.

Resistively isolated net named BB_33 with device leads R196_1 and R204_1.

Resistively isolated net named BB with device leads R204_2 and U49_6.

Net named BB2D0 with device leads RN11_1 and U46_G23.

Net named BB2D1 with device leads RN11_2 and U46_F26.

Net named BB2D10 with device leads RN12_3 and U46_C25.

Net named BB2D11 with device leads RN12_4 and U46_D24.

Net named BB2D12 with device leads RN12_5 and U46_C26.

Net named BB2D13 with device leads RN12_6 and U46_A25.

Net named BB2D14 with device leads RN12_7 and U46_B24.

Net named BB2D15 with device leads RN12_8 and U46_A24.

Net named BB2D2 with device leads RN11_3 and U46_G24.

Net named BB2D3 with device leads RN11_4 and U46_E25.

Net named BB2D4 with device leads RN11_5 and U46_E26.

Net named BB2D5 with device leads RN11_6 and U46_F24.

Net named BB2D6 with device leads RN11_7 and U46_D25.

Net named BB2D7 with device leads RN11_8 and U46_E23.

Net named BB2D8 with device leads RN12_1 and U46_D26.

Net named BB2D9 with device leads RN12_2 and U46_E24.

Resistively isolated net named BD0 with device leads J17_95 (*), RN18_8, RN30_5, and RN39_1.

Resistively isolated net named BD1 with device leads J17_91 (*), RN18_7, RN30_6, and RN39_2.

Resistively isolated net named BD2 with device leads J17_89 (*), RN18_6, RN30_7, and RN39_3.

Resistively isolated net named BD3 with device leads J17_87 (*), RN18_5, RN30_8, and RN39_4.

Resistively isolated net named BD4 with device leads J17_85 (*), RN19_8, RN33_5, and RN39_5.

Resistively isolated net named BD5 with device leads J17_81 (*), RN19_7, RN33_6, and RN39_6.

Resistively isolated net named BD6 with device leads J17_79 (*), RN19_6, RN33_7, and RN39_7.

Resistively isolated net named BD7 with device leads J17_77 (*), RN19_5, RN33_8, and RN39_8.

Resistively isolated net named BD8 with device leads J17_75 (*), RN32_1, and RN34_5.

Resistively isolated net named BD9 with device leads J17_71 (*), RN32_2, and RN34_6.

Resistively isolated net named BD10 with device leads J17_69 (*), RN32_3, and RN34_7.

Resistively isolated net named BD11 with device leads J17_67 (*), RN32_4, and RN34_8.

Resistively isolated net named BD12 with device leads J17_65 (*), RN32_5, and RN41_5.

Resistively isolated net named BD13 with device leads J17_61 (*), RN32_6, and RN41_6.

Resistively isolated net named BD14 with device leads J17_59 (*), RN32_7, and RN41_7.

Resistively isolated net named BD15 with device leads J17_57 (*), RN32_8, and RN41_8.

Resistively isolated net named C3_1074547 with device lead R3618_2.

Resistively isolated net named C3_1073401 with device lead R3418_2.

Resistively isolated net named C3 with device lead R3118_2.

Resistively isolated net named C3_1075120 with device lead R3518_2.

Resistively isolated net named C3_1073970 with device lead R3318_2.

Resistively isolated net named C3_1105681 with device lead R3218_2.

Net named CLKOUT1_1133935 with device lead U8_AD20.

Net named CLKOUT1 with device lead U7_AD20.

Net named CLKOUT2_1133973 with device lead U8_AC19.

Net named CLKOUT2 with device lead U7_AC19.

Resistively isolated net named CLKSEL with device leads R571_1 and U9_P12.

Resistively isolated net named N565961 with device lead R150_1.

Resistively isolated net named DIV with device lead RN22_6.

Resistively isolated net named DP0 with device leads R171_2 and U84_1.

Resistively isolated net named DP1 with device leads R165_2 and U84_30.

Resistively isolated net named DP2 with device leads R162_2 and U84_51.

Resistively isolated net named DP3 with device leads R172_2 and U84_80.

Resistively isolated net named DPU0 with device leads R259_2 and U69_1.

Resistively isolated net named DPU1 with device leads R274_2 and U69_30.

Resistively isolated net named DPU2 with device leads R278_2 and U69_51.

Resistively isolated net named DPU3 with device leads R261_2 and U69_80.

Resistively isolated net named DR with device leads R3207_T and R3209_1.

Resistively isolated net named DR_1073423 with device leads R3407_1 and R3409_1.

Resistively isolated net named DR_1073982 with device leads R3307_1 and R3309_1.

Resistively isolated net named DR_1074574 with device leads R3607_1 and R3609_1.

Resistively isolated net named DR_1075112 with device leads R3507_1 and R3509_1.

Resistively isolated net named DR_1127486 with device leads R3107_1 and R3109_1.

Resistively isolated net named N_2571378 with device lead R651_1.

Resistively isolated net named DT with device leads R3601_1 and R3603_2.

Resistively isolated net named DT_1073383 with device leads R3401_1 and R3403_2.

Resistively isolated net named DT_1073988 with device leads R3301_1 and FR3303_2.

Resistively isolated net named DT_1075125 with device leads R3501_1 and R3503_2.

Resistively isolated net named DT_1105716 with device leads R3201_1 and R3203_2.

Resistively isolated net named DT_1127462 with device leads R3101_1 and R3103_2.

Net named DX1 with device lead U7_J1.

Net named DX1_1133948 with devicelead U8_J1.

Net named GPIO4_1133876 with device leads R594_2 and U10_R10.

Resistively isolated net named HDLC1 with device leads J16_133 (*), R659_1, and U57_1.

Resistively isolated net named HDLC2 with device leads J16_117 (*), R658_1, and U57_2.

Resistively isolated net named IIC_CK with device leads J16_99 (*) and R638_1.

Resistively isolated net named IIC_SDA with device leads J16_97 (*) and R637_1.

Resistively isolated net named INT_BP with device leads R672_1, U56_12, and U56_13.

Resistively isolated net named J1_24 with device leads J17_24 (*), R316_2, U38_3, and U39_4.

Net named MINUS48V_RET with device leads R218_1 and R219_1.

Resistively isolated net named MOT_MODE_1088429 with device leads R653_2 and U9_26.

Resistively isolated net named N00263 with device leads R401_1 and R402_1.

Resistively isolated net named N00269 with device leads R434_2, R435_1, and R438_2.

Resistively isolated net named N00441 with device lead R452_1.

Resistively isolated net named N15724 with device lead R217_2.

Resistively isolated net named N15740 with device lead R215_2.

Resistively isolated net named N27684 with device leads R4875_2 and R4879_2.

Resistively isolated net named N29940 with device lead R686_1.

Resistively isolated net named N47697 with device leads R439_2 and R441_1.

Resistively isolated net named N421421 with device lead R11_1.

Resistively isolated net named N422166 with device lead R8_1.

Resistively isolated net named N422172 with device lead R10_1.

Resistively isolated net named N447278 with device leads R137_1, U79_1, U79_24, U79_25, and U79_48.

Resistively isolated net named N452640 with device leads R372_1 and U30_12.

Resistively isolated net named N457455 with device lead R232_2.

Resistively isolated net named N457485 with device lead R231_2.

Resistively isolated net named N493143_1105619 with device lead R3245_2.

Resistively isolated net named N493143_1074489 with device lead R3645_2.

Resistively isolated net named N493143 with device lead R3445_2.

Resistively isolated net named N494007 with device leads R158_2 and U47_52.

Resistively isolated net named N552553 with device lead R251_2.

Resistively isolated net named N560212 with device lead R236_2.

Resistively isolated net named N578566 with device leads R164_1 and U84_49.

Resistively isolated net named N635156 with device leads R538_2 and U14_9.

Resistively isolated net named N642853 with device leads R166_2 and U84_14.

Resistively isolated net named N653192_1074463 with device lead R3644_2.

Resistively isolated net named N653192 with device lead R3444_2.

Resistively isolated net named N662056 with device leads R619_2 and U11_9.

Resistively isolated net named N669381 with device leads R4873_2 and R4877_2.

Resistively isolated net named N669388 with device leads R4874_2 and R4878_2.

Resistively isolated net named N669402 with device leads R4876_2 and R4880_2.

Resistively isolated net named N684612 with device lead R3244_2.

Resistively isolated net named N686620 with device leads R4881_2 and R4883_2.

Resistively isolated net named N686624 with device leads R4882_2 and R4884_2.

Resistively isolated net named N704220 with device lead R86_2.

Resistively isolated net named N714812 with device lead R295_1.

Resistively isolated net named N714826 with device lead R284_1.

Resistively isolated net named N714840 with device lead R296_1.

Resistively isolated net named N715263 with device lead R286_2.

Resistively isolated net named TA with device leads R30_1 and R298_2.

Resistively isolated net named N718234 with device lead R297_2.

Resistively isolated net named N718242 with device lead R287_2.

Resistively isolated net named N725047 with device leads J17_13 (*) and R154_2.

Resistively isolated net named N733172 with device lead R307_2.

Resistively isolated net named N733263 with device lead R308_2.

Resistively isolated net named N743892 with device leads R202_1 and R203_1.

Resistively isolated net named N893113 with device leads R412_1 and U30_9.

Resistively isolated net named N2300441 with device leads R97_2 and R98_1.

Resistively isolated net named N2300441_1085052 with device leads R101_2 and R102_1.

Resistively isolated net named N2300441_1085935 with device leads R109_2 and R110_1.

Resistively isolated net named N2300441_1086548 with device leads R89_2 and R90_1.

Net named N2344250 with device lead U7_AB2.

Net named N2344250_1133981 with device lead U8_AB2.

Net named N2440292 with device lead U10_B13.

Net named N2440292_1089589 with device lead U9_B13.

Resistively isolated net named N2520070 with device leads R627_1 and U9_N5.

Resistively isolated net named N2529522 with device leads R605_2 and U9_E8.

Net named N2547992 with device lead U7_J4.

Net named N2547992_1134016 with device lead U8_J4.

Resistively isolated net named N2696274 with device leads R655_2 and U9_K2.

Resistively isolated net named N2864589_1086679 with device leads R99_1 and R100_2.

Resistively isolated net named N2864589 with device leads R111_1 and R112_2.

Resistively isolated net named N2864589_1086545 with device leads R91_1 and R92_2.

Resistively isolated net named N2864589_1085046 with device leads R103_1 and R104_2.

Resistively isolated net named N3041326_1088467 with device leads R597_2 and U9_B10.

Resistively isolated net named RCLKD with device leads R273_1 and U84_89.

Net named N3587390 with device leads R273_2 and U46_C22.

Resistively isolated net named RCLKU with device leads R269_1 and U69_89.

Net named N3587402 with device leads R269_2 and U46_AE10.

Net named AOE_1086473 with device leads R650_1 and 77_V25.

Resistively isolated net named N3591861 with device leads R650_2 and U9_N6.

Net named N3667948_1088299 with device lead U7_B9.

Net named N3667948 with device lead U8_B9.

Net named N3690547_1133929 with device lead U10_W2.

Resistively isolated net named N3765625 with device lead R481_2.

Resistively isolated net named N3896461 with device leads R107_1 and R108_2.

Resistively isolated net named N3896461_1086715 with device leads R95_{—1 and R96}_2.

Resistively isolated net named N3896525 with device leads R93_2 and R94_1.

Resistively isolated net named N3896525_1085923 with device leads R105_2 and R106_1.

Resistively isolated net named N3925256_1085636 with device lead R364_1.

Resistively isolated net named N3925256_1084788 with device lead R366_1.

Resistively isolated net named N3925256 with device lead R362_{—1.}

Resistively isolated net named N3925256_1087023 with device lead R358_1.

Resistively isolated net named N3925256_1089289 with device lead R360_1.

Resistively isolated net named N3925256_1085274 with device lead R368_1.

Resistively isolated net named N3925329_1085641 with device lead R365_1.

Resistively isolated net named N3925329_1084791 with device lead R367_1.

Resistively isolated net named N3925329_1089288 with device lead R361_1.

Resistively isolated net named N3925329_1087021 with device lead R359_1.

Resistively isolated net named N3925329 with device lead R363_1.

Resistively isolated net named N3925329_1085272 with device lead R369_1.

Resistively isolated net named N4072730 with device lead R440_1.

Resistively isolated net named N4214570 with device lead R12_1.

Resistively isolated net named N4221180 with device lead R7_1.

Resistively isolated net named N4221420 with device lead R9_1.

Resistively isolated net named N5974180 with device leads R178_2 and U74_13.

Resistively isolated net named N14384463 with device leads R309_2 and U40_12.

Resistively isolated net named N14384615 with device leads R311_1 and U40_9.

Resistively isolated net named N14397370 with device leads R318_2 and U40_2.

Resistively isolated net named N14403333 with device leads R317_2, U38_5, U39_1, and U39_2.

Resistively isolated net named N14419858 with device lead R656_1.

Resistively isolated net named N14421588 with device leads R283_1 and U69_49.

Resistively isolated net named N14421624 with device leads R167_2 and U69_14.

Resistively isolated net named N14653238 with device lead R634_2.

Resistively isolated net named N40726911 with device leads R45_2 and U14_12.

Resistively isolated net named N66202411 with device leads R549_2 and U11_12.

Resistively isolated net named N144121900 with device leads R314_2 and U39_12.

Resistively isolated net named N146532660 with device lead R589_1.

Resistively isolated net named N146532941 with device lead R590_2.

Resistively isolated net named N146533144 with device lead R591_1.

Resistively isolated net named N146533180 with device lead R636_1.

Resistively isolated net named N146533460 with device lead R596_1.

Resistively isolated net named N146534061 with device lead R635_2.

Resistively isolated net named NLAMP_TST with device leads R179_2 and U74_9.

Net named NT0 with device lead U46_AC3.

Net named NT1 with device lead U46_AD5.

Net named NT2 with device lead U46_AC5.

Net named NT3 with device lead U46_AE5.

Net named NT4 with device lead U46_AF4.

Net named NT5 with device lead U46_AD4.

Net named NT6 with device lead U46_AE4.

Net named NT7 with device lead U46_AF3.

Net named NT8 with device lead U46_AE3.

Net named NT9 with device lead U46_AF2.

Net named NT10 with device lead U46_AD1.

Resistively isolated net named OE with device lead RN22_7.

Resistively isolated net named OE1 with device lead RN22_1.

Resistively isolated net named OE2 with device lead RN22_2.

Resistively isolated net named OE3 with device lead RN22_3.

Resistively isolated net named OE4 with device lead RN22_4.

Resistively isolated net named OE5 with device lead RN22_8.

Resistively isolated net named PLC with device lead R3619_2.

Resistively isolated net named PLC_1073384 with device lead R3419_2.

Resistively isolated net named PLC_1073991 with device lead R3319_2.

Resistively isolated net named PLC_1075129 with device lead R3519_2.

Resistively isolated net named PLC_1105718 with device lead R3219_2.

Resistively isolated net named PLC_1127477 with device lead R3119_2.

Resistively isolated net named PLD with device lead R3129_2.

Resistively isolated net named PLD_1073428 with device lead R3429_2.

Resistively isolated net named PLD_1073943 with device lead R3329_2.

Resistively isolated net named PLD_1074561 with device lead R3629_2.

Resistively isolated net named PLD_1075116 with device lead R3529_2.

Resistively isolated net named PLD_1105694 with device lead R3229_2.

Resistively isolated net named POTS_CON1 with device lead R20_2.

Net named PP10 with device leads RN38_2 and U46_R25.

Net named PP11 with device leads RN38_3 and U46_R26.

Net named PP12 with device leads RN38_4 and U46_T24.

Net named PP13 with device leads RN38_5 and U46_P25.

Net named PP14 with device leads RN38_6 and U46_R23.

Net named PP15 with device leads RN38_7 and U46_P26.

Net named PP16 with device leads RN38_8 and U46_R24.

Net named PP17 with device leads RN48_1 and U46_N25.

Net named PP19 with device leads RN48_3 and U46_AF9.

Net named PP20 with device leads RN48_4 and U46_B15.

Net named PP21 with device leads RN48_5 and U46_A16.

Net named PP22 with device leads RN48_6 and U46_C17.

Net named PP23 with device leads RN48_7 and U46_A17.

Net named PP24 with device leads RN48_8 and U46_C18.

Net named PP25 with device leads RN37_1 and U46_B17.

Net named PP27 with device leads RN37_3 and U46_R3.

Net named PP29 with device leads RN37_5 and U46_U3.

Net named PP31 with device leads RN37_7 and U46_W1.

Net named PP33 with device leads RN36_1 and U46_U2.

Net named PP35 with device leads RN36_3 and U46_V1.

Net named PP37 with device leads RN36_5 and U46_W3.

Net named PP51 with device leads RN46_3 and U46_A23

Net named PP52 with device leads RN46_4 and U46_C23

Net named PPAA0 with device leads RN4_1 and U46_AF21.

Net named PPAA1 with device leads RN4_2 and U46_AD20.

Net named PPAA3 with device leads RN4_3 and U46_W26.

Net named PPAA4 with device leads RN4_4 and U46_W24.

Net named CE0MINUS with device leads R660_1 and U7_AA25.

Resistively isolated net named QCEMINUS with device leads R660_2 and U9_U1.

Net named QDX_1133908 with device lead U10_N13.

Resistively isolated net named RADR4 with device lead RN2_2.

Net named RADRD0 with device leads U46_B20 and U84_37.

Net named RADRD1 with device leads U46_A21 and U84_36.

Net named RADRD2 with device leads U46_C21 and U84_35.

Net named RADRD3 with device leads U46_D20 and U84_34.

Net named RADRD4 with device leads U46_B21 and U84_33.

Net named RADRD5 with device leads U46_A22 and U84_32.

Net named RADRD6 with device leads U46_C19 and U84_100.

Net named RADRD7 with device leads U46_B18 and U84_99.

Net named RADRD8 with device leads U46_D15 and U84_82.

Net named RADRD9 with device leads U46_A14 and U84_81.

Net named RADRD10 with device leads U46_A20 and U84_44.

Net named RADRD11 with device leads U46_C20 and U84_45.

Net named RADRD12 with device leads U46_B19 and U84_46.

Net named RADRD13 with device leads U46_D18 and U84_47.

Net named RADRD14 with device leads U46_A19 and U84_48.

Net named RADRU0 with device leads U46_AE7 and U69_37.

Net named RADRU1 with device leads U46_AF6 and U69_36.

Net named RADRU2 with device leads U46_AD6 and U69_35.

Net named RADRU3 with device leads U46_AC7 and U69_34.

Net named RADRU4 with device leads U46_AE6 and U69_33.

Net named RADRU5 with device leads U46_AF5 and U69_32.

Net named RADRU6 with device leads U46_AF8 and U69_100.

Net named RADRU7 with device leads U46_AD8 and U69_99.

Net named RADRU8 with device leads U46_AF11 and U69_82.

Net named RADRU9 with device leads U46_AE12 and U69_81.

Net named RADRU10 with device leads U46_AF12 and U69_44.

Net named RADRU11 with device leads U46_AF7 and U69_45.

Net named RADRU12 with device leads U46_AD7 and U69_46.

Net named RADRU13 with device leads U46_AE8 and U69_47.

Net named RADRU14 with device leads U46_AC9 and U69_48.

Net named RADVDN with device leads U46_B14 and U84_83.

Net named RADVUN with device leads U46_AD10 and U69_83.

Net named RCEDN0 with device leads U46_A18 and U84_98.

Net named RCEUN0 with device leads U46_AE9 and U69_98.

Resistively isolated net named REF with device lead R3122_2.

Resistively isolated net named REF_1073394 with device lead R3422_2.

Resistively isolated net named REF_1073937 with device lead R3322_2.

Resistively isolated net named REF_1074598 with device lead R3622_2.

Resistively isolated net named REF_1075107 with device lead R3522_2.

Resistively isolated net named REF_1105707 with device lead R3222_2.

Net named RGWDN with device leads U46_D17 and U84_88.

Net named RGWUN with device leads U46_AF10 and U69_88.

Net named ROEDN0 with device leads U46_B16 and U84_86.

Net named ROEUN with device leads U46_AC10 and U69_86.

Net named RSCDN with device leads U46_C16 and U84_85.

Net named RSCUN with device leads U46_AE11 and U69_85.

Resistively isolated net named RSN with device leads R3120_1 and R3127_2.

Resistively isolated net named RSN_1073385 with device leads R3420_1 and R3427_2.

Resistively isolated net named RSN_1074001 with device leads R3320_1 and R3327_2.

Resistively isolated net named RSN_1074580 with device leads R3620_1 and R3627_2.

Resistively isolated net named RSN_1075103 with device leads R3520_1 and R3527_2.

Resistively isolated net named RSN_1105669 with device leads R3220_1 and R3227_2.

Net named RSPDN with device leads U46_A15 and U84_84.

Net named RSPUN with device leads U46_AD9 and U69_84.

Net named RXENB1 with device leads R281_2, RN1_1, and U46_AE22.

Resistively isolated net named RXENB2 with device lead RN1_2.

Resistively isolated net named RXENB3 with device lead RN1_3.

Net named SEL_AB with device leads U13_6 and U80_66.

Net named SLIF_A0 with device lead U46_R2.

Net named SLIF_B0 with device lead U46_T2.

Resistively isolated net named SPR with device lead R304_2.

Resistively isolated net named TRI with device lead R151_1.

Resistively isolated net named TRIPH with device lead R155_1.

Resistively isolated net named TXADR4 with device lead RN2_1.

Net named TXENB1 with device leads R291_2, RN1_4, and U46_V25.

Resistively isolated net named TXENB2 with device lead RN1_5.

Resistively isolated net named TXENB3 with device lead RN1_6.

Net named TXPARTY with device leads RN2_3 and U46_T26.

Resistively isolated net named TYPE0 with device lead R394_1.

Resistively isolated net named TYPE1 with device lead R398_1.

Resistively isolated net named TYPE2 with device lead R392_1.

Resistively isolated net named TYPE3 with device lead R378_1.

Resistively isolated net named TYPE4 with device lead R376_1.

Resistively isolated net named TYPE5 with device lead R374_1.

Resistively isolated net named TYPE6 with device lead R371_1.

Resistively isolated net named TYPE7 with device lead R357_1.

Resistively isolated net named TYPE8 with device lead R404_1.

Resistively isolated net named TYPE9 with device lead R409_1.

Resistively isolated net named TYPE10 with device lead R428_1.

Resistively isolated net named TYPE11 with device lead R431_1.

Resistively isolated net named TYPE12 with device lead R411_1.

Resistively isolated net named TYPE13 with device lead R406_1.

Resistively isolated net named TYPE14 with device lead R400_1.

Resistively isolated net named TYPE15 with device lead R396_1.

Net named VCC25 with device lead R28_1.

Net named VCORE with device leads U7_A1, U7_AB23, U7_AD1, U7_AD26, U7_AF1, 2-U7_B2, U7_C3, U7_D4, U7_A2, U7_AC3, U7_AD2, U7_AF2, U7_U7_B3, U7_C4, U7_D5, 3-U7_A3, U7_AC4, U7_AD3, U7_AE1, U7_AE2, U7_AF3, U7_B24, U7_C23, U7_D22, 4-U7_A24, U7_AC5, U7_AD4, U7_AE3, U7_AF24, U7_B25, U7_C24, U7_D23, U7_A25, 5-U7_AC22, U7_AD23, U7_AE24, U7_AF25, U7_B26, U7_C25, U7_D24, U7_A26, 6-U7_AC23, U7_AD24, U7_AE25, U7_AF26, U7_C1, U7_C26, U7_E4, U7_AB4, 7-U7_AC24, U7_AD25, U7_AE26, U7_B1, U7_C2, U7_D3, U7_E23, U8_A1, U8_AB23, 8-U8_AD1, U8_AD26, U8_AF1, U8_B2, U8_C3, U8_D4, U8_A2, U8_AC3, U8_AD2, 9-U8_AF2, U8_B3, U8_C4, U8_D5, U8_A3, U8_AC4, U8_AD3, U8_{AE1, U8}_AE2, 10-U8_AF3, U8_B24, U8_C23, U8_D22, U8_A24, U8_AC5, U8_AD4, U8_AE3, U8_AF24, 11-U8_B25, U8_C24, U8_D23, U8_A25, U8_AC22, U8_AD23, U8_AE24, U8_AF25, 12-U8_B26, U8_C25, U8_D24, U8_A26, U8_AC23, U8_AD24, U8_AE25, U8_AF26, 13-U8_C1, U8_C26, U8_E4, U8_AB4, U8_AC24, U8_AD25, U8_AE26, U8_B1, U8_C2, 14-U8_D3, U8_E23, U9_B16, U9_C1, U9_E6, U9_F10, U9_F14, U9_J1, U9_L15, 15-U9_P10, U9_T1, U9_V2, U9_V18, U9_W16, U10_B16, U10_C1, U10_E6, U10_F10 16-U10_F14, U10_J1, U10_L15, U10_P10, U10_T1, U10_V2, U10_V18, and U10_W16.

Net named VDDA with device lead U9_F13.

Net named VDDA_1084190 with device lead U10_F13.

Net named XCS_FLASHMINUS_1133926 with device lead U10_F6.

Shorts to the following unconnected device leads are covered: Unconnected device leads U7_AB26, U7_AA24, U7_AB25, U7_Y25, U7_AA26, U7_W23, U7_Y24, U7_AF22, U7_AE22, U7_AC20, U7_AE21, U7_V23, U7_T4, U7_E2, U7_F3, U7_E1, U7_F2, U7_D10, U7_C9, U7_A7, U7_Y1, U7_W2, U7_V3, U7_U4, U7_V2, U7_AA3, U7_AB1, U7_AA2, U7_Y3, U8_AB26, U8_AA24, U8_AB25, U8_Y25, U8_AA26, U8_W23, U8_Y24, U8_AF22, U8_AE22, U8_AC20, U8_AE21, U8_V23, U8_T4, U8_E2, U8_F3, U8_E1, U8_F2, U8_D10, U8_C9, U8_A7, U8_Y1, U8_W2, U8_V3, U8_U4, U8_V2, U8_AA3, U8_AB1, US_AA2, US_Y3, U10_R14, and U10_W7.

Fault coverage class 4 nets (some opens covered):

Net named AFE_SDO:

Opens that float low covered on the following: device lead U8_R2.

Possible opens coverage on pullup device lead R509_2.

No opens coverage on device leads R476_2, R478_2, and R479_2.

Net named AFE_SDO_1086422:

Opens that float low covered on the following: device lead U7_R2.

Possible opens coverage on pullup device lead R488_2.

No opens coverage on device leads R472_2, R473_2, and R474_2.

Net named CLKS2_1088291:

Opens that float low covered on the following: device lead U7_R3.

Possible opens coverage on pullup device lead R487_1.

Net named CLKS2:

Opens that float low covered on the following: device lead U8_R3.

Possible opens coverage on pullup device lead R501_1.

Net named CLKSEL_1084198:

Opens that float low covered on the following: device lead U10_P12.

Possible opens coverage on pullup device lead R573_1.

Net named DR2:

Opens that float low covered on the following: device lead U7_V1.

Possible opens coverage on pullup device lead R485_1.

Net named DR2_1133989:

Opens that float low covered on the following: device lead U8_V1.

Possible opens coverage on pullup device lead R499_1.

Net named GND:

Opens that float high covered on the following: device leads U7_L2 and U8_L2.

Possible opens coverage on pulldown device leads R45_1, R49_1, R86_1, R137_2, R151_2, R155_2, R158_1, R162_1, R164_2, R165_1, R171_1, R172_1, R178_1, R202_2, R215_1, R217_1, R231_1, R232_1, R236_1, R259_1, R261_1, R274_1, R278_1, R283_2, R284_2, R287_1, R295_2, R296_2, R297_1, R311_2, R314_1, R318_1, R372_2, R402_2, R412_2, R434_1, R439_1, R452_2, R482_1, R496_1, R538_1, R542_1, R543_1, R544_1, R549_1, R550_1, R552_2, R554_2, R557_2, R559_2, R567_1, R572_1, R574_1, R576_2, R578_2, R579_1, R581_1, R585_1, R586_1, R589_2, R591_2, R596_2, R597_1, R598_1, R605_1, R606_1, R619_1, R627_2, R628_2, R636_2, R653_1, R654_1, R655_1, R657_1, R657_1, R695_2, R3103_1, R3107_2, R3118_1, R3119_1, R3122_1, R3127_1, R3129_1, R3203_1, R3207_2, R3218_1, R3219_1, P3222_1, R3227_1, R3229_1, R3303_1, R3307_2, R3318_1, R3319_1, R3322_1, R3327_1, R3329_1, R3403_1, R3407_2, R3418_1, R3419_1, R3422_1, R3427_1, R3429_1, R3503_1, R3507_2, R3518_1, R3519_1, R3522_1, R3527_1, R3529_1, R3603_1, R3607_2, R3618_1, R3619_1, R3622_1, R3627_1, R3629_1, RN2_10, and RN3_10.

No opens coverage on device leads J16_1(*), J16_3(*), J16_5(*), J16_7(*7), J16_9(*), J16_11(*), J16_26(*), J16_34(*), J16_43(*), J16_53(*), J16_54(*), J16_63(*), J16_64(*), J16_74(*), J16_84(*), J16_94(*), J16_103(*), J16_104(*), J16_113(*), J16_114(*), J16_123(*), J16_124(*), J17_1(*), J17_3(*), J17_5(*), J17_7(*), J17_9(*), J17_11(*), J17_15(*), J17_23(*), J17_33(*), J17_34(*), J17_43(*), J17_44(*), J17_53(*), J17_54(*), J17_63(*), J17_64(*), J17_73(*), J17_74(*), J17_83(*), J17_84(*), J17_93(*), J17_94(*), J17_103(*), J17_104(*), J17_113(*), J17_114(*), J17_123(*), J17_124(*), J17_139(*), R29_2, R45_1, R49_1, R86_1, R137_2, R151_2, R155_2, R158_1, R162_1, R164_2, R165_1, R171_1, R172_1, R178_1, R202_2, R215_1, R217_1, R231_1, R232_1, R236_1, R246_2, R248_2, R257_1, R259_1, R261_1, R274_1, R278_1, R283_2, R284_2, R287_1, R295_2, R296_2, R297_1, R310_2, R311_2, R314_1, R318_1, R372_2, R402_2, R412_2, R434_1, R439_1, R452_2, R482_1, R496_1, R538_1, R541_1, R542_1, R543_1, R544_1, R549_1, R550_1, R552_2, R554_1, R557_2, R559_2, R567_1, R572_1, R574_1, R576_2, R578_2, R579_1, R581_1, R585_1, R586_1, R589_2, R591_2, R596_2, R597_1, R598_1, R605_1, R606_1, R619_1, R627_2, R628_2, R636_2, R653_1, R654_1, R655_1, R657_1, R694_2, R695_2, R3103_1, R3107_2, R3118_1, R3119_1, R3122_1, R3127_1, R3129_1, R3203_1, R3207_2, R3218_1, R3219_1, R3222_1, R3227_1, R3229_1, R3303_1, R3307_2, R3318_1, R3319_1, R3322_1, R3327_1, R3329_1, R3403_1, R3407_2, R3418_1, R3419_1, R3422_1, R3427_1, R3429_1, R3503_1, R3507_2, R3518_1, R3519_1, R3522_1, R3527_1, R3529_1, R3603_1, R3607_2, R3618_1, R3619_1, R3622_1, R3627_1, R3629_1, R4887_1, RN2_9, RN2_10, RN3_9, RN3_10, U4_4, U4_5, U4_7, U4_9, U4_10, U4_12, U4_13, U7_B4, U7_A15, U7_D25, U7_R26, U7_AE23, U7_AF12, U7_AC2, U7_M1, U7_C5, U7_C16, U7_E24, U7_U26, U7_AD22, U7_AF10, U7_AB3, U7_K1, U7_D6, U7_A19, U7_F23, U7_W26, U7_AC21, U7_AF8, U7_AA4, U7_H1, U7_A4, U7_A23, U7_D26, U7_AC26, U7_AF23, U7_AF4, U7_AC1, U7_D1, U7_A8, U7_D21, U7_H26, U7_AA23, U7_AF19, U7_AC6, U7_W1, U7_F4, U7_C11, U7_C22, U7_K26, U7_AB24, U7_AF17, U7_AD5, U7_U1, U7_E3, U7_B12, U7_B23, U7_M26, U7_AC25, U7_AF15, U7_AE4, U7_R1, U7_D2, U7_B13, U7_A13, U7_N25, U7_N26, U7_AE14, U7_AF13, U7_P2, U7_N1, U7_B14, U7_A14, U7_P25, U7_P26, U7_AE13, U7_AF14, U7_N2, U7_P1, U8_B4, U8_A15, U8_D25, U8_R26, U8_AE23, U8_AF12, U8_AC2, U8_Ml, U8_C5, U8_C16, U8_E24, U8_U26, U8_AD22, U8_AF10, U8_AB3, U8_K1, U8_D6, U8_A19, U8_F23, U8_W26, U8_AC21, U8_AF8, U8_AA4, U8_H1, U8_A4, U38_A23, U8_D26, U8_AC26, U8_AF23, U8_AF4, U8_AC1, U8_D1, U8_A8, U8_D21, U8_H26, U8_AA23, U8_AF19, U8_AC6, U8_W1, U8_F4, U8_C11, U8_C22, U8_K26, U8_AB24, U8_AF17, U8_AD5, U8_U1, U8_E3, U8_B12, U8_B23, U8_M26, U8_AC25, U8_AF15, U8_AE4, U8_R1, U8_D2, U8_B13, U8_A13, U8_N25, U8_N26, U8_AE14, U8_AF13, U8_P2, U8_N1, U8_B14, U8_A14, U8_P25, U8_P26, U8_AE13, U8_AF14, U8_N2, U8_P1, U9_A7, U9_C18, U9_E5, U9_F9, U9_J19, U9_M6, U9_P11, U9_R15, U9_T4, U9_W4, U9_W14, U9_D12, U9_F7, U9_G18, U9_H6, U9_M14, U9_P1, U9_W9, U9_W12, U10_A7, U10_A7, U10_C18, U10_E5, U10_F9, U10_J19, U10_M6, U10_P11, U10_R15, U10_T4, U10_W4, U10_W14, U10_D12, U10_F7, U10_G18, U10_H6, U10_M14, U10_P1 U10_W9, U10_W12, U11_5, U11_8, U11_16, U13_2, U13_4, U13_7, U13_9, U13_10, U13_12, U13_13, U14_5, U14_8, U14_16, U30_5, U30_8, U30_16, U38_1, U38_7, U38_11, U38_13, U39_7, U40_7, U46_A1, U46_A2, U46_A26, U46_B2, U46_B25, U46_B26, U46_C3, U46_C24, U46_D4, U46_D9, U46_D14, U46_D19, U46_D23, U46_H4, U46_J23, U46_N4, U46_P23, U46_V4, U46_W23, U46_AC4, U46_AC8, U46_AC13, U46_AC18, U46_AC23, U46_AD3, U46_AD24, U46_AE1, U46_AE2, U46_AE25, U46_AF1, U46_AF25, U46_AF26, U46_M1, U46_Y3, U47_1, U47_13, U47_25, U47_38, U47_51, U47_66, U47_79, U47_91, U47_103, U47_118, U47_131, U47_143, U47_158, U47_170, U47_182, U47_195, U49_7, U56_2, U56_5, U56_7, U56_9, U56_10, U57_7, U57_9, U57_10, U58_7, U68_2, U68_4, U68_7, U68_9, U68_12, U69_5, U69_10, U69_17, U69_21, U69_26, U69_31, U69_40, U69_55, U69_60, U69_64, U69_67, U69_71, U69_76, U69_90, U69_92, U74_7, U79_4, U79_10, U79_15, U79_21, U79_28, U79_34, U79_39, U79_45, U80_1, U80_11, U80_23, U80_38, U80_49, U80_64, U80_77, U80_88, U84_5, U84_10, U84_17, U84_21, U84_26, U84_31, U84_40, U84_55, U84_60, U84_64, U84_67, U84_71, U84_76, U84_90, and U84_92.

Net named MO: Opens that float high covered on the following: device lead U80_24. Possible opens coverage on pulldown device lead R49_2.

Net named MGNDA: Possible opens coverage on pulldown device leads R90_2, R91_2, R94_2, R95_2, R98_2, R99_2, R102_2, R103_2, R106_2, R107_2, R110_2, R111_2, R358_2, R359_2, R360_2, 8361_2, 8362_2, R363_2, R364_2, R365_2 R366_2, R367_2, R368_2, and R369_2.

Net named MOT_MODE: Opens that float high covered on the following: device lead U10_P6. Possible opens coverage on pulldown device lead R654_2.

Net named MVCC33:

Possible opens coverage on pullup device leads R484_2, R485_2, R487_2, R488_1, R489_1, R490_2, R491_2, R492_1, R493_1, R495_2, R498_2, R499_2, R501_2, R502_1, R503_2, R504_2, R505_1, R506_1, R509_1, R555_1, R560_1, R563_1, R564_1, R571_2, R573_2, R580_1, R582_1, R593_1, R595_1, R602_1, R604_1, R621_1, R623_1, R626_1, R656_2, R679_1, and R680_1.

No opens coverage on device leads R484_2, R485_2, R487_2, R488_1, R489_1, R490_2, R491_2, R492_1, R493_1, R495_2, R498_2, R499_2, R501_2, R502_1, R503_2, R504_2, R505_1, R506_1, R509_1, R553_1, R555_1, R558_1, R560_1, R563_1, R564_1, R571_2, R573_2, R580_1, R582_1, R592_1, R593_1, R594_1, R595_1, R600_1, R602_1, R603_1, R604_1, R620_1, R621_1, R623_1, R626_1, R632_2, P633_2, R656_2, R675_1, R679_1, R680_1, R683_1, R687_2, R689_2, R690_2, R691_2, U7_C6, U7_C14, U7_C21, U7_N24, U7_AD21, U7_AD13, U7_AD6, U7_P3, U7_B7, U7_A16, U7_G23, U7_T26, U7_AE20, U7_AF11, U7_Y4, U7_L1, U7_B8, U7_C17, U7_H24, U7_U24, U7_AE19, U7_AD10, U7_W3, U7_K3, U7_C10, U7_B19, U7_K24, U7_W24, U7_AD17, U7_AE8, U7_U3, U7_H3, U7_A11, U7_B20, U7_L26, U7_Y23, U7_AF16, U7_AE7, U7_T1, U7_G4, U8_C6, U8_C14, U8_C21, U8_N24, U8_AD21, U8_AD13, U8_AD6, U8_P3, U8_B7, U8_A16, U8_G23, U8_T26, U8_AE20, U8_AF11, U8_Y4, U8_L1, U8_B8, U8_C17, U8_H24, U8_U24, U8_AE19, U8_AD10, U8_W3, U8_K3, U8_C10, U8_B19, U8_K24, U8_W24, U8_AD17, U8_AE8, U8_U3, U8_H3, U8_A11, U8_B20, U8_L26, U8_Y23, U8_AF16, U8_AE7, U8_T1, U8_G4, U9_E9, U9_F1, U9_G7, U9_H18, U9_N7, U9_P18, U9_R6, U9_R11, U10_E9, U10_F1, U10_G7, U10_H18, U10_N7, U10_P18, U10_R6, and U10_R11.

Net named N01580_1133978:

Opens that float low covered on the following: device lead U8_L3.

Possible opens coverage on pullup device lead R502_2.

Net named N01580:

Opens that float low covered on the following: device lead U7_L3.

Possible opens coverage on pullup device lead R489_2.

Net named N01587_1088288:

Opens that float low covered on the following: device lead U7_G3.

Possible opens coverage on pullup device lead R492_2.

Net named N01587:

Opens that float low covered on the following: device lead U8_G3.

Possible opens coverage on pullup device lead R505_2.

Net named N01594:

Opens that float low covered on the following: device lead U8_A12.

Possible opens coverage on pullup device lead R595_2.

Net named N01594_1088295:

Opens that float low covered on the following: device lead U7_A12.

Possible opens coverage on pullup device lead R593_2.

Net named N02093:

Opens that float high covered on the following: device leads U8_AA1, U8_Y2, and U8_V4.

Possible opens coverage on pulldown device lead R496_2.

Net named N02093_1088284:

Opens that float high covered on the following: device leads U7_AA1, U7_Y2, and U7_V4.

Possible opens coverage on pulldown device lead R482_2.

Net named N02236_1134014:

Opens that float low covered on the following: device lead U8_B15.

Possible opens coverage on pullup device lead R626_2.

Net named N02236:

Opens that float low covered on the following: device lead U7_B15.

Possible opens coverage on pullup device lead R623_2.

Net named N08947:

Opens that float high covered on the following: device lead U7_M4.

Possible opens coverage on pulldown device lead R554_1.

Net named N08947_1133943:

Opens that float high covered on the following: device lead U8_M4.

Possible opens coverage on pulldown device lead R559_1.

Net named N19410_1088278:

Opens that float low covered on the following: device lead U7_Y26.

Possible opens coverage on pullup device lead R679_2.

Net named N19410:

Opens that float low covered on the following: device lead U8_Y26.

Possible opens coverage on pullup device lead R680_2.

Net named N19559_1088264:

Opens that float low covered on the following: device lead U7_H4.

Possible opens coverage on pullup device lead R555_2.

Net named N19559:

Opens that float low covered on the following: device lead U8_H4.

Possible opens coverage on pullup device lead R560_2.

Net named N19563_1088265:

Opens that float low covered on the following: device lead U7_G2.

Possible opens coverage on pullup device lead R493_2.

Net named N19563:

Opens that float low covered on the following: device lead U8_G2.

Possible opens coverage on pullup device lead R506_2.

Net named N2520070_1084182:

Opens that float high covered on the following: device lead U10_N5.

Possible opens coverage on pulldown device lead R628_1.

Net named N2529522_1133866:

Opens that float high covered on the following: device lead U10_E8.

Possible opens coverage on pulldown device lead R606_2.

Net named N2696274_1133924:

Opens that float high covered on the following: device lead U10_K2.

Possible opens coverage on pulldown device lead R657_2.

Net named N3041326:

Opens that float high covered on the following: device lead U10_B10.

Possible opens coverage on pulldown device lead R598_2.

Net named PP50:

Opens that float low covered on the following: device lead U46_B22.

Possible opens coverage on pullup device lead RN46_2.

Net named PP54:

Opens that float low covered on the following: device lead U46_D22.

Possible opens coverage on pullup device lead RN46_6.

Net named RXCLAV1:

Opens that float high covered on the following: device lead U46_AF24.

Possible opens coverage on pulldown device lead RN3_7.

Net named RXCLAV2:

Opens that float high covered on the following: device lead U46_AD23.

Possible opens coverage on pulidown device lead RN3_6.

Net named RXCLAV3:

Opens that float high covered on the following: device lead U46_AE24.

Possible opens coverage on pulldown device lead RN3_5.

Net named RXPARTY:

Opens that float high covered on the following: device lead U46_AD25.

Possible opens coverage on pulldown device lead RN2_4.

Net named TXCLAV1:

Opens that float high covered on the following: device lead U46_K25.

Possible opens coverage on pulldown device lead RN3_3.

Net named TXCLAV2:

Opens that float high covered on the following: device lead U46_M23.

Possible opens coverage on pulldown device lead RN3_2.

Net named TXCLAV3:

Opens that float high covered on the following: device lead U46_L26.

Possible opens coverage on pulldown device lead RN3_1.

Net named URA4:

Opens that float high covered on the following: device lead U10_E14.

Possible opens coverage on pulldown device lead R543_2.

Net named UTA4 1134077:

Opens that float high covered on the following: device lead U10_G14.

Possible opens coverage on pulldown device lead R581_2.

Net named VCC5:

Possible opens coverage on pullup device leads R7_2, R8_2, R9_2, R10_2, R11_2, R12_2, R686_2, R3244_1, R3245_1, R3444_1, R3445_1, R3644_1, R3645_1, R4873_1, P4874_1, P4875_1, P4876_1, P4881_1, and R4882_1;

No opens coverage on device leads R7_2, R8_2, R9_2, R10_2, R11_2, R12_2, R686_2, R3244_1, R3245_1, R3444_1, R3445_1, R3644_1, R3645_1, R4873_1, R4874_1, R4875_1, R4876_1, R4881_1, R4882_1, and R4885_1.

Net named VCCA_DA:

Possible opens coverage on pullup device lead R457_2.

Net named VCCA_DA2:

Possible opens coverage on pullup device lead R456_2.

Net named XASMINUS:

Opens that float low covered on the following: device lead U8_D9.

Possible opens coverage on pullup device lead R582_2.

Net named XASMINUS_1088238:

Opens that float low covered on the following: device lead U7_D9.

Possible opens coverage on pullup device lead R580_2.

Net named XBLASTMINUS:

Opens that float low covered on the following: device lead U8_B6.

Possible opens coverage on pullup device lead R564_2.

Net named XBLASTMINUS_1088248:

Opens that float low covered on the following: device lead U7_B6.

Possible opens coverage on pullup device lead R563_2.

Net named XBOFF:

Opens that float high covered on the following: device lead U8_B11.

Possible opens coverage on pulldown device lead R586_2.

Net named XBOFF_1088231:

Opens that float high covered on the following: device lead U7_B11.

Possible opens coverage on pulldown device lead R585_2.

Net named XCLKIN:

Opens that float high covered on the following: device lead U8_A9.

Possible opens coverage on pulldown device lead R574_2.

Net named XCLKIN_1088235:

Opens that float high covered on the following: device lead U7_A9.

Possible opens coverage on pulldown device lead R572_2.

Fault coverage class 5 nets (not covered):

Net named 01 with device lead R1_1.

Net named 01_1085208 with device lead R5_1.

Net named 02 with device lead R6_1.

Net named 02_1087327 with device lead R2_1.

Net named 03_1087325 with device lead R3_1.

Net named 03 with device lead R4_1.

Net named 0_9V_REF with device leads R4885_2 and R4887_2.

Net named X35M4 with device leads R43_1 and U14_14.

Net named 35MCLK with device lead R43_2.

Net named X35M0 with device leads R39_1 and U14_19.

Net named 35MCLKA0 with device leads R39_2 and U10_F8.

Net named X35M1 with device leads R40_1 and U14_18.

Net named 35MCLKA1 with device lead R40_2.

Net named X35M2 with device leads R41_1 and U14_17.

Net named 35MCLKA2 with device lead R41_2.

Net named X35M3 with device leads R42_1 and U14_15.

Net named 35MCLKA3 with device lead R42_2.

Net named N663628 with device lead R44_1.

Net named 35MDIV2 with device leads R44_2 and U11_10.

Net named 38_88M with device lead R176_2.

Net named 3VDD_PLL with device lead R203_2.

Net named WT_EN with device leads R32_1 and U80_27.

Net named RED_EN with device leads R36_1 and U80_21.

Net named GRN_EN with device leads R26_1 and U80_48.

Net named BLAMP_TST with device leads R25_1 and U13_3.

Net named 5VDD with device leads J16_8(*), J16_10(*), J16_12(*), J17_8(*), J17_10(*), J17_12(*), R25_2, R26_2, R32₁₃ 2, R36_2, R198_1, R199_1, R200_1, and R201_1.

Net named 70R7MHZ with device lead U9_E7.

Net named 70R7MHZ_1084183 with device lead U10_E7.

Net named N578832 with device lead RN8_1.

Net named AD_B0 with device lead RN8_8.

Net named N578834 with device lead RN8_2.

Net named AD_B1 with device lead RN8_7.

Net named N578836 with device lead RN8_3.

Net named AD_B2 with device lead RN8_6.

Net named N578838 with device lead RN8_4.

Net named AD_B3 with device lead RN8_5.

Net named N580371 with device lead RN14_1.

Net named AD_B4 with device lead RN14_8.

Net named N580373 with device lead RN14_2.

Net named AD_B5 with device lead RN14_7.

Net named N580375 with device lead RN14_3.

Net named AD_B6 with device lead RN14_6.

Net named N580377 with device lead RN14_4.

Net named AD_B7 with device lead RN14_5.

Net named N580685 with device lead RN15_1.

Net named AD_B8 with device lead RN15_8.

Net named N580687 with device lead RN15_2.

Net named AD_B9 with device lead RN15_7.

Net named N580689 with device lead RN15_3.

Net named AD_B10 with device lead RN15_6.

Net named N580691 with device lead RN15_4.

Net named AD_B11 with device lead RN15_5.

Net named N580999 with device lead RN16_1.

Net named AD_B12 with device lead RN16_8.

Net named N581001 with device lead RN16_2.

Net named AD_B13 with device lead RN16_7.

Net named N581003 with device lead RN16_3.

Net named AD_B14 with device lead RN16_6.

Net named N581005 with device lead RN16_4.

Net named AD_B15 with device lead RN16_5.

Net named AFEA_D0_1086502 with device lead U9_N16.

Net named AFEA_D1_1086503 with device lead U9_N19.

Net named AFEA_D2_1086504 with device lead U9_N18.

Net named AFEA_D3_1086505 with device lead U9_N15.

Net named AFEA_D4_1086506 with device lead U9_N14.

Net named AFEA_D5_1086507 with device lead U9_P19.

Net named AFEA_D6_1086508 with device lead U9_P16.

Net named AFEA_D7_1086509 with device lead U9_P15.

Net named AFEA_D8_1086510 with device lead U9_R18.

Net named AFEA_D9_1086511 with device lead U9_R19.

Net named AFEA_D10_1086512 with device lead U9_R16.

Net named AFEA_D11_1086513 with device lead U9_T18.

Net named AFEA_D12_1086514 with device lead U9_T19.

Net named AFEA_D13_1086515 with device lead U9_U18.

Net named AFEA_D14_1086516 with device lead U9_U19.

Net named AFEA_D15_1086517 with device lead U9_V19.

Net named AFEC_D0_1086486 with device lead U9_J15.

Net named AFEC_D1_1086487 with device lead U9_J16.

Net named AFEC_D2_1086488 with device lead U9_J18.

Net named AFEC_D3_1086489 with device lead U9_J14.

Net named AFEC_D4_1086490 with device lead U9_K15.

Net named AFEC_D5_1086491 with device lead U9_K16.

Net named AFEC_D6_1086492 with device lead U9_K18.

Net named AFEC_D7_1086493 with device lead U9_K19.

Net named AFEC_D8_1086494 with device lead U9_K14.

Net named AFEC_D9_1086495 with device lead U9_L14.

Net named AFEC_D10_1086496 with device lead U9_L18.

Net named AFEC_D11_1086497 with device lead U9_L19.

Net named AFEC_D12_1086498 with device lead U9_L16.

Net named AFEC_D13_1086499 with device lead U9_M15.

Net named AFEC_D14_1086500 with device lead U9_M16.

Net named AFEC_D15_1086501 with device lead U9_M18.

Net named N2521228_1089588 with device leads R520_1 and U9_H14.

Net named AFE_CSAN_1086483 with device lead R520_2.

Net named N252l240_1089586 with device leads R513_1 and U9_H19.

Net named AFE_CSBN_1086481 with device lead R513_2.

Net named N3782278 with device leads R561_1 and U9_R13.

Net named AFE_CSCN_1086485 with device lead R561_2.

Net named AFEOEMINUS with device leads R514_1, R515_1, R516_1, and U9_H16.

Net named AFE_OECN_1086480 with device lead R514_2.

Net named AFE_OEAN_1086477 with device lead R515_2.

Net named AFE_OEBN_1086471 with device lead R516_2.

Net named AFE_RXAN with device leads R80_2, R81_2, and R82_2.

Net named AFE_RXAN_1086395 with device leads R62_2, R63_2, and R64_2.

Net named AFE_RXAP with device leads R83_2, R84_2, and R85_2.

Net named AFE_RXAP_1086410 with device leads R65_2, R66_2, and R67_2.

Net named AFE_RXBN with device leads R74_2, R75_2, and R76_2.

Net named AFE_RXBN_1086370 with device leads R56_2, R57_2, and R58_2.

Net named AFE_RXBP with device leads R77_2, R78_2, and R79_2.

Net named AFE_RXBP_1086401 with device leads R59_2, 960_2, and 961_2.

Net named AFE_RXCN with device leads R50_2, R51_2, and 952_2.

Net named AFE_RXCN_1082373 with device leads R68_2, R69_2, and 970_2.

Net named AFE_RXCP with device leads R71_2, R72_2, and R73_2.

Net named AFE_RXCP_1086404 with device leads R53_2, R54_2, and R55_2.

Net named AFESYNC with device leads R517_1, R518_1, R519_1, and U9_M19.

Net named AFE_SYNCC_1086479 with device lead R517_2.

Net named AFE_SYNCB_1086476 with device lead R518_2.

Net named AFE_SYNCA_1086475 with device lead R519_2.

Net named AFEWRN with device leads R510_1, R511_1, R512_1, and U9_H15.

Net named AFE_WRBN_1086478 with device lead R510_2.

Net named AFE_WRCN_1086472 with device lead R511_2.

Net named AFE_WRAN_1086482 with device lead R512_2.

Net named ALC_RQ with device lead U47_112.

Net named BA16 with device leads J17_56(*) and U79_47.

Net named BA17 with device leads J17_52(*) and U79_46.

Net named BA18 with device leads J17_50(*) and U79_44.

Net named BA19 with device leads J17_48(*) and U79_43.

Net named BA20 with device leads J17_46(*) and U79_41.

Net named BA21 with device leads J17_42(*) and U79_40.

Net named BA22 with device leads J17_40(*) and U79_38.

Net named BA23 with device leads J17_38(*) and U79_37.

Net named BA24 with device leads J17_36(*) and U79_36.

Net named BA25 with device leads J17_32(*) and U79_35.

Net named BA26 with device leads J17_30(*) and U79_33.

Net named BA27 with device leads J17_28(*) and U79_32.

Net named BA28 with device leads J17_26(*) and U79_30.

Net named BA29 with device leads J17_22(*) and U79_29.

Net named BA30 with device leads J17_20(*) and U79_27.

Net named BA31 with device leads J17_18(*) and U79_26.

Net named BAD_CLK_A with device lead U47_55.

Net named BAD_CLK_B with device lead U47_102.

Net named N563252with device lead RN13_1.

Net named BALQ_RQ_A with device lead RNT13_8.

Net named N563254 with device lead RN13_2.

Net named BALQ_RQ_B with device lead RN13_7.

Net named BAD0 with device lead RN27_1.

Net named BA_D0 with device leads RN27_8 and U47_21.

Net named BAD1 with device lead RN27_2.

Net named BA_D1 with device leads RN27_7 and U47_20.

Net named BAD2 with device lead RN27_3.

Net named BA_D2 with device leads RN27_6 and U47_19.

Net named BAD3 with device lead RN27_4.

Net named BA_D3 with device leads RN27_5 and U47_17.

Net named BAD4 with device lead RN28_1.

Net named BA_D4 with device leads RN28_8 and U47_37.

Net named BAD5 with device lead RN28_2.

Net named BA_D5 with device leads RN28_7 and U47_36.

Net named BAD6 with device lead RN28_3.

Net named BA_D6 with device leads RN28_6 and U47_35.

Net named BAD7 with device lead RN28_4.

Net named BA_D7 with device leads RN28_5 and U47_34.

Net named BAD8 with device lead RN29_1.

Net named BA_D8 with device leads RN29_8 and U47_31.

Net named BAD9 with device lead RN29_2.

Net named BA_D9 with device leads RN29_7 and U47_30.

Net named BAD10 with device lead RN29_3.

Net named BA_D10 with device leads RN29_6 and U47_29.

Net named BAD11 with device lead RN29_4.

Net named BA_D11 with device leads RN29_5 and U47_28.

Net named BAD12 with device lead RN35_1.

Net named BA_D12 with device leads RN35_8 and U47_27.

Net named BAD13 with device lead RN35_2.

Net named BA_D13 with device leads RN35_7 and U47_24.

Net named BAD14 with device lead RN35_3.

Net named BA_D14 with device leads RN35_6 and U47_23.

Net named BAD15 with device lead RN35_4.

Net named BA_D15 with device leads RN35_5 and U47_22.

Net named N089650 with device leads RN40_4 and U79_2.

Net named BBA16 with device lead RN40_5.

Net named N089651 with device leads RN40_3 and U79_3.

Net named BBA17 with device lead RN40_6.

Net named N089652 with device leads RN40_2 and U79_5.

Net named BBA18 with device lead RN40_7.

Net named N089653 with device leads RN40_1 and U79_6.

Net named BBA19 with device lead RN40_8.

Net named N71035134 with device leads RN43_4 and U79_8.

Net named BBA20 with device lead RN43_5.

Net named N71035135 with device leads RN43_3 and U79_9.

Net named BBA21 with device leads RN43_6 and U80_44.

Net named N71035137 with device leads RN43_2 and U79_11.

Net named BBA22 with device leads RN43_7 and U80_43.

Net named N71035139 with device leads RN43_1 and U79_12.

Net named BBA23 with device leads RN43_8 and U80_42.

Net named N71035115 with device leads RN44_4 and U79_13.

Net named BBA24 with device leads RN44_5, U46_H26, and U80_41.

Net named N71035126 with device leads RN44_3 and U79_14.

Net named BBA25 with device leads RN44_6 and U46_H25.

Net named N71035129 with device leads RN44_2 and U79_16.

Net named BBA26 with device leads RN44_7 and U46_J26.

Net named N71035131 with device leads RN44_1 and U79_17.

Net named BBA27 with device leads RN44_8 and U46_K24.

Net named N71035133 with device leads RN47_4 and U79_19.

Net named BBA28 with device leads RN47_5, U46_J25, and U80_40.

Net named N71035136 with device leads RN47_3 and U79_20.

Net named BBA29 with device leads RN47_6, U46_K23, and U80_39.

Net named N71035140 with device leads RN47_2 and U79_22.

Net named BBA30 with device leads RN47_7, U46_K26, and U80_35.

Net named N71035141 with device leads RN47_1 and U79_23.

Net named BBA31 with device leads RN47_8 and U80_34.

Net named BBD0 with device leads RN17_1, U9_H4, U10_H4, and U80_53.

Net named BBD1 with device leads RN17_2, U9_J4, U10_J4, and U80_55.

Net named BBD2 with device leads RN17_3, U9_J2, U10_J2, and U80_57.

Net named BBD3 with device leads RN17_4, U9_J5, U10_J5, and U80_61.

Net named BBD4 with device leads RN17_5, U9_J6, U10_J6, and U80_65.

Net named BBD5 with device leads RN17_6, U9_K6, U10_K6, and U80_68.

Net named BBD6 with device leads RN17_7, U9_K5, U10_K5, and U80_70.

Net named BBD7 with device leads RN17_8, U9_L6, U10_L6, and U80_59.

Net named CT_C8_90 with device lead R228_1.

Net named BCT_C8_90 with device leads R228_2 and U47_49.

Net named CT_C8 with device lead R223_1.

Net named BCT_C8 with device leads R223_2 and U47_2.

Net named BCT_DIN with device lead U47_5.

Net named CT_FRAM with device lead R216_1.

Net named BCT_FRAM with device leads R216_2 and U47_46.

Net named BCT_SIN with device lead U47_3.

Net named BIST_EN with device lead U9_M1.

Net named BIST_EN_1084185 with device lead U10_M1.

Net named BLAMP_SYNC with device leads U47_87, U74_4, and U80_60.

Net named BLAMP_TST2 with device leads U13_1 and U74_10.

Net named BLAMP_TST_215583 with device leads U47_45, U74_8, and U74_11.

Net named N563256 with device lead RN13_3.

Net named BMCLK with device lead RN13_6.

Net named BPTCK_RET with device lead U40_6.

Net named BRW2 with device lead J16_88(*).

Net named BSEL_AD with device lead U47_81.

Net named N556847 with device leads RN23_4 and U47_132.

Net named CARD_CON0 with device lead RN23_5.

Net named N558035 with device leads RN23_3 and U47_127.

Net named CARD_CON1 with device lead RN23_6.

Net named N558040 with device leads RN23_2 and U47_134.

Net named CARD_CON2 with device lead RN23_7.

Net named N558045 with device leads RN23_1 and U47_133.

Net named CARD_CON3 with device lead RN23_8.

Net named CCLK with device lead U47_155.

Net named CLK2 with device lead R184_2.

Net named CLK_C with device lead U47_83.

Net named CLK_TST with device lead U47_110.

Net named COM8 with device lead J16_35(*).

Net named CPU_PRGM with device lead R669_1.

Net named CS_BUF with device lead U4_3.

Net named CT_DO with device lead U47_41.

Net named CT_SO with device lead U47_12.

Net named DATA with device lead U47_153.

Net named DONE with device lead U47_104.

Net named DR_626152 with device leads R263_2 and U47_96.

Net named DSP_INT_1088328 with device leads U7_W4 and U9_A5.

Net named N2571378_1088297 with device lead R649_1.

Net named DSP_RSTMINUS_1088304 with device leads R649_2, U7_K2, and U9_B2.

Net named DS_C0_C1 with device lead U47_85.

Net named DS_TST with device lead U47_101.

Net named DX with device leads R267_2 and U47_117.

Net named ED0 with device leads U7_AF21 and U9_V5.

Net named ED1 with device leads U7_AD19 and U9_T6.

Net named ED2 with device leads U7_AC18 and U9_V6.

Net named ED3_1088320 with device leads U7_AF20 and U9_W6.

Net named ED4 with device leads U7_AD18 and U9_T7.

Net named ED5 with device leads U7_AC17 and U9_V7.

Net named ED6 with device leads U7_AE18 and U9_W8.

Net named ED7 with device leads U7_AF18 and U9_T8.

Net named ED8 with device leads U7_AC16 and U9_V8.

Net named ED9 with device leads U7_AE17 and U9_V9.

Net named ED10_1088390 with device leads U7_AD16 and U9_T9.

Net named ED11 with device leads U7_AE16 and U9_W10.

Net named ED12_1088310 with device leads U7_AC15 and U9_T10.

Net named ED13 with device leads U7_AD15 and U9_V10.

Net named ED14_1088321 with device leads U7_AE15 and U9_V11.

Net named ED15 with device leads U7_AC14 and U9_T11.

Net named ED16_1088459 with device leads U7_AD14 and U9_W11.

Net named ED17_1088318 with device leads U7_AC13 and U9_T12.

Net named ED18_1088451 with device leads U7_AE12 and U9_V12.

Net named ED19 with device leads U7_AD12 and U9_V13.

Net named ED20_1088419 with device leads U7_AC12 and U9_T13.

Net named ED21_1088412 with device leads U7_AE11 and U9_W13.

Net named ED22 with device leads U7_AD11 and U9_T14.

Net named ED23_1088439 with device leads U7_AE10 and U9_V14.

Net named ED24 with device leads U7_AC11 and U9_V15.

Net named ED25_1088406 with device leads U7_AF9 and U9_T15.

Net named ED26_1088408 with device leads U7_AE9 and U9_W15.

Net named ED27_1088331 with device leads U7_AC10 and U9_V16.

Net named ED28_1088306 with device leads U7_AD9 and U9_T16.

Net named ED29_1088453 with device leads U7_AF7 and U9_W17.

Net named ED30_1088315 with device leads U7_AC9 and U9_V17.

Net named ED31 with device leads U7_AD8 and U9_W18.

Net named EMU0 with device leads R689_1 and UB8_AC8.

Net named EMU0_1088259 with device leads R687_1 and U7_AC8.

Net named EMU1_1088266 with device leads R690_1 and U7_AF6.

Net named EMU1 with device leads R691_1 and U8_AF6.

Net named FBAN with device leads R350_2 and R426_2.

Net named FBAN_1086400 with device leads R332_2 and R423_2.

Net named FBAP with device leads R355_2 and R420_2.

Net named FBAP_1086393 with device leads R337_2 and R417_2.

Net named FBBN with device leads R344_2 and R425_2.

Net named FBBN_1086388 with device leads R326_2 and R422_2.

Net named FBBP with device leads R349_2 and R419_2.

Net named FBBP_1086387 with device leads R331_2 and R416_2.

Net named FBCN with device leads R338_2 and 9424_2.

Net named FBCN_1086392 with device leads R320_2 and R421_2.

Net named FBCP with device leads R343_2 and R418_2.

Net named FBCP_1086396 with device leads R325_2 and R415_2.

Net named FS1 with device lead U47_206.

Net named FS2 with device lead U47_72.

Net named FS3 with device lead U47_205.

Net named FS4 with device lead U47_73.

Net named FS5 with device lead U47_204.

Net named FS6 with device lead U47_74.

Net named GPIO2 with device leads 9603_2 and U9_R9.

Net named GPIO3_1088454 with device leads R620_2 and U9_P9.

Net named GPIO4 with device leads R592_2 and U9_R10.

Net named GSR0_1125165 with device leads R3623_1 and R3626_2.

Net named GSR0 with device leads R3223_1 and R3226_2.

Net named GSR0_1125156 with device leads R3423_1 and R3426_2.

Net named GSR1 with device leads R3123_1 and R3126_2.

Net named GSR1_1125159 with device leads R3523_1 and R3526_2.

Net named GSR1_1125151 with device leads R3323_1 and R3326_2.

Net named GSX0_1125147 with device lead R3404_2.

Net named GSX0 with device lead R3204_2.

Net named GSX0_1125164 with device lead R3604_2.

Net named GSX1 with device lead R3104_2.

Net named GSX1_1125161 with device lead R3504_2.

Net named GSX1_1125150 with device lead R3304_2.

Net named HDLC0 with device leads J16_67(*), J16_131(*), R666_1, U58_8, and U58_11.

Net named HDLC_A0 with device lead U58_2.

Net named N7166010 with device leads R224_1 and U56_3.

Net named HDLC_A1 with device leads R224_2 and U58_9.

Net named HDLC_B0 with device lead U58_5.

Net named N7324911 with device leads R225_1 and U56_6.

Net named HDLC_B1 with device leads R225_2 and U58_12.

Net named HOOK_ST1 with device lead U47_70.

Net named HOOK_ST2 with device lead U47_69.

Net named HOOK_ST3 with device lead U47_68.

Net named HOOK_ST4 with device lead U47_67.

Net named HOOK_ST5 with device lead U47_65.

Net named HOOK_ST6 with device lead U47_63.

Net named ISYNC1 with device lead U47_193.

Net named ISYNC2 with device lead U47_200.

Net named ISYNC3 with device lead U47_190.

Net named ISYNC4 with device lead U47_199.

Net named ISYNC5 with device lead U47_191.

Net named ISYNC6 with device lead U47_198.

Net named N741457 with device leads J16_40(*) and R671_1.

Net named J2_40 with device leads R310_1, R671_2, and U40_11.

Net named N741465 with device leads J16_42(*) and R670_1.

Net named J2_42 with device leads R312_2, R670_2, and U40_8.

Net named LAMP_SYNC with device lead U74_3.

Net named MCLK with device lead U47_113.

Net named MDMRDY_B with device leads U9_L5 and U80_97.

Net named MPSIN_B with device leads RN10_4, U9_G5, and U80_16.

Net named N00021 with device leads R205_1 and R206_2.

Net named N00026 with device leads R195_2, R197_2, and R205_2.

Net named N00058 with device leads R193_1 and R206_1.

Net named N00143 with device lead R194_1.

Net named N00180 with device leads R193_2 and R194_2.

Net named N00195 with device leads R401_2 and R429_1.

Net named N00201 with device lead R210_1.

Net named N00204 with device leads R414_1 and R432_2.

Net named N00212 with device leads R87_2, R210_2, R432_1, R436_2, R451_1, R454_2, and R458_2.

Net named N00218 with device leads R436_1 and R437_2.

Net named N00228 with device lead R407_2.

Net named N00616 with device leads R195_1, R197_1, R218_2, and R219_2.

Net named N00999 with device leads R407_1, R429_2, and R433_1.

Net named N02619_1088290 with device lead R608_2.

Net named N02619 with device lead R610_2.

Net named N04897 with device lead R38_2.

Net named N13352 with device lead R17_1.

Net named N15279 with device lead U74_2.

Net named N17162 with device lead U74_1.

Net named N17627 with device lead R438_1.

Net named N28963 with device leads R28_2 and R29_1.

Net named N39640 with device leads R198_2, R199_2, R200_2, and R201_2.

Net named N42533 with device leads R454_1 and R455_2.

Net named N44078 with device lead R433_2.

Net named N44106 with device leads R413_1 and R414_2.

Net named N44118 with device lead R413_2.

Net named N45077 with device leads R458_1 and R459_2.

Net named N48368 with device lead R451_2.

Net named N48401 with device lead R441_2.

Net named N57202 with device lead R87_1.

Net named N61782 with device lead R640_2.

Net named N62012 with device lead R640_1.

Net named RING_INBIT with device leads R631_1 and U47_60.

Net named N62188 with device lead R631_2.

Net named N62670 with device lead R17_2.

Net named N142324 with device lead R3134_2.

Net named N142324_1073449 with device lead R3434_2.

Net named N142324_1074005 with device lead R3334_2.

Net named N142324_1105737 with device lead R3234_2.

Net named N142324_1075167 with device lead R3534_2.

Net named N142324_1074610 with device lead R3634_2.

Net named N147310_1073990 with device lead R3317_1.

Net named N147310 with device lead R3617_1.

Net named N147310_1073390 with device lead R3417_1.

Net named N147310_1105668 with device lead R3217_1.

Net named N147310_1075149 with device lead R3517_1.

Net named N147310_1127535 with device lead R3117_1.

Net named N147362_1073972 with device leads R3309_2 and R3310_1.

Net named N147362_1105720 with device leads R3209_2 and R3210_1.

Net named N147362 with device leads R3609_2 and R3610_1.

Net named N147362_1127468 with device leads R3209_2 and R3110_1.

Net named N147362_1073432 with device leads R3409_2 and R3410_1.

Net named N147362_1075131 with device leads R3509_2 and R3510_1.

Net named N147792_1074584 with device lead R3625_1.

Net named N147792_1075104 with device lead R3525_1.

Net named N147792 with device lead R3225_1.

Net named N147792_1127540 with device lead R3125_1.

Net named N147792_1073422 with device lead R3425_1.

Net named N147792_1073933 with device lead R3325_1.

Net named N147828_1073413 with device leads R3401_2 and R3402_1.

Net named N147828 with device leads R3201_2 and R3202_1.

Net named N147828_1075113 with device leads R3501_2 and R3502_1.

Net named N147828_1074587 with device leads R3601_2 and R3602_1.

Net named N147828_1073956 with device leads R3301_2 and R3302_1.

Net named N147828_1127469 with device leads R3101_2 and R3102_1.

Net named N152798_1075095 with device lead R3516_2.

Net named N152798 with device lead R3116_2.

Net named N152798_1073939 with device lead R3316_2.

Net named N152798_1074549 with device lead R3616_2.

Net named N152798_1073411 with device lead R3416_2.

Net named N152798_1105679 with device lead R3216_2.

Net named N153643 with device leads R3216_1 and R3220_2.

Net named N153643_1127488 with device leads R3116_1 and R3120_2.

Net named N153643_1074575 with device leads R3616_1 and R3620_2.

Net named N153643_1073430 with device leads R3416_1 and R3420_2.

Net named N153643_1073996 with device leads R3316_1 and R3320_2.

Net named N153643_1075123 with device leads R3516_1 and R3520_2.

Net named N168565_1075108 with device lead R3533_2.

Net named N168565_1105704 with device lead R3233_2.

Net named N168565_1074565 with device lead R3633_2.

Net named N168565_1073997 with device lead R3333_2.

Net named N168565 with device lead R3133_2.

Net named N168565_1073378 with device lead R3433_2.

Net named N176623_1075126 with device lead R3532_1.

Net named N176623_1073978 with device lead R3332_1.

Net named N176623 with device lead R3232_1.

Net named N176623_1127478 with device lead R3132_1.

Net named N176623_1073415 with device lead R3432_1.

Net named N176623_1074603 with device lead R3632_1.

Net named N201702_1073947 with device lead R3334_1.

Net named N201702_1105726 with device lead R3234_1.

Net named N201702_1073445 with device lead R3434_1.

Net named N201702 with device lead R3634_1.

Net named N201702_1075142 with device lead R3534_1.

Net named N201702_1127490 with device lead R3134_1.

Net named N6638191 with device leads R46_1 and U68_6.

Net named N407347 with device leads R46_2, U14_10, and U14_11.

Net named N4072732 with device lead R450_1.

Net named N407361 with device leads R450_2 and U68_5.

Net named N493599 with device leads R157_2 and U47_50.

Net named N495008_1127489 with device lead R3137_1.

Net named N495008_1075137 with device lead R35371.

Net named N495008 with device lead R3237_1.

Net named N495008_1073418 with device lead R3437_1.

Net named N495008_1074602 with device lead R3637_1.

Net named N495008_1073952 with device lead R3337_1.

Net named N513368_1127519 with device leads R3108_2 and R3112_1.

Net named N513368_1073402 with device leads R3408_2 and R3412_1.

Net named N513368 with device leads R3208_2 and R3212_1.

Net named N513368_1075153 with device leads R3508_2 and R3512_1.

Net named N513368_1073969 with device leads R3308_2 and R3312_1.

Net named N513368_1074593 with device leads R3608_2 and R3612_1.

Net named N514047_1073983 with device leads R3304_1, R3306_1, and R3311_2.

Net named N514047_1075148 with device leads R3504_1, R3506_1, and R3511_2.

Net named N514047_1073406 with device leads R3404_1, R3406_1, and R3411_2.

Net named N514047_1127510 with device leads R3104_1, R3106_1, and R3111_2.

Net named N514047_1105712 with device leads R3204_1, R3206_1, and R3211_2.

Net named N514047 with device leads R3604_1, R3606_1, and R3611_2.

Net named N514054_1105719 with device leads R3211_1 and R3215_2.

Net named N514054_1074589 with device leads R3611_1 and R3615_2.

Net named N514054 with device leads R3111_1 and R3115_2.

Net named N514054_1075105 with device leads R3511_1 and R3515_2.

Net named N514054_1073395 with device leads R3411_1 and R3415_2.

Net named N514054_1073962 with device leads R3311_1 and R3315_2.

Net named N514064_1105721 with device lead R3215_1.

Net named N514064_1073977 with device lead R3315_1.

Net named N514064 with device lead R3115_1.

Net named N514064_1075111 with device lead R3515_1.

Net named N514064_1074540 with device lead R3615_1.

Net named N514064_1073431 with device lead R3415_1.

Net named N537010 with device lead U47_109.

Net named CARD_CON4 with device lead R188_1.

Net named N558050 with device leads R188_2 and U47_15.

Net named BCT_DO_A with device lead RN42_1.

Net named N563137 with device lead RN42_8.

Net named BCT_SO_A with device lead RN42_2.

Net named N563140 with device lead RN42_7.

Net named BCT_DO_B with device lead RN42_3.

Net named N563143 with device lead RN42_6.

Net named BCT_SO_B with device lead RN42_4.

Net named N563146 with device lead RN42_5.

Net named SLOT_ID4 with device leads R306_1 and U49_1.

Net named N566135 with device leads R306_2 and U47_139.

Net named AD_A3 with device lead RN9_4.

Net named N566878 with device lead RN9_5.

Net named AD_A2 with device lead RN9_3.

Net named N566880 with device lead RN9_6.

Net named AD_A1 with device lead RN9_2.

Net named N566882 with device lead RN9_7.

Net named AD_A0 with device lead RN9_1.

Net named N566884 with device lead RN9_8.

Net named AD_A7 with device lead RN5_4.

Net named N567290 with device lead RN5_5.

Net named A_A6 with device lead RN5_3.

Net named N567292 with device lead RN5_6.

Net named AD_A5 with device lead RN5_2.

Net named N567294 with device lead RN5_7.

Net named AD_A4 with device lead RN5_1.

Net named N567296 with device lead RN5_8.

Net named SIGN_2M_OUT with device leads RN26_4 and U47_119.

Net named N567481 with device lead RN26_5.

Net named FR_SYNC with device leads RN25_1 and U47_142.

Net named N567491 with device lead RN25_8.

Net named SIGN_2M_IN with device leads RN26_3 and U47_120.

Net named N567512 with device lead RN26_6.

Net named VOICE_2M_OUT with device leads RN26_2 and U47_123.

Net named N567512 with device lead RN26_7.

Net named VOICE_2M_IN with device leads RN26_1 and U47_124.

Net named N567532 with device lead RN26_8.

Net named SPARE1 with device leads R257_2, RN25_2, and U47_154.

Net named N567542 with device lead RN25_7.

Net named SPARE2 with device leads RN25_3 and U47_135.

Net named N567552 with device lead RN25_6.

Net named TEST_MODE with device leads RN25_4 and U47_141.

Net named N567562 with device lead RN25_5.

Net named AD_A11 with device lead RN6_4.

Net named N568012 with device lead RN6_5.

Net named AD_A10 with device lead RN6_3.

Net named N568014 with device lead RN6_6.

Net named AD_A9 with device lead RN6_2.

Net named N568016 with device lead RN6_7.

Net named AD_A8 with device lead RN6_1.

Net named N568018 with device lead RN6_8.

Net named AD_A15 with device lead RN7_4.

Net named N568959 with device lead RN7_5.

Net named AD_A14 with device lead RN7_3.

Net named N568961 with device lead RN7_6.

Net named AD_A13 with device lead RN7_2.

Net named N568963 with device lead RN7_7.

Net named AD_A12 with device lead RN7_1.

Net named N568965 with device lead RN7_8.

Net named N584464 with device leads R3123_2 and R3124_1.

Net named N584464_1073425 with device leads R3423_2 and R3424_1.

Net named N584464_1105703 with device leads R3223_2 and R3224_1.

Net named N584464_1075098 with device leads R3523_2 and R3524_1.

Net named N584464_1074559 with device leads R3623_2 and R3624_1.

Net named N584464_1073944 with device leads R3323_2 and R3324_1.

Net named N590875 with device lead U47_32.

Net named N599181 with device lead U47_54.

Net named N643423 with device lead U84_50.

Net named N655211_1074459 with device leads R3505_1 and R3510_2.

Net named N655211 with device leads R3305_1 and R3310_2.

Net named N655211_1105616 with device leads R3105_1 and R3110_2.

Net named N655223_1105607 with device leads R3205_1 and R3210_2.

Net named N655223 with device leads R3405_1 and R3410_2.

Net named N655223_1074458 with device leads R3605_1 and R3610_2.

Net named 35MCLKB0 with device leads R534_1 and U9_F8.

Net named N660823 with device leads R534_2 and U14_2.

Net named 35MCLKB1 with device lead R535_1.

Net named N660828 with device leads R535_2 and U14_3.

Net named 35MCLKB2 with device lead R536_1.

Net named N660837 with device leads R536_2 and U14_4.

Net named URCLK with device leads R613_1 and U10_E10.

Net named N662132 with device leads R613_2 and U11_3.

Net named UTCLK1 with device leads R614_1 and U9_B19.

Net named URCLK1 with device leads R615_1 and U9_E10.

Net named N662196 with device leads R614_2, R615_2, and U11_4.

Net named ASP_UTPCLK with device leads R616_1 and U46_V24.

Net named N662525 with device leads R616_2 and U11_6.

Net named TSTCLK2 with device lead R618_1.

Net named TSTCLK1 with device lead R617_1.

Net named N662562 with device leads R617_2, R618_2, and U11_7.

Net named CLK50MB with device leads R624_1 and U7_C12.

Net named CLK50MA with device leads R639_1 and U8_C12.

Net named N663028 with device leads R624_2 and R639_2.

Net named N687003_1075154 with device lead R3508_1.

Net named N687003_1105702 with device lead R3208_1.

Net named N687003_1074608 with device lead R3608_1.

Net named N687003 with device lead R3108_1.

Net named N687003_1073934 with device lead R3308_1.

Net named N687003_1073403 with device lead R3408_1.

Net named N704612 with device leads J17_16 (*) and R153_1.

Net named N705532 with device lead R187_1.

Net named N705538 with device lead R190_1.

Net named N705541 with device lead R190_2.

Net named N706027 with device lead R183_1.

Net named N706030 with device lead R183_2.

Net named N707027 with device lead R177_2.

Net named N707892 with device lead R177_1.

Net named N710691 with device lead R184_1.

Net named GNTR with device leads R285_1 and U11_11.

Net named N716079 with device lead R285_2.

Net named N732105 with device leads U57_3, U57_4, and U57_13.

Net named N732214 with device leads U56_1 and U57_6.

Net named N732503 with device leads U56_4 and U57_11.

Net named HDLC3 with device leads J16_130 (*), R226_1, and R227_1.

Net named N7326421 with device leads R226_2 and U58_3.

Net named N732938 with device leads R227_2 and U58_6.

Net named HCLK0 with device leads R240_1 and U46_M2.

Net named N734581 with device leads R240_2 and R241_1.

Net named N734653 with device lead R688_2.

Net named N892805 with device leads R239_2, U30_11, and U49_15.

Net named N893076 with device leads R238_2, R248_1, U30_10, U40_5, and U49_16.

Net named N893209 with device leads U39_5, U39_9, and U49_14.

Net named N2204058 with device leads R384_2 and R423_1.

Net named N2204058_1086547 with device leads R380_2 and R421_1.

Net named N2204058_1085927 with device leads R390_2 and R426_1.

Net named N2204058_1085048 with device leads R386_2 and R424_1.

Net named RXDATA1 with device leads R607_1, R609_1, and U46_Y24.

Net named N2262168 with device leads R607_2 and U9_F12.

Net named N2262168_1133880 with device leads R609_2 and U10_F12.

Net named RXDATA2 with device leads R551_1, R556_1, and U46_Y26.

Net named N2262173 with device leads R551_2 and U9_D13.

Net named N2262173_1133844 with device leads R556_2 and U10_D13.

Net named RXDATA5 with device leads R545_1, R547_1, and U46_AA24.

Net named N2262215 with device leads R545_2 and U9_E12.

Net named N2262215_1133892 with device leads R547_2 and U10_E12.

Net named N2298762 with device leads R600_2 and U9_R8.

Net named N2439987 with device leads R539_1 and U9_E13.

Net named N2439971_1089572 with device lead R539_2.

Net named RXDATAO with device leads R583_1, R584_1, and U46_W25.

Net named N2536432_1088461 with device leads R583_2 and U9_A13.

Net named N2536432 with device leads R584_2 and U10_A13.

Net named RXDATA3 with device leads R587_1, R588_1, and U46_Y25.

Net named N2536441 with device leads R587_2 and U9_A12.

Net named N2536441_1133879 with device leads R588_2 and U10_A12.

Net named RXDATA4 with device leads R575_1, R577_1, and U46_AA26.

Net named N2536444_1088456 with device leads R575_2 and U9_B12.

Net named N2536444 with device leads R577_2 and U10_B12.

Net named RXDATA6 with device leads R565_1, R566_1, and U46_Y23.

Net named N2536450 with device leads R565_2 and U9_D11.

Net named N2536450_1133883 with device leads R566_2 and U10_D11.

Net named RXDATA/ with device leads R599_1, R601_1, and U46_AA25.

Net named N2536453_1088312 with device leads R599_2 and U9_A11.

Net named N2536453 with device leads R601_2 and U10_A11.

Net named N2714077_1085933 with device leads R389_2 and R420_1.

Net named N2714077 with device leads R383_2 and R417_1.

Net named N2714077_1085053 with device leads R385_2 and R418_1.

Net named N2714077_1086549 with device leads R379_2 and R415_1.

Net named N2847142_1088252 with device lead R663_1.

Net named N2847142 with device lead R693_1.

Net named N2847154_1088268 with device lead R662_1.

Net named N2847154 with device lead R692_1.

Net named N3152729_1089786 with device lead R445_1.

Net named N3152729 with device lead R448_1.

Net named N3197439_1089789 with device lead R444_1.

Net named N3197439 with device lead R447_1.

Net named N3198170_1089792 with device lead R443_1.

Net named N3198170 with device lead R446_1.

Net named ARDY with device leads R665_1 and U7_W25.

Net named N3672092 with device leads R665_2 and U9_P13.

Net named N3690541 with device lead U9_U2.

Net named N3690541_1133927 with device lead U10_U2.

Net named N3690544_1133928 with device lead U10_V1.

Net named N3690544 with device lead U9_V1.

Net named N3690547 with device lead U9_W2.

Net named N3690550 with device lead U9_W3.

Net named N3690550_1133930 with device lead U10_W3.

Net named N3778043_1085640 with device leads R144_1, R338_1, R339_1, and R340_1.

Net named N3778043 with device leads R142_1, R332_1, R333_1, and R334_{—1.}

Net named N3778043_1089291 with device leads R140_1, R326_1, R327_1, and R328_1.

Net named N3778043_1084794 with device leads R146_1, R344_1, R345_1, and R346_1.

Net named N3778043_1087024 with device leads R138_1, R320_1, R321_1, and R322_1.

Net named N3778043_1085278 with device leads R148_1, R350_1, R351_1, and R352_1.

Net named N3778053_1087025 with device leads R139_2, R322_2, R323_2, R324_1, and R325_1.

Net named N3778053_1085276 with device leads R149_2, R352_2, R353_2, R354_1, and R355_1.

Net named N3778053_1084795 with device leads R147_2, R346_{13 2, R347}_2, R348_1, and R349_1.

Net named N3778053_1085642 with device leads R145_2, R340_2, R341_2, R342_1, and R343_1.

Net named N3778053 with device leads R143_2, R334_2, R335_2, R336_1, and R337_1.

Net named N3778053_1089292 with device leads R141_2, R328_2, R329_2, R330_1, and R331_1.

Net named N3778699_1086538 with device lead R55_1.

Net named N3778699_1085037 with device lead R73_1.

Net named N3778699 with device lead R85_1.

Net named N3778699_1086701 with device lead R67_1.

Net named N3778705 with device lead R80_1.

Net named N3778705_1086687 with device lead R62_1.

Net named N3778705_1086536 with device lead R50_1.

Net named N3778705_1085032 with device lead R68_1.

Net named N3778761_1086693 with device lead R64_1.

Net named N3778761 with device lead R82_1.

Net named N3778761_1086529 with device lead R52_1.

Net named N3778761_1085033 with device lead R70_1.

Net named N3778794_1086688 with device lead R66_1.

Net named N3778794 with device lead R84_1.

Net named N3778794_1086539 with device lead R54_1.

Net named N3778794_1085034 with device lead R72_1.

Net named N3778814 with device lead R83_1.

Net named N3778814_1086532 with device lead R53_1.

Net named N3778814_1085035 with device lead R71_1.

Net named N3778814_1086698 with device lead R65_1.

Net named N3802343_1086541 with device lead R51_1.

Net named N3802343_1085036 with device lead R69_1.

Net named N3802343_1086714 with device lead R63_1.

Net named N3802343 with device lead R81_1.

Net named N3896449 with device lead R76_1.

Net named N3896449_1086697 with device lead R58_1.

Net named N3896453_1085926 with device leads R388_2 and R425_1.

Net named N3896453 with device leads R382_2 and R422_1.

Net named N3896481 with device lead R78_1.

Net named N3896481_1086692 with device lead R60_1.

Net named N3896485 with device lead R75_1.

Net named N3896485_1086696 with device lead R57_1.

Net named N3896537_1086708 with device lead R56_1.

Net named N3896537 with device lead R74_1.

Net named N3896605 with device leads R387_2 and R419_1.

Net named N3896605_1086675 with device leads R381_2 and R416_1.

Net named N3896689 with device lead R77_1.

Net named N3896689_1086690 with device lead R59_1.

Net named N3896697_1086705 with device lead R61_1.

Net named N3896697 with device lead R79_1.

Net named N3944775_1088300 with device lead R662_2.

Net named N3944775 with device lead R692_2.

Net named N3945007_1088293 with device lead R663_2.

Net named N3945007 with device lead R693_2.

Net named N3945011_1088283 with device lead R648_1.

Net named N3945011 with device lead R682_1.

Net named N3945059 with device lead R681_1.

Net named N3945059_1088302 with device lead R647_1.

Net named N3945091_1088279 with device lead R647_2.

Net named N3945091 with device lead R681_2.

Net named N3945163 with device lead R682_2.

Net named N3945163_1088301 with device lead R648_2.

Net named MDMA_RST with device leads R642_1, U10_P5, and U80_91.

Net named N3949353 with device leads R642_2 and U10_V3.

Net named MDMB_RST with device leads R641_1, U9_P5, and U80_92.

Net named N3949353_1088463 with device leads R641_2 and U9_V3.

Net named N4044611_1087298 with device lead R335_1.

Net named N4044611_1086974 with device lead R323_1.

Net named N4044611_1084761 with device lead R347_1.

Net named N4044611_1089233 with device lead R329_1.

Net named N4044611_1085240 with device lead R353_1.

Net named N4044611 with device lead R341_1.

Net named N4051797 with device lead R4_2.

Net named N4051797_1087314 with device lead R3_2.

Net named N4051801_1087310 with device lead R1_2.

Net named N4051801 with device lead R5_2.

Net named N4051875 with device lead R6_2.

Net named N4051875_1087309 with device lead R2_2.

Net named N6938790 with device lead R3124_2.

Net named N6947000 with device lead R3524_2.

Net named N6947000_1074003 with device lead R3324_2.

Net named N6947520 with device lead R3424_2.

Net named N6947800 with device lead R3624_2.

Net named N6967740 with device lead R3224_2.

Net named N14385821 with device leads U38_4 and U39_10.

Net named UTCLK with device leads R611_1 and U10_B19.

Net named DBG_CLK with device leads R187_2 and R612_1.

Net named N14418765 with device leads R611_2, R612_2, and U11_2.

Net named 35MCLKB3 with device lead R537_1.

Net named N14419530 with device leads R537_2 and U14_6.

Net named N14421600 with device lead U69_50.

Net named N14822169 with device lead U56_11.

Net named J1_127 with device leads R299_1 and U30_14.

Net named N71033563 with device leads J17_127(*) and R299_2.

Net named J1_129 with device leads R300_1 and U39_6.

Net named N71033564 with device leads J17_129(*) and R300_2.

Net named J1_131 with device leads R301_1 and U30_7.

Net named N71033565 with device leads J17_131(*) and R301_2.

Net named J1_133 with device leads R302_1 and U38_8.

Net named N71033566 with device leads J17_133(*) and R302_2.

Net named NBAD_ALE_A with device lead U47_42.

Net named NBAD_ALE_B with device lead U47_107.

Net named NBAD_RD_A with device lead U47_40.

Net named NBAD_RD_B with device lead U47_93.

Net named NBAD_WRDA with device lead U47_39.

Net named NBAD_WR_B with device lead U47_98.

Net named N563258 with device lead RN13_4.

Net named NBINT_OUT with device lead RN13_5.

Net named NBRESET with device leads U47_44 and U74_6.

Net named NCON with device leads U38_9, U39_13, U40_1, U40_4, U40_10, U40_13, and U49_18.

Net named NCS_RD_A with device leads R275_2 and U47_11.

Net named NCS_RD_B with device leads R229_2 and U47_43.

Net named NCS_WR_A with device lead U47_14.

Net named NCS_WR_B with device lead U47_48.

Net named N144122301 with device leads R319_1 and U40_3.

Net named NINIT with device lead R319_2.

Net named N14415619 with device leads R315_1 and U39_11.

Net named NINIT2 with device lead R315_2.

Net named NINIT_1078391 with device leads R233_2 and U47_77.

Net named NINT_OUT with device leads R186_1 and U47_122.

Net named NOE_C_TST with device lead U47_84.

Net named PRGM with device leads R247_1 and U47_106.

Net named NRESET with device leads R247_2 and R253_2.

Net named NRESET_626093 with device lead U74_5.

Net named NRES_C_TST with device lead U47_82.

Net named NT11 with device lead U46_AC2.

Net named NT12 with device lead U46_AC1.

Net named NT13 with device lead U46_AB4.

Net named NT14 with device lead U46_AA1.

Net named NT15 with device lead U46_Y4.

Net named NT16 with device lead U46_AB2.

Net named NT17 with device lead U46_AB1.

Net named NT18 with device lead U46_AA3.

Net named NTR_REFA with device leads U10_F5 and U11_19.

Net named NTR_REFB with device leads U9_F5 and U11_18.

Net named NVFR0 with device leads R3226_1 and R3230_2.

Net named NVFR0_1125166 with device leads R3626_1 and R3630_2.

Net named NVFR0_1125148 with device leads P3426_1 and R3430_2.

Net named NVFR1 with device leads R3126_1 and P3130_2.

Net named NVFR1_1125163 with device leads R3526_1 and R3530_2.

Net named NVFR1_1125155 with device leads R3326_1 and R3330_2.

Net named NVFX0 with device lead R3206_2.

Net named NVFX0_1125154 with device lead R3406_2.

Net named NVFX0_1125160 with device lead R3606_2.

Net named NVFX1_1125162 with device lead R3506_2.

Net named NVFX1 with device lead R3106_2.

Net named NVFX1_1125153 with device lead R3306_2.

Net named PD6 with device leads J16_47(*) and R669_2.

Net named P01 with device leads R38_1 and R688_1.

Net named POTS_GRN with device leads U47_111 and U80_45.

Net named POTS_RED with device leads U47_114 and U80_46.

Net named POTS_WT with device leads U47_115 and U80_47.

Net named PP1 with device leads RN31_1 and U46_AD26.

Net named PP2 with device leads RN31_2 and U46_AC25.

Net named PP3 with device leads RN31_3 and U46_AC24.

Net named PP4 with device leads RN31_4 and U46_AC26.

Net named FP5 with device leads RN31_5 and U46_AB25.

Net named PP6 with device leads RN31_6 and U46_AB23.

Net named PP7 with device leads RN31_7 and U46_AB24.

Net named PP8 with device leads RN31_8 and U46_AB26.

Net named PP39 with device leads RN36_7 and U46_J2.

Net named PP41 with device leads RN45_1 and U46_H2.

Net named PP43 with device leads RN45_3 and U46_G2.

Net named PP45 with device leads RN45_5 and U46_E2.

Net named PP47 with device leads RN45_7 and U46_D2.

Net named PP49 with device leads RN46_1 and U46_C2.

Net named PSG with device lead R3636_2.

Net named PSG_1073439 with device lead R3436_2.

Net named PSG_1073973 with device lead R3336_2.

Net named PSG_1075127 with device lead R3536_2.

Net named PSG_1105705 with device lead R3236_2.

Net named PSG_1127470 with device lead R3136_2.

Net named QDR with device lead U10_R12.

Net named QDR 1088329 with device lead U9_P12.

Net named QDX with device lead U9_N13.

Net named RDATD0 with device leads U46_A5 and U84_52.

Net named RDATD1 with device leads U46_B5 and U84_53.

Net named RDATD2 with device leads U46_C7 and U84_56.

Net named RDATD3 with device leads U46_A6 and U84_57.

Net named RDATD4 with device leads U46_D7 and U84_58.

Net named RDATD5 with device leads U46_B6 and U84_59.

Net named RDATD6 with device leads U46_C8 and U84_62.

Net named RDATD7 with device leads U46_A7 and U84_63.

Net named RDATD8 with device leads U46_D8 and U84_68.

Net named RDATD9 with device leads U46_B7 and U84_69.

Net named RDATD10 with device leads U46_C9 and U84_72.

Net named RDATD11 with device leads U46_A8 and U84_73.

Net named RDATD12 with device leads U46_B8 and U84_74.

Net named RDATD13 with device leads U46_A9 and U84_75.

Net named RDATD14 with device leads U46_C10 and U84_78.

Net named RDATD15 with device leads U46_B9 and U84_79.

Net named RDATD16 with device leads U46_D10 and U84_2.

Net named RDATD17 with device leads U46_A10 and U84_3.

Net named RDATD18 with device leads U46_C11 and U84_6.

Net named RDATD19 with device leads U46_B10 and U84_7.

Net named RDATD20 with device leads U46_D12 and U84_8.

Net named RDATD21 with device leads U46_A11 and U84_9.

Net named RDATD22 with device leads U46_C12 and U84_12.

Net named RDATD23 with device leads U46_B11 and U84_13.

Net named RDATD24 with device leads U46_A12 and U84_18.

Net named RDATD25 with device leads U46_C13 and U84_19.

Net named RDATD26 with device leads U46_B12 and U84_22.

Net named RDATD27 with device leads U46_C14 and U84_23.

Net named RDATD28 with device leads U46_A13 and U84_24.

Net named RDATD29 with device leads U46_D13 and U84_25.

Net named RDATD30 with device leads U46_B13 and U84_28.

Net named RDATD31 with device leads U46_C15 and U84_29.

Net named RDATU0 with device leads U46_AC20 and U69_52.

Net named RDATU1 with device leads U46_AE21 and U69_53.

Net named RDATU2 with device leads U46_AD19 and U69_56.

Net named RDATU3 with device leads U46_AF20 and U69_57.

Net named RDATU4 with device leads U46_AC19 and U69_58.

Net named RDATU5 with device leads U46_AE20 and U69_59.

Net named RDATU6 with device leads U46_AD18 and U69_62.

Net named RDATU7 with device leads U46_AF19 and U69_63.

Net named RDATU8 with device leads U46_AE19 and U69_68.

Net named RDATU9 with device leads U46_AF18 and U69_69.

Net named RDATU10 with device leads U46_AD17 and U69_72.

Net named RDATU11 with device leads U46_AE18 and U69_73.

Net named RDATU12 with device leads U46_AC17 and U69_74.

Net named RDATU13 with device leads U46_AF17 and U69_75.

Net named RDATU14 with device leads U46_AD16 and U69_78.

Net named RDATU15 with device leads U46_AE17 and U69_79.

Net named RDATU16 with device leads U46_AC15 and U69_2.

Net named RDATU17 with device leads U46_AF16 and U69_3.

Net named RDATU18 with device leads U46_AD15 and U69_6.

Net named RDATU19 with device leads U46_AE16 and U69_7.

Net named RDATU20 with device leads U46_AF15 and U69_8.

Net named RDATU21 with device leads U46_AD14 and U69_9.

Net named RDATU22 with device leads U46_AE15 and U69_12.

Net named RDATU23 with device leads U46_AD13 and U69_13.

Net named RDATU24 with device leads U46_AF14 and U69_18.

Net named RDATU25 with device leads U46_AC14 and U69_19.

Net named RDATU26 with device leads U46_AE14 and U69_22.

Net named RDATU27 with device leads U46_AD12 and U69_23.

Net named RDATU28 with device leads U46_AF13 and U69_24.

Net named RDATU29 with device leads U46_AC12 and U69_25.

Net named RDATU30 with device leads U46_AE13 and U69_28.

Net named RDATU31 with device leads U46_AD11 and U69_29.

Net named RINGER with device leads R3102_2, R3105_2, R3202_2, R3205_2, R3302_2, R3305_2, R3402_2, R3405_2 , R3502_2, R3505_2, R3602_2, R3605_2.

Net named RINGX with device lead R3225_2.

Net named RINGX_1073433 with device lead R3425_2.

Net named RINGX_1073987 with device lead R3325_2.

Net named RINGX_1074557 with device lead R3625_2.

Net named RINGX_1075101 with device lead R3525_2.

Net named RINGX_1127471 with device lead R3125_2.

Net named RXADDR0 with device leads U9_D15, U10_D15, and U46_AF23.

Net named RXADDR1 with device leads U9_E15, U10_E15, and U46_AC22.

Net named RXADDR2 with device leads U9_A15, U10_A15, and U46_AE23.

Net named RXADDR3 with device leads U9_A14, U10_A14, and U46_AD21.

Net named RXAN with device leads R112_1, R124_2, and R354_2.

Net named RXAN_1086386 with device leads R100_1, R118_2, and R336_2.

Net named RXAP with device leads R109_1, R123_2, and R351_2.

Net named RXAP_1086408 with device leads R97_1, R117_2, and R333_2.

Net named RXBN with device leads R108_1, R122_2, and R348_2.

Net named RXBN_1086403 with device leads R96_1, R116_2, and R330_2.

Net named RXBP with device leads R105_1, R121_2, and R345_2.

Net named RXBP_1086373 with device leads R93_1, R115_2, and R327_2.

Net named RXCLAV0 with device leads RN3_8, U9_B11, U10_B11, and U46_AE26.

Net named RXCN with device leads R92_1, R114_2, and R324_2.

Net named RXCN_1082372 with device leads R104_1, R120_2, and R342_2.

Net named RXCP with device leads R89_1, R113_2, and R321_2.

Net named RXCP_1082375 with device leads R101_1, R119_2, and R339_2.

Net named RXENB0 with device leads R279_2, U9_E11, U10_E11, and U46_AF22.

Net named RXSOC with device leads U9_F11, U10_F11, and U46_AD22.

Net named SCAN_EN with device lead U9_M5.

Net named SCAN_EN 1084196 with device lead U10_M5.

Net named SEL_DLC_AB with device lead U13_5.

Net named SEL_D_A with device leads R220_2 and U47_8.

Net named SEL_D_B with device leads R222_2 and U47_9.

Net named SEL_S_A with device leads R221_2 and U47_4.

Net named SEL_S_B with device leads R214_2 and U47_10.

Net named SENCEAN with device leads R124_1 and R390_1.

Net named SENCEAN_1086384 with device leads R118_1 and R384_1.

Net named SENCEAP with device leads R123_1 and R389_1.

Net named SENCEAP_1086382 with device leads R117_1 and R383_1.

Net named SENCEBN with device leads R122_1 and R388_1.

Net named SENCEBN_1086407 with device leads R116_1 and R382_1.

Net named SENCEBP with device leads R121_1 and R387_1.

Net named SENCEBP_1086376 with device leads R115_1 and R381_1.

Net named SENCECN with device leads R120_1 and R386_1.

Net named SENCECN_1086402 with device leads R114_1 and R380_1.

Net named SENCECP with device leads R119_1 and R385_1.

Net named SENCECP_1086411 with device leads R113_1 and R379_1.

Net named SET_ALC_RQ with device leads R180_2 and U47_116.

Net named N550930 with device leads R264_1 and R265_1.

Net named SLIF_A2 with device leads R264_2 and U46_L2.

Net named N550927 with device leads R242_1 and R243_1.

Net named SLIF_B2 with device leads R242_2 and U46_F2.

Net named N556822 with device leads RN20_4 and U47_129.

Net named SLOT_ID0 with device leads RN20_5 and U49_5.

Net named N611589 with device leads RN20_3 and U47_128.

Net named SLOT_ID1 with device leads RN20_6 and U49_4.

Net named N611582 with device leads RN20_2 and U47_126.

Net named SLOT_ID2 with device leads RN20_7 and U49_3.

Net named N611557 with device leads RN20_and U47_125.

Net named SLOT_ID3 with device leads RN20_8 and U49_2.

Net named ST_C_A with device lead U47_162.

Net named ST_TST with device lead U47_100.

Net named N708478 with device leads R175_1 and R176_1.

Net named SYSCLK_IN with device leads R175_2 and U46_U26.

Net named TAN with device leads J17_112(*) and R298_1.

Net named TBD0 with device lead RN18_1.

Net named TBD1 with device lead RN18_2.

Net named TBD2 with device lead RN18_3.

Net named TBD3 with device lead RN18_4.

Net named TBD4 with device lead RN19_1.

Net named TBD5 with device lead RN19_2.

Net named TBD6 with device lead RN19_3.

Net named TBD7 with device lead RN19_4.

Net named STDI with device leads R13_2, R15_1, and U49_17.

Net named QBS_TDO_1088323 with device leads R667_1 and U9_R5.

Net named TDO_5 with device leads R15_2 and R667_2.

Net named TEST_EN with device lead U9_R7.

Net named TEST_EN_1084186 with device lead U10_R7.

Net named TEST_PLL with device lead U9_D9.

Net named TEST_PLL_1084188 with device lead U10_D9.

Net named TIPX with device lead R3617_2.

Net named TIPX_1073412 with device lead R3417_2.

Net named TIPX_1073959 with device lead R3317_2.

Net named TIPX_1075128 with device lead R3517_2.

Net named TIPX_1105717 with device lead R3217_2.

Net named TIPX_1127473 with device lead R3117_2.

Net named TST_IN1 with device lead R3137_2.

Net named TST_IN2 with device lead P3237_2.

Net named TST_IN3 with device lead R3337_2.

Net named TST_IN4 with device lead R3437_2.

Net named TST_IN5 with device lead R3537_2.

Net named TST_IN6 with device lead R3637_2.

Net named TST_OUT_IN1 with device lead P3132_2.

Net named TST_OUT_IN2 with device lead R3232_2.

Net named TST_OUT_IN3 with device lead R3332_2.

Net named TST_OUT_IN4 with device lead R3432_2.

Net named TST_OUT_IN5 with device lead R3532_2.

Net named TST_OUT_IN6 with device lead R3632_2.

Net named TXADDR0 with device leads U9_G13, U10_G13, and U46_U24.

Net named TXADDR1 with device leads U9_G19, U10_G19, and U46_T25.

Net named TXADDR2 with device leads U9_G16, U10_G16, and U46_U23.

Net named TXADDR3 with device leads U9_G15, U10_G15, and U46_U25.

Net named TXAN with device lead R149_1.

Net named TXAN_1086380 with device lead R143_1.

Net named TXAP with device lead R148_2.

Net named TXAP_1086412 with device lead R142_2.

Net named TXBN with device lead R147_1.

Net named TXBN_1086372 with device lead R141_1.

Net named TXBP with device lead R146_2.

Net named TXBP_1086406 with device lead R140_2.

Net named TXCLAV0 with device leads RN3_4, U9_A17, U10_A17, and U46_L24.

Net named TXCN with device lead R139_1.

Net named TXCN_1082374 with device lead R145_1.

Net named TXCP with device lead R144_2.

Net named TXCP_1086391 with device lead R138_2.

Net named TXENBO with device leads R290_2, U9_B17, U10_B17, and U46_V26.

Net named TXSOC with device leads U9_A16, U10_A16, and U46_V23.

Net named URA4_1088308 with device leads R541_2 and U9_E14.

Net named UTA4 with device leads R579_2 and U9_G14.

Net named VBAT with device lead R3136_1.

Net named VBAT_1073392 with device lead R3436_1.

Net named VBAT_1073986 with device lead R3336_1.

Net named VBAT_1074562 with device lead R3636_1.

Net named VBAT_1075102 with device lead R3536_1.

Net named VBAT_1105674 with device lead R3236_1.

Net named VBAT_PS with device leads R435_2, P437_1, R3133_1, R3233_1, R3333_1, R3433_1, R3533_1, and R3633_1.

Net named VEE with device leads R455_1 and R459_1.

Net named VMID_REFA with device lead R445_2.

Net named VMID_REFA_1082378 with device lead R448_2.

Net named VMID_REFB with device lead R444_2.

Net named VMID_REFB_1082377 with device lead R447_2.

Net named VMID_REFC with device lead R443_2.

Net named VMID_REFC_1082379 with device lead R446_2.

Net named VRX0_1125158 with device lead R3630_1.

Net named VRX0_1125152 with device lead R3430_1.

Net named VRX0 with device lead R3230_1.

Net named VRX1_1125149 with device lead R3330_1.

Net named VRX1_1125157 with device lead R3530_1.

Net named VRX1 with device lead R3130_1.

Net named VSYNC with device lead U47_89.

Net named VSYNC_S with device leads R16_1 and U47_138.

Net named VTX with device lead R3112_2.

Net named VTX_1073388 with device lead R3412_2.

Net named VTX_1073965 with device lead R3312_2.

Net named VTX_1074596 with device lead R3612_2.

Net named VTX_1075155 with device lead R3512_2.

Net named VTX_1105690 with device lead R3212_2.

Net named WEO with device lead J16_48(*).

Net named XADP_CON0 with device lead U47_160.

Net named XADP_CON1 with device lead U47_108.

Net named XADP_CON2 with device lead U47_207.

Net named XBD0 with device lead RN30_4.

Net named XBD1 with device lead RN30_3.

Net named XBD2 with device lead RN30_2.

Net named XBD3 with device lead RN30_1.

Net named XBD4 with device lead RN33_4.

Net named XBD5 with device lead RN33_3.

Net named XBD6 with device lead RN33_2.

Net named XBD7 with device lead RN33_1.

Net named XBD8 with device lead RN34_4.

Net named XBD9 with device lead R34_3.

Net named XBD10 with device lead RN34_2.

Net named XBD11 with device lead RN34_1.

Net named XBD12 with device lead RN41_4.

Net named XBD13 with device lead RN41_3.

Net named XBD14 with device lead RN41_2.

Net named XBD15 with device lead RN41_1.

Net named XBE0 with device leads U7_C8 and U9_D16.

Net named XBE1_1088311 with device leads U7_A6 and U9_D16.

Net named XBE2 with device leads U7_D8 and U9_B18.

Net named XBE3 with device leads U7_C7 and U9_D18.

Net named XCNTL_WE with device leads U7_B10 and U9_B14.

Net named XCS_DSPMINUS with device leads U7_A10 and U9_D14.

Net named XCS_FLASHMINUS with device lead U9_F6.

Net named XD0 with device leads U7_K23 and U9_G1.

Net named XD1 with device leads U7_J24 and U9_G2.

Net named XD2 with device leads U7_H25 and U9_G4.

Net named XD3_1088326 with device leads U7_G26 and U9_E1.

Net named XD4 with device leads U7_J23 and U9_F2.

Net named XD5 with device leads U7_G25 and U9_F4.

Net named XD6 with device leads U7_F26 and U9_D1.

Net named XD7 with device leads U7_H23 and U9_E2.

Net named XD8 with device leads U7_G24 and U9_E4.

Net named XD9 with device leads U7_F25 and U9_D2.

Net named XD10_1088457 with device leads U7_E26 and U9_B1.

Net named XD11 with device leads U7_F24 and U9_B3.

Net named XD12_1088313 with device leads U7_E25 and U9_C2.

Net named XD13 with device leads U7_B22 and U9_A2.

Net named XD14 with device leads U7_D20 and U9_A3.

Net named XD15 with device leads U7_A22 and U9_D4.

Net named XD16 with device leads U7_B21 and U9_B4.

Net named XD17_1088444 with device leads U7_C20 and U9_D5.

Net named XD18_1088325 with device leads U7_D19 and U9_A4.

Net named XD19_1088378 with device leads U7_A21 and U9_B5.

Net named XD20 with device leads U7_C19 and U9_D6.

Net named XD21 with device leads U7_D18 and U9_B6.

Net named XD22_1088386 with device leads U7_A20 and U9_A6.

Net named XD23 with device leads U7_C18 and U9_D7.

Net named XD24 with device leads U7_D17 and U9_B7.

Net named XD25 with device leads U7_B18 and U9_A8.

Net named XD26 with device leads U7_A18 and U9_D8.

Net named XD27_1088348 with device leads U7_D16 and U9_B8.

Net named XD28_1088332 with device leads U7_B17 and U9_A9.

Net named XD29_1088428 with device leads U7_A17 and U9_B9.

Net named XD30 with device leads U7_B16 and U9_A10.

Net named XD31_1088303 with device leads U7_D15 and U9_D10.

Net named XWR_OE with device leads U7_D1 and U9_B15.

Net named ZEROCUR1 with device lead R4877_1.

Net named ZEROCUR2 with device lead R4878_1.

Net named ZEROCUR3 with device lead R4879_1.

Net named ZEROCUR4 with device lead R4880_1.

Net named ZEROCUR5 with device lead R4883_1.

Net named ZEROCUR6 with device lead R4884_1.

Faults on the following unconnected device leads are not covered:

Unconnected device leads J16_13(*), J16_14(*), J16_15(*), J16_16(*), J16_17(*), J16_18(*), J16_19(*), J16_20(*), J16_21(*), J16_22(*), J16_23(*), J16_24(*), J16_27(*), J16_28(*), J16_29(*), J16_30(*), J16_31(*), J16_32(*), J16_33(*), J16_36(*), J16 37(*), J16_38(*), J16_39(*), J16_44(*), J16_46(*), J16_49(*), J16_50(*), J16_51(*), J16_52(*), J16_55(*), J16_56(*), J16_57(*), J16_58(*), J16_59(*), J16_60(*), J16_61(*), J16_62(*), J16_65(*), J16_66(*), J16_68(*), J16_69(*), J16_71(*), J16_73(*), J16_75(*), J16_77(*), J16_79(*), J16_80(*), J16_81(*), J16_83(*), J16_85(*), J16_86(*), J16_87(*) J16_89(*), J16_91(*), J16_93(*), J16_95(*), J16_98(*), J16_100(*), J16_101(*), J16_102(*), J16_105(*), J16_106(*), J16_107(*), J16_108(*), J16_109(*), J16_110(*), J16_111(*), J16_112(*), J16_115(*), J16_116(*), J16_118(*), J16_119(*), J16_120(*), J16_121(*), J16_122(*), J16_125(*), J16_126(*), J16_127(*), J16_128(*), J16_129(*), J16_132(*), J16_134(*), J16_135(*), J16_136(*), J16_137(*), J16_138(*), J16_139(*), J16_140(*), J17_14(*), J17_17(*), J17_19(*), J17_21(*), J17_25(*), J17_27(*), J17_29(*), J17_31(*), J17_35(*), J17_37(*), J17_39(*), J17_41(*), J17_45(*), J17_47(*), J17_49(*), J17_51(*), J17_55(*), J17_58(*), J17_60(*), J17_62(*), J17_66(*), J17_68(*), J17_70(*), J17_72(*), J17_76(*), J17_78(*), J17_80(*), J17_82(*), J17 86(*), J17_88(*), J17_90(*), J17_92(*), J17_96(*), J17_97(*), J17_98(*), J17_99(*), J17_100(*), J17_101(*), J17_102(*), J17_105(*), J17_106(*), J17_107(*), J17_108(*), J17_109(*), J17_110(*), J17_111(*), J17_115(*), J17_116(*), J17_117(*), J17_118(*), J17_119(*), J17_120(*), J17_121(*), J17_122(*), J17_125(*), J17_126(*), J17_128(*), J17_130(*), J17_132(*), J17_134(*), J17_136(*), J17_137(*), J17_138(*), J17_140(*), R608_1, R610_1, RN1_8, RN2_5, RN2_6, RN2_7, RN2_8, RN4_5, RN4_6, RN4_7, RN4_8, RN10_5, RN10_6, RN10_7, RN10_8, RN38_1, RN46_7, RN46_8, RN48_2, U4_6, U4_11, U9_P8, U9_R14, U9_W7, U10_P8, U11_13, U11_14, U11_15, U11_17, U13_8, U13_11, U14_7, U14_13, U30_13, U38_2, U38_6, U38_10, U38_12, U39_3, U47_47, U47_56, U47_57, U47_58, U47_59, U47_61, U47_62, U47_64, U47_75, U47_76, U47_80, U47_88, U47_90, U47_92, U47_94, U47_95, U47_97, U47_99, U47_136, U47_137, U47_144, U47_145, U47_146, U47_147, U47_148, U47_149, U47_150, U47_151, U47_152, U47_159, U47_161, U47_163, U47_164, U47_165, U47_166, U47_167, U47_168, U47_169, U47_171, U47_172, U47_174, U47_175, U47_176, U47_177, U47_178, U47_179, U47_180, U47_181, U47_184, U47_185, U47_186, U47_187, U47_188, U47_189, U47_194, U47_196, U47_197, U47_201, U47_202, U47_203, U56_8, U57_8, U68_3, U68_8, U68_11, U69_16, U69_38, U69_39, U69_42, U69_43, U69_66, U74_12, U80_26, U84_16, U84_38, U84_39, U84_42, U84_43, and U84_66.

Fault coverage class 6 nets (covered by TAPIT):

Net named BPTCK with tester pin $CTCK and device lead U49_9.

Net named BPTDI with tester pin $CTDI and device lead U49_11.

Net named BPTDO with tester pin $CTDO and device lead U49_8.

Net named BPTMS with tester pin $CTMS and device lead U49_10.

Net named CCLK_1090531 with device lead U80_74.

Net named CPU_INIT with device leads J16_45(*), R289_2, and U80_36.

Net named DONE_527779 with device leads J16_41(*), R288_1, and U80_50.

Net named HCLK0N with device leads R241_2 and U46_L1.

Net named N02622_1088257 with device lead U7_C13.

Net named N02622 with device lead U8_C13.

Net named N85388 with device leads R260_1 and U46_C5.

Net named N414847 with device lead U46_N2.

Net named N417754 with device leads R262_2 and U46_P2.

Net named N423101 with device leads R246_1 and U46_N1.

Net named N414902 with device leads R266_1 and U46_L3.

Net named N556407 with device lead R266_2.

Net named N665509 with device lead U46_A4.

Net named N2439987_1084184 with device leads R540_1 and U10_E13.

Net named N2439971 with device lead R540_2.

Net named N2547978_1088271 with device lead U7_C15.

Net named N2547978 with device lead U8_C15.

Net named N2547983 with device lead U8_D12.

Net named N2547983_1088272 with device lead U7_D12.

Net named J1_135 with device leads R170_2, R303_1, RN1_7, U39_8, and U46_B4.

Net named N71033567 with device leads J17_135(*) and R303_2.

Net named NTRST with device leads R694_1, R695_1, U7_AC7, U8_AC7, U9_P7, and U10_P7.

Net named PRGMN with device leads R18_1, R24_1, and U80_52.

Net named PORESET with device leads R24_2, R152_1, and R153_2.

Net named PP26 with device leads RN37_2 and U46_R4.

Net named PP28 with device leads RN37_4 and U46_V2.

Net named PP30 with device leads RN37_6 and U46_Y2.

Net named PP32 with device leads RN37_8 and U46_T3.

Net named PP34 with device leads RN36_2 and U46_W2.

Net named PP36 with device leads RN36_4 and U46_W4.

Net named PP38 with device leads RN36_6 and U46_H1.

Net named PP40 with device leads RN36_8 and U46_G1.

Net named PP42 with device leads RN45_2 and U46_F1.

Net named PP44 with device leads RN45_4 and U46_D1.

Net named PP46 with device leads RN45_6 and U46_C1.

Net named PP48 with device leads RN45_8 and U46_B1.

Net named DSP_TDO with device leads R622_1 and U7_AE6.

Net named QBS_TDI with device leads R622_2 and U9_T5.

Net named DSP_TDO_1134008 with device leads R625_1 and U8_AE6.

Net named QBS_TDI_1133932 with device leads R625_2 and U10_T5.

Net named SLIF_A1 with device lead U46_P1.

Net named SLIF_A3 with device leads R265_2 and U46_K1.

Net named SLIF_B1 with device lead U46_R1.

Net named SLIF_B3 with device leads R243_2 and U46_E1.

Net named TCK1 with device leads U30_2 and U46_A3.

Net named TCK2 with device leads U30_3, U47_7, and U80_5.

Net named TCLKR with device leads R548_1 and U8_AE5.

Net named QBS_TCK with device leads R633_1, R645_1, and U10_V4.

Net named TCK3 with device leads R548_2, R645_2, and U30_4.

Net named TCLKR_1088280 with device leads R546_1 and U7_AES.

Net named QBS_TCK_1088324 with device leads R632_1, R643_1, and U9_V4.

Net named TCK4 with device leads R546_2, R643_2, and U30_6.

Net named TDI_2 with device leads R168_1, R272_2, and U47_6.

Net named TDO_1 with device leads R168_2 and U46_C6.

Net named TDI_3 with device leads R35_2, R270_1, and U80_4.

Net named TDO_2 with device leads R270_2 and U47_157.

Net named TDI_4 with device leads R33_1, R683_2, and U8_AF5.

Net named TDO_3 with device leads R33_2 and U80_76.

Net named TDI_5 with device leads R675_2, R676_1, and U7_AF5.

Net named QBS_TDO with device leads R677_1 and U10_R5.

Net named TDO_4 with device leads R676_2 and R677_2.

Net named TMS1 with device leads U30_19 and U46_D5.

Net named TMS2 with device leads U30_18, U47_16, and U80_6.

Net named TMS3 with device leads U8_AD7, U10_W5, and U30_17.

Net named TMS4 with device leads U7_AD7, U9_W5, and U30_15.

Net named UTTRI with device leads R174_1 and U46_B3.

Net named VCC3 with tester pin $CTRST and device leads J16_2(*), J16_4(*), J16_6(*), J17_2(*), J17_4(*), J17_6(*), R13_1, R16_2, R18_2, R35_1, R47_2, R152_2, R157_1, R166_1, R167_1, R170_1, R174_2, R179_1, R180_1, R186_2, R196_2, R212_1, R213_1, R214_1, R220_1, R221_1, R222_1, R229_1, R233_1, R238_1, R239_1, R251_1, R253_1, R260_2, R262_1, R263_1, R267_1, R272_1, R275_1, R279_1, R281_1, R286_1, R288_2, R289_1, R290_1, R291_1, R292_1, R293_1, R294_1, R304_1, R307_1, R308_1, R309_1, R312_1, R316_1, R317_1, R357_2, R371_2, R374_2, R376_2, R378_2, R392_2, R394_2, R396_2, R398_2, R400_2, R404_2, R406_2, R409_2, R411_2, R428_2, R431_2, R440_2, R481_1, R590_1, R634_1, R635_1, R637_2, R638_2, R658_2, R659_2, R666_2, R672_2, R674_2, RN1_9, RN1_10, RN4_9, RN4_10, RN10_9, RN10_10, RN11_9, RN11_10, RN12_9, RN12_10, RN17_9, RN17_10, RN22_9, RN22_10, RN31_9, RN31_10, RN32_9, RN32_10, RN36_9, RN36_10, RN37_9, RN37_10, RN38_9, RN38_10, RN39_9, RN39_10, RN45_9, RN45_10, RN46_9, RN46_10, RN48_9, RN48_10, U4_14, U11_1, U11_20, U13_14, U14_1, U14_20, U30_1, U30_20, U38_14, U39_14, U40_14, U46_D6, U46_D11, U46_D16, U46_D21, U46_F4, U46_F23, U46_L4, U46_L23, U46_T4, U46_T23, U46_AA4, U46_AA23, U46_AC6, U46_AC11, U46_AC16, U46_AC21, U46_M4, U47_18, U47_26, U47_33, U47_53, U47_71, U47_78, U47_86, U47_105, U47_121, U47_130, U47_140, U47_156, U47_173, U47_183, U47_192, U47_208, U49_19, U56_14, U57_14, U58_14, U68_1, U68_10, U68_13, U68_14, U69_4, U69_11, U69_15, U69_20, U69_27, U69_41, U69_54, U69_61, U69_65, U69_70, U69_77, U69_87, U69_91, U69_93, U69_94, U69_95, U69_96, U69_97, U74_14, U79_7, U79_18, U79_1, U79_42, U80_12, U80_25, U80_37, U80_51, U80_63, U80_75, U80_80, U80_89, U80_100, U84_4, U84_11, U84_15, U84_20, U84_27, U84_41, 084_54, U84_61, U84_65, U84_70, U84_77, U84_87, U84_91, U84_93, U84_94, U84_95, U84_96, and U84_97.

Fault coverage class summary:

| | | | Unconnected | |
|---|---|---|---|---|
| | Nets | | Device Leads | |
| Class | Count | Percent | Count | Percent |
| 1 (fully covered) | 153 | 8.3 | 17 | 4.9 |
| 2 (partially covered) | 68 | 3.7 | 0 | 0.0 |
| 3 (shorts covered) | 386 | 20.9 | 60 | 17.2 |
| 4 (some opens covered) | 56 | 3.0 | 0 | 0.0 |
| 5 (not covered) | 1117 | 60.3 | 271 | 77.9 |
| 6 (covered by TAPIT) | 71 | 3.8 | 0 | 0.0 |
| Total | 1851 | 100.0 | 348 | 100.0 |

All tester pins on the following nets are unused by this test:

If there were tester pins on the following nets, this test would have used them:

The following device leads must be disabled (tristated) in order for the specified interconnect test to work:

U13_{—}6

The following logical constraints have been applied during this test:

LcExpect=X on net named BB2D0.

LcExpect=X on net named BB2D1.

LcExpect=X on net named BB2D10.

LcExpect=X on net named BB2D11.

LcExpect=X on net named BB2D12.

LcExpect=X on net named BB2D13.

LcExpect=X on net named BB2D14.

LcExpect=X on net named BB2D15.

LcExpect=X on net named BB2D2.

LcExpect=X on net named BB2D3.

LcExpect=X on net named BB2D4.

LcExpect=X on net named BB2D5.

LcExpect=X on net named BB2D6.

LcExpect=X on net named BB2D7.

LcExpect=X on net named BB2D8.

LcExpect=X on net named BB2D9.

LcExpect=X on net named EMU0.

LcExpect=X on net named EMU0_1088259.

LcExpect=X on net named EMU1_1088266.

LcExpect=X on net named EMU1.

LcExpect=X on net named GPIO4_1133876.

LcExpect=X on net named GPIO4.

LcExpect=X on net named PP1.

LcExpect=X on net named PP2.

LcExpect=X on net named PP3.

LcExpect=X on net named PP4.

LcExpect=X on net named PP5.

LcExpect=X on net named PP6.

LcExpect=X on net named PP7.

LcExpect=X on net named PF8.

LcExpect=X on net named PP39.

LcExpect=X on net named PP41.

LcExpect=X on net named PP43.

LcExpect=X on net named PP45.

LcExpect=X on net named PP47.

LcExpect=X on net named PP49.

LcExpect=X on net named PP51.

LcExpect=X on net named SEL_AB.

The following groups of boundary-scan outputs are always turned off:

Group including device leads U7_AC10, U7_AD9, U7_AF7, U7_AC9, and U7_AD8.

Reason(s):

U7_AC10 connected to the following active non-boundary-scan output(s): device lead U9_V16.

U7_AD9 connected to the following active non-boundary-scan output(s): device lead U9_T16.

U7_AF7 connected to the following active non-boundary-scan output(s): device lead U9_W17.

U7_AC9 connected to the following active non-boundary-scan output(s): device lead U9_V17.

U7_AD8 connected to the following active non-boundary-scan output(s): device lead U9_W18.

Group including device leads U7_AE15, U7_AC14, U7_AD14, U7_AC13, U7_AE12, U7_AD12, U7_AC12, U7_AE11, U7_AD11, U7_AE10, U7_AC11, U7_AF9, and U7_AE9.

Reason(s):

U7_AE15 connected to the following active non-boundary-scan output(s): device lead U9_V11.

U7_AC14 connected to the following active non-boundary-scan output(s): device lead U9_T11.

U7_AD14 connected to the following active non-boundary-scan output(s): device lead U9_W11.

U7_AC13 connected to the following active non-boundary-scan output(s): device lead U9_T12.

U7_AE12 connected to the following active non-boundary-scan output(s): device lead U9_V12.

U7_AD12 connected to the following active non-boundary-scan output(s): device lead U9_V13.

U7_AC12 connected to the following active non-boundary-scan output(s): device lead U9_T13.

U7_AE11 connected to the following active non-boundary-scan output(s): device lead U9_W13.

U7_AD11 connected to the following active non-boundary-scan output(s): device lead U9_T14.

U7_AE10 connected to the following active non-boundary-scan output(s): device lead U9_V14.

U7_AC11 connected to the following active non-boundary-scan output(s): device lead U9_V15.

U7_AF9 connected to the following active non-boundary-scan output(s): device lead U9_T15.

U7_AE9 connected to the following active non-boundary-scan output(s): device lead U9_W15.

Group including device leads U7_AF21, U7_AD19, U7_AC18, U7_AF20, U7_AD18, U7_AC17, U7_AE18, U7_AF18, U7_AC16, U7_AE17, U7_AD16, U7_AE16, U7_AC15, and U7_AD15.

Reason(s):

U7_AF21 connected to the following active non-boundary-scan output(s): device lead U9_V5.

U7_AD19 connected to the following active non-boundary-scan output(s): device lead U9_T6.

U7_AC18 connected to the following active non-boundary-scan output(s): device lead U9_V6.

U7_AF20 connected to the following active non-boundary-scan output(s): device lead U9_W6.

U7_AD18 connected to the following active non-boundary-scan output(s): device lead U9_T7.

U7_AC17 connected to the following active non-boundary-scan output(s): device lead U9_V7.

U7_AE18 connected to the following active non-boundary-scan output(s): device lead U9_W8.

U7_AF18 connected to the following active non-boundary-scan output(s): device lead U9_T8.

U7_AC16 connected to the following active non-boundary-scan output(s): device lead U9_V8.

U7_AE17 connected to the following active non-boundary-scan output(s): device lead U9_V9.

U7_AD16 connected to the following active non-boundary-scan output(s): device lead U9_T9.

U7_AE16 connected to the following active non-boundary-scan output(s): device lead U9_W10.

U7_AC15 connected to the following active non-boundary-scan output(s): device lead U9_T10.

U7_AD15 connected to the following active non-boundary-scan output(s): device lead U9_V10.

Group including device leads U7_K23, U7_J24, U7_H25, U7_G26, U7_J23, U7_G25, U7_F26, U7_H23, U7_G24, U7_F25, U7_E26, U7_F24, U7_E25, U7_B22, U7_D20, and U7_A22.

Reason(s):

U7_K23 connected to the following active non-boundary-scan output(s): device lead U9_G1.

U7_J24 connected to the following active non-boundary-scan output(s): device lead U9_G2.

U7_H25 connected to the following active non-boundary-scan output(s): device lead U9_G4.

U7_G26 connected to the following active non-boundary-scan output(s): device lead U9_E1.

U7_J23 connected to the following active non-boundary-scan output(s): device lead U9_F2.

U7_G25 connected to the following active non-boundary-scan output(s): device lead U9_F4.

U7_F26 connected to the following active non-boundary-scan output(s): device lead U9_D1.

U7_H23 connected to the following active non-boundary-scan output(s): device lead U9_E2.

U7_G24 connected to the following active non-boundary-scan output(s): device lead U9_E4.

U7_F25 connected to the following active non-boundary-scan output(s): device lead U9_D2.

U7_E26 connected to the following active non-boundary-scan output(s): device lead U9_B1.

U7_F24 connected to the following active non-boundary-scan output(s): device lead U9_B3.

U7_E25 connected to the following active non-boundary-scan output(s): device lead U9_C2.

U7_B22 connected to the following active non-boundary-scan output(s): device lead U9_A2.

U7_D20 connected to the following active non-boundary-scan output(s): device lead U9_A3.

U7_A22 connected to the following active non-boundary-scan output(s): device lead U9_D4.

Group including device leads U7_B21, U7_C20, U7_D19, U7_A21, U7_C19, U7_D18, U7_A20, U7_C18, U7_D17, U7_B18, U7_A18, U7_D16, U7_B17, U7_A17, U7_B16, and U7_D15.

Reason(s):

U7_B21 connected to the following active non-boundary-scan output(s): device lead U9_B4.

U7_C20 connected to the following active non-boundary-scan output(s): device lead U9_D5.

U7_D19 connected to the following active non-boundary-scan output(s): device lead U9_A4.

U7_A21 connected to the following active non-boundary-scan output(s): device lead U9_B5.

U7_C19 connected to the following active non-boundary-scan output(s): device lead U9_D6.

U7_D18 connected to the following active non-boundary-scan output(s): device lead U9_B6.

U7_A20 connected to the following active non-boundary-scan output(s): device lead U9_A6.

U7_Cl8 connected to the following active non-boundary-scan output(s): device lead U9_D7.

U7_D17 connected to the following active non-boundary-scan output(s): device lead U9_B7.

U7_B18 connected to the following active non-boundary-scan output(s): device lead U9_A8.

U7_A18 connected to the following active non-boundary-scan output(s): device lead U9_D8.

U7_D16 connected to the following active non-boundary-scan output(s): device lead U9_B8.

U7_B17 connected to the following active non-boundary-scan output(s): device lead U9_A9.

U7_A17 connected to the following active non-boundary-scan output(s): device lead U9_B9.

U7_B16 connected to the following active non-boundary-scan output(s): device lead U9_A10.

U7_D15 connected to the following active non-boundary-scan output(s): device lead U9_D10.

Group including device leads U7_C8, U7_A6, U7_D8, U7_C7, U7_D9, U7_D11, and U7_B6.

Reason(s):

U7_C8 connected to the following active non-boundary-scan output(s): device lead U9_D16.

U7_A6 connected to the following active non-boundary-scan output(s): device lead U9_A18.

U7_D8 connected to the following active non-boundary-scan output(s): device lead U9_B18.

U7_C7 connected to the following active non-boundary-scan output(s): device lead U9_D18.

U7_D1 connected to the following active non-boundary-scan output(s): device lead U9_B15.

Group including device leads U10_H4, U10_J4, U10_J2, U10_J5, U10_J6, U10_K6, U10_K5, and U10_L6.

Reason(s):

U10_H4 connected to the following active non-boundary-scan output(s): device lead U9_H4.

U10_J4 connected to the following active non-boundary-scan output(s): device lead U9_J4.

U10_J2 connected to the following active non-boundary-scan output(s): device lead U9_J2.

U10_J5 connected to the following active non-boundary-scan output(s): device lead U9_J5.

U10_J6 connected to the following active non-boundary-scan output(s): device lead U9_J6.

U10_K6 connected to the following active non-boundary-scan output(s): device lead U9_K6.

U10_K5 connected to the following active non-boundary-scan output(s): device lead U9_K5.

U10_L6 connected to the following active non-boundary-scan output(s): device lead U9_L6.

Group including device lead U80_53.

Reason(s):

U80_53 connected to the following active non-boundary-scan output(s): device lead U9_H4.

Group including device lead U80_55.

Reason(s):

U80_55 connected to the following active non-boundary-scan output(s): device lead U9_J4.

Group including device lead U80_57.

Reason(s):

U80_57 connected to the following active non-boundary-scan output(s): device lead U9_J2.

Group including device lead U80_61.

Reason(s):

U80_61 connected to the following active non-boundary-scan output(s): device lead U9_J5.

Group including device lead U80_65.

Reason(s):

U80_65 connected to the following active non-boundary-scan output(s): device lead U9_J6.

Group including device lead U80_68.

Reason(s):

U80_68 connected to the following active non-boundary-scan output(s): device lead U9_K6.

Group including device lead U80_70.

Reason(s):

U80_70 connected to the following active non-boundary-scan output(s): device lead U9_K5.

Group including device lead U80_59.

Reason(s):

U80_59 connected to the following active non-boundary-scan output(s): device lead U9_L6.

Group including device lead U10_F11.

Reason(s):

U10_F11 connected to the following active non-boundary-scan output(s): device lead U9_F11.

Group including device lead U10_E11.

Reason(s):

U10_E11 connected to the following active non-boundary-scan output(s): device lead U9_E11.

U10_E11 connected to the following two state boundary-scan output(s): device lead U46_AF22.

Group including device lead U10_B11.

Reason(s):

U10_B11 connected to the following active non-boundary-scan output(s): device lead U9_B1.

Group including device leads U10_A11, U10_D11, U10_E12, U10_{B12, U10}_A12, U10_D13, U10_F12, and U10_A13.

Reason(s):

U10_A11 connected to the following active non-boundary-scan output(s): device lead U9_A11.

U10_D11 connected to the following active non-boundary-scan output(s): device lead U9_D11.

U10_E12 connected to the following active non-boundary-scan output(s): device lead U9_E12.

U10_B12 connected to the following active non-boundary-scan output(s): device lead U9_B12.

U10_A12 connected to the following active non-boundary-scan output(s): device lead U9_A12.

U10_D13 connected to the following active non-boundary-scan output(s): device lead U9_D13.

U10_F12 connected to the following active non-boundary-scan output(s): device lead U9_F12.

U10_A13 connected to the following active non-boundary-scan output(s): device lead U9_A13.

Group including device leads U10_E14, U10_A14, U10_A15, U10_E15, and U10_D15.

Reason(s):

U10_A14 connected to the following active non-boundary-scan output(s): device lead U9_A14.

U10_A14 connected to the following two state boundary-scan output(s): device lead U46_AD21.

U10_A15 connected to the following active non-boundary-scan output(s): device lead U9_A15.

U10_A15 connected to the following two state boundary-scan output(s): device lead U46_AE23.

U10_E15 connected to the following active non-boundary-scan output(s): device lead U9_E15.

U10_E15 connected to the following two state boundary-scan output(s): device lead U46_AC22.

U10_D15 connected to the following active non-boundary-scan output(s): device lead U9_D15.

U10_D15 connected to the following two state boundary-scan output(s): device lead U46_AF23.

Group including device lead U10_A16.

Reason(s):

U10_A16 connected to the following active non-boundary-scan output(s): device lead U9_A16.

U10_A16 connected to the following two state boundary-scan output(s): device lead U46_V23.

Group including device lead U10_B17.

Reason(s):

U10_B17 connected to the following active non-boundary-scan output(s): device lead U9_B17.

U10_B17 connected to the following two state boundary-scan output(s): device lead U46_V26.

Group including device lead U10_A17.

Reason(s):

U10_A17 connected to the following active non-boundary-scan output(s): device lead U9_A17.

Group including device leads U10_G14, U10_G15, U10_G16, U10_G19, and U10_G13.

Reason(s):

U10_G15 connected to the following active non-boundary-scan output(s): device lead U9_G15.

U10_G15 connected to the following two state boundary-scan output(s): device lead U46_U25.

U10_G16 connected to the following active non-boundary-scan output(s): device lead U9_G16.

U10_G16 connected to the following two state boundary-scan output(s): device lead U46_U23.

U10_G19 connected to the following active non-boundary-scan output(s): device lead U9_G19.

U10_G19 connected to the following two state boundary-scan output(s): device lead U46_T25.

U10_G13 connected to the following active non-boundary-scan output(s): device lead U9_G13.

U10_G13 connected to the following two state boundary-scan output(s): device lead U46_U24.

Group including device leads U8_C8, U8_A6, U8_D8, U8_C7, U8_D9, U8_D11, and U8_B6.

Reason(s):

U8_C8 connected to the following two state boundary-scan output(s): device lead U10_D16.

U8_A6 connected to the following two state boundary-scan output(s): device lead U10_A18.

U8_D8 connected to the following two state boundary-scan output(s): device lead U10_B18.

U8_C7 connected to the following two state boundary-scan output(s): device lead U10_D18.

U8_D11 connected to the following two state boundary-scan output(s): device lead U10_B15.

Group including device lead U80_80.

Reason(s):

U80_80 drives a power net.

U80_80 drives a TAP net.

U80_80 connected to the following uncharacterized lead(s): device lead U46_M4.

Group including device lead U80_91.

Reason(s):

U80_91 connected to the following uncharacterized lead(s): device lead U10_P5.

Group including device lead U80_92.

Reason(s):

U80_92 connected to the following uncharacterized lead(s): device lead U9_P5.

Group including device lead U80_97.

Reason(s):

U80_97 connected to the following active non-boundary-scan output(s): device lead U9_L5.

Group including device lead U80_14.

Reason(s):

U80_14 connected to the following two state boundary-scan output(s): device lead U46_F25.

Group including device lead U80_15.

Reason(s):

U80_15 connected to the following two state boundary-scan output(s): device lead U10_G5.

Group including device lead U80_16.

Reason(s):

U80_16 connected to the following active non-boundary-scan output(s): device lead U9_G5.

Group including device lead U80_48.

Reason(s):

U80_48 connected to the following active non-boundary-scan output(s): device lead U13_3.

Group including device lead U80_21.

Reason(s):

U80_21 connected to the following active non-boundary-scan output(s): device lead U13_3.

Group including device lead U80_27.

Reason(s):

U80_27 connected to the following active non-boundary-scan output(s): device lead U13_3.

Group including device lead U80_34.

Reason(s):

U80_34 connected to the following active non-boundary-scan output(s): device lead U79_23.

Group including device lead U80_35.

Reason(s):

U80_35 connected to the following active non-boundary-scan output(s): device lead U79_22.

Group including device lead U80_39.

Reason(s):

U80_39 connected to the following active non-boundary-scan output(s): device lead U79_20.

Group including device lead U80_40.

Reason(s):

U80_40 connected to the following active non-boundary-scan output(s): device lead U79_19.

Group including device lead U80_41.

Reason(s):

U80_41 connected to the following active non-boundary-scan output(s): device lead U79_13.

Group including device lead U80_42.

Reason(s):

U80_42 connected to the following active non-boundary-scan output(s): device lead U79_12.

Group including device lead U80_43.

Reason(s):

U80_43 connected to the following active non-boundary-scan output(s): device lead U79_11.

Group including device lead U80_44.

Reason(s):

U80_44 connected to the following active non-boundary-scan output(s): device lead U79_9.

Group including device lead U80_45.

Reason(s):

U80_45 connected to the following active non-boundary-scan output(s): device lead U47_111.

Group including device lead U80_46.

Reason(s):

U80_46 connected to the following active non-boundary-scan output(s): device lead U47_114.

Group including device lead U80_47.

Reason(s):

U80_47 connected to the following active non-boundary-scan output(s): device lead U47_115.

Group including device lead U80_60.

Reason(s):

U80_60 connected to the following active non-boundary-scan output(s): device leads U47_87 and U74_4.

Group including device leads U46_C15, U46_B13, U46_D13, U46_A13, U46_C14, U46_B12, U46_C13, U46_A12, U46_B11, U46_C12, U46_A11, U46_D12, U46_B10, U46_C11, U46_A10, U46_D10, U46_B9, U46_C10, U46_A9, U46_B8, U46_A8, U46_C9, U46_B7, U46_D8, U46_A7, U46_C8, U46_B6, U46_D7, U46_A6, U46_C7, U46_B5, and U46_A5.

Reason(s):

U46_C15 connected to the following active non-boundary-scan output(s): device lead U84_29.

U46_B13 connected to the following active non-boundary-scan output(s): device lead U84_28.

U46_D13 connected to the following active non-boundary-scan output(s): device lead U84_25.

U46_A13 connected to the following active non-boundary-scan output(s): device lead U84_24.

U46_C14 connected to the following active non-boundary-scan output(s): device lead U84_23.

U46_B12 connected to the following active non-boundary-scan output(s): device lead U84_22.

U46_C13 connected to the following active non-boundary-scan output(s): device lead U84_19.

U46_A12 connected to the following active non-boundary-scan output(s): device lead U84_18.

U46_B11 connected to the following active non-boundary-scan output(s): device lead U84_13.

U46_C12 connected to the following active non-boundary-scan output(s): device lead U84_12.

U46_A11 connected to the following active non-boundary-scan output(s): device lead U84_9.

U46_D12 connected to the following active non-boundary-scan output(s): device lead U84_8.

U46_B10 connected to the following active non-boundary-scan output(s): device lead U84_7.

U46_C11 connected to the following active non-boundary-scan output(s): device lead U84_6.

U46_A10 connected to the following active non-boundary-scan output(s): device lead U84_3.

U46_D10 connected to the following active non-boundary-scan output(s): device lead U84_2.

U46_B9 connected to the following active non-boundary-scan output(s): device lead U84_79.

U46_C10 connected to the following active non-boundary-scan output(s): device lead U84_78.

U46_A9 connected to the following active non-boundary-scan output(s): device lead U84_75.

U46_B8 connected to the following active non-boundary-scan output(s): device lead U84_74.

U46_A8 connected to the following active non-boundary-scan output(s): device lead U84_73.

U46_C9 connected to the following active non-boundary-scan output(s): device lead U84_72.

U46_B7 connected to the following active non-boundary-scan output(s): device lead U84_69.

U46_D8 connected to the following active non-boundary-scan output(s): device lead U84_68.

U46_A7 connected to the following active non-boundary-scan output(s): device lead U84_63.

U46_C8 connected to the following active non-boundary-scan output(s): device lead U84_62.

U46_B6 connected to the following active non-boundary-scan output(s): device lead U84_59.

U46_D7 connected to the following active non-boundary-scan output(s): device lead U84_58.

U46_A6 connected to the following active non-boundary-scan output(s): device lead U84_57.

U46_C7 connected to the following active non-boundary-scan output(s): device lead U84_56.

U46_B5 connected to the following active non-boundary-scan output(s): device lead U84_53.

U46_A5 connected to the following active non-boundary-scan output(s): device lead U84_52.

Group including device leads U46_AD11, U46_AE13, U46_AC12, U46_AF13, U46_AD12, U46_AE14, U46_AC14, U46_AF 14, U46_AD13, U46_AE15, U46_AD14, U46_AF15, U46_AE16, U46_AD15, U46_AF16, U46_AC15, U46_AE17, U46_AD16, U46_AF17, U46_AC17, U46_AE18, U46_AD17, U46_AF18, U46_AE19, U46_AF19, U46_AD18, U46_AE20, U46_AC19, U46_AF20, U46_AD19, U46_AE21, and U46_AC20.

Reason(s):

U46_AD11 connected to the following active non-boundary-scan output(s): device lead U69_29.

U46_AE13 connected to the following active non-boundary-scan output(s): device lead U69_28.

U46_AC12 connected to the following active non-boundary-scan output(s): device lead U69_25.

U46_AF13 connected to the following active non-boundary-scan output(s): device lead U69_24.

U46_AD12 connected to the following active non-boundary-scan output(s): device lead U69_23.

U46_AE14 connected to the following active non-boundary-scan output(s): device lead U69_22.

U46_AC14 connected to the following active non-boundary-scan output(s): device lead U69_19.

U46_AF14 connected to the following active non-boundary-scan output(s): device lead U69_18.

U46_AD13 connected to the following active non-boundary-scan output(s): device lead U69_13.

U46_AE15 connected to the following active non-boundary-scan output(s): device lead U69_12.

U46_AD14 connected to the following active non-boundary-scan output(s): device lead U69_9.

U46_AF15 connected to the following active non-boundary-scan output(s): device lead U69_8.

U46_AE16 connected to the following active non-boundary-scan output(s): device lead U69_7.

U46_AD15 connected to the following active non-boundary-scan output(s): device lead U69_6.

U46_AF16 connected to the following active non-boundary-scan output(s): device lead U69_3.

U46_AC15 connected to the following active non-boundary-scan output(s): device lead U69_2.

U46_AE17 connected to the following active non-boundary-scan output(s): device lead U69_79.

U46_AD16 connected to the following active non-boundary-scan output(s): device lead U69_78.

U46_AF17 connected to the following active non-boundary-scan output(s): device lead U69_75.

U46_AC17 connected to the following active non-boundary-scan output(s): device lead U69_74.

U46_AE18 connected to the following active non-boundary-scan output(s): device lead U69_73.

U46_AD17 connected to the following active non-boundary-scan output(s): device lead U69_72.

U46_AF18 connected to the following active non-boundary-scan output(s): device lead U69_69.

U46_AE19 connected to the following active non-boundary-scan output(s): device lead U69_68.

U46_AF19 connected to the following active non-boundary-scan output(s): device lead U69_63.

U46_AD18 connected to the following active non-boundary-scan output(s): device lead U69_62.

U46_AE20 connected to the following active non-boundary-scan output(s): device lead U69_59.

U46_AC19 connected to the following active non-boundary-scan output(s): device lead U69_58.

U46_AF20 connected to the following active non-boundary-scan output(s): device lead U69_57.

U46_AD19 connected to the following active non-boundary-scan output(s): device lead U69_56.

U46_AE21 connected to the following active non-boundary-scan output(s): device lead U69_53.

U46_AC20 connected to the following active non-boundary-scan output(s): device lead U69_52.

It is understood that the above input file is only one example of a file that in-circuit test optimization generator 150 is adapted to receive.

In another embodiment, in-circuit test optimization generator program 150 is adapted to receive information about an electronic circuit board's net level fault coverage data from a test and/or on-board programming software program such as described in U.S. patent application Ser. No. 09/853,072 filed May 9, 2001 and titled, “Test and On-board Programming Station,” which is commonly assigned and incorporated by reference.

In one embodiment, all of inputs, 101-1 to 101-N and 105, to in-circuit test optimization generator 150 are organized and stored as links within an electronic circuit board setup file. The in-circuit test optimization generator program 150 extracts data from the input text files having several specific formats, for example:

Interconnect Test Fault Coverage Report (FCR) in the form of a vitg.rep file,

List of Power Nets (PN) in the form of a regular text file (PN file),

Full Board netlist in the form of a computer aided design (CAD) defined ASCII-type file (NET file), and

Full Board bill of materials (BOM) in the form of a CAD defined ASCII-type file (BOM file).

In this embodiment, any CAD defined ASCII-type file is acceptable. In one embodiment, the in-circuit test optimization generator program 150 uses a separate algorithm for each file type. The user specifies the paths of the input files when a new electronic circuit board setup file is created and can change them later. Input file paths in the form of links are saved within electronic circuit board setup files.

In one embodiment, in-circuit test optimization generator 150 derives output files from input files such as input from interconnect test generation software 105 and customer add-ins 101-1 to 101-N according to in-circuit test optimization algorithms. The output files are in the form of output netlists.

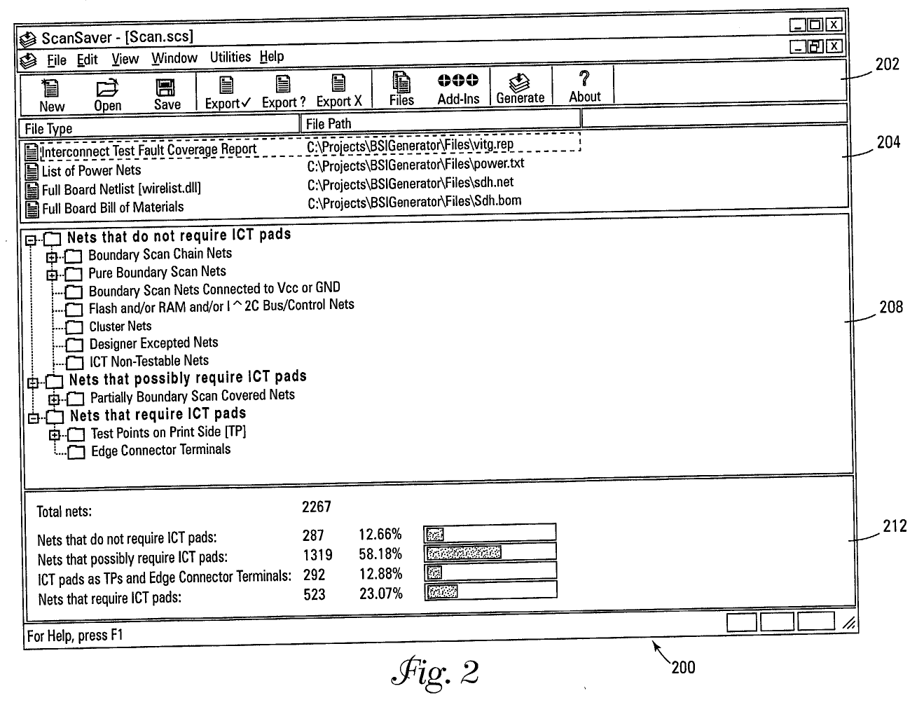

FIG. 2 is an illustration of a main screen for an in-circuit test optimization generator program such as 150 of FIG. 1, shown generally at 200 and constructed according to the teachings of the present invention. In this embodiment, main screen 200 is divided into four separate sub screens 202, 204, 208, and 212. Sub screen 202 is a user-friendly windows based menu or similar. Sub screen 204 lists input files for a specific electronic circuit board. Sub screen 208 reflects three classes of on-board nets that are derived by the in-circuit test optimization generator 150. Sub screen 212 lists the results of the in-circuit test optimization generator program 150 in one or more forms.

In this embodiment, sub screen 208 reflects three classes of on-board nets and these classes include nets that do not require in-circuit test pads, nets that possibly require in-circuit test pads, and nets that require in-circuit test pads. Each of these classes include subclasses, for example in this embodiment, the class of nets that require in-circuit test pads includes subclass Test Points on the print side of the electronic circuit board and Edge Connector through-hole terminals.

Sub screen 204 is one illustration of the files that are inputs to the optimized netlist generator 150 and are used to derive what nets do not require in-circuit test pads, what nets possibly require in-circuit test pads, and what nets require in-circuit test pads. In this embodiment, there are 4 input files in use that include Interconnect Test Fault Coverage Report (FCR), list of power nets (PN), full board netlist, and full board bill of materials (BOM). The FCR file (vitg.rep) is imported from a test generation software program such as Teradyne Victory boundary scan interconnect test generation software as the net level fault coverage report. This ASCII file is accessible from any Teradyne Victory based test generating software (such as Teradyne or ASSET InterTech test platforms). The full board netlist, BOM file and PN file are ASCII files that are accessible from any computer aided design (CAD) system.

In operation, the in-circuit test optimization generator program 150 reads the input files and stores the links for these files for further use. In one embodiment, inputs to the in-circuit test optimization generator program 150 are entered manually by utilizing the “New” option of menu sub screen 202. In one embodiment, inputs to the in-circuit test optimization generator 150 are entered automatically from the electronic circuit board setup file by utilizing the “Export” options of menu sub screen 202. In another embodiment, inputs to the in-circuit test optimization generator 150 are input both manually and automatically. The full path and names of these inputs are displayed in sub screen 204 of main screen 200. In addition to input files, the in-circuit test optimization generator 150 uses a variety of customer add-ins such as 101-1 to 101-N as discussed with respect to FIG. 1.

The results as displayed in sub screen 212 are regenerated by utilizing menu sub screen 202 “Generate” option. The results can be regenerated indefinitely. As a result, a designer will be able to easily manipulate trade-offs until a desired result is obtained.

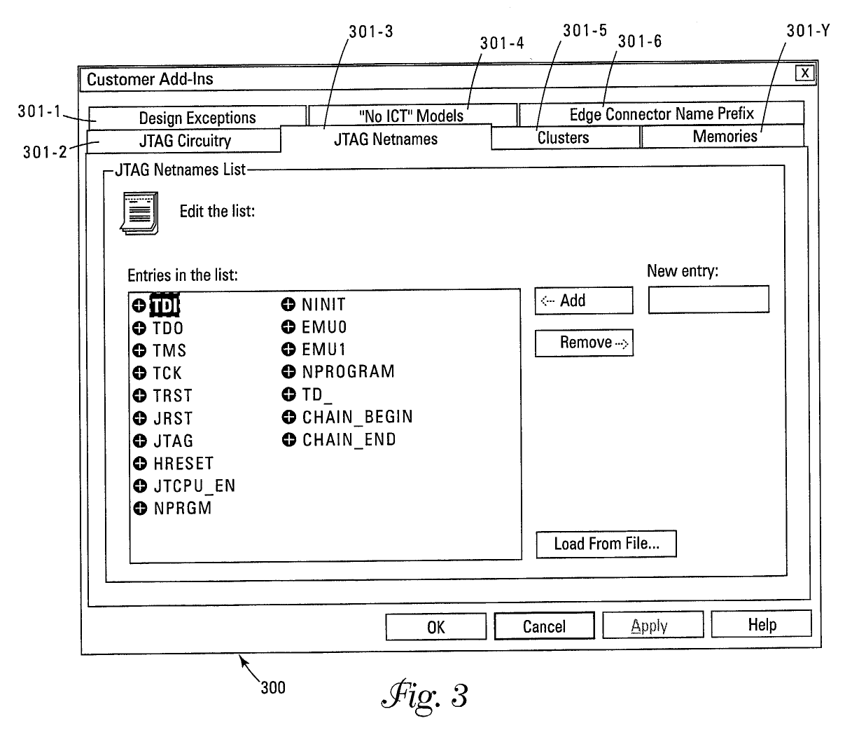

FIG. 3 is an illustration of a customer add-in screen, shown generally at 300, and constructed according to the teachings of the present invention. Screen 300 includes a number of user-inserted tabs 301-1 to 301-Y that represent specific customer add-ins. In order to optimize the number of in-circuit test pads on a specific electronic circuit board a user can modify and update the inputs to the in-circuit test optimization generator program 150 via customer add-ins screen 300. Screen 300 of FIG. 3 is activated by utilizing the “Add-Ins” option of menu sub screen 202.

Each of these user-inserted tabs 301-1 to 301-Y is a net name or device name that reflects one of restriction parameters of a processed board such as:

Design Exceptions: the board designer restriction net names (for example, CLK2, OSC5). There are designer restrictions in the form of no-probing netlist (see 101-N of FIG. 1) or/and HDIT restrictions in the form of no-vias netlist (see 101-4 of FIG. 1).

“No-ICT Models”: names of devices without in-circuit test models accessible (for example, U7). There are in-circuit test restrictions in form of list of no-probing devices (see 101-1 of FIG. 1).

JTAG Circuitry: non-boundary-scan device names used in the board boundary scan chain circuitry (for example, U1, U2)—see 101-3 of FIG. 1.

JTAG Netnames: net names of the board boundary scan environment (for example, TDI_15, TCK2)—see 101-3 of FIG. 1.

Clusters: names of non-boundary-scan devices that are tested in boundary scan cluster test (for example, U3, U4)—see 101-2 of FIG. 1.

Memories: names of memory devices that are tested in boundary scan memory test (for example, U5, U6)—see 101-2 of FIG. 1.

Edge Connector Name Prefix: prefixes of the board edge connector names (for example, J for J8 connector).

Each customer add-in entry can be loaded one-by-one by a user (schematics designer, test engineer, or the like) via a dialog menu or from an ASCII file as a list of add-ins, and stored in the board setup file for further processing. Each customer add-in entry can be edited and/or removed as desired by the user.

Once all the desired inputs (101-1 to 101-N and 105 of FIG. 1) are received, the in-circuit test optimization generator program 150 is executed by utilizing the “Generate” option of menu sub screen 202. In this embodiment, the results are displayed in sub screen 212 and in sub screen 208. The results are displayed in sub screen 212 as numerical and percentage data, as well as in the form of histograms. At the same time, the results are displayed in sub screen 208 as partial sub lists of each of a plurality of main output netlists. In this embodiment, there are three main output netlist files (see 208 of FIG. 2), as follows:

Nets that do not require in-circuit test pads, consists of:

List 1.1 Boundary Scan Chain nets (direct testing in Scan Path integrity test)

List 1.2 Pure Boundary Scan nets (direct testing in Interconnect test, Victory Sub-Class 1)

List 1.3 Boundary Scan Chain nets connected to Power nets (direct testing in Interconnect test, Victory Sub-Classes 2, 4)

List 1.4 Memory Device's nets (indirect testing in MemCon test, Flash Programming and I²C Programming processes)

List 1.5 Cluster nets (direct testing in Cluster test)

List 1.6 Designer Excepted Nets (no Structural Test coverage)

List 1.7 In-circuit test non-testable nets

Nets that possibly require in-circuit test pads, consists of:

List 2 Partially boundary scan covered nets (direct testing in Interconnect test, 100% shorts detection and partial opens detection, Victory Sub-Class 2)

Nets that require in-circuit test pads, including:

List 3.1 Test Points on the electronic circuit board print side (TP pads as in-circuit test pads)

List 3.2 Edge Connector Terminals (In-circuit test pads on connector through-hole terminals)

In one embodiment, the algorithm for in-circuit testing optimization generator 150 operates as follows.

1. For input NET and input bill of material (BOM) files include all Test Points for probing in List 3.1 (TP pads as ICT pads) and mark all N/A devices in input NET file. For each line of an input BOM file, if the entry has one of the following no-assembly properties “N/A” or “n/a” or “NOT ASSY” and if the entry is TP* then the <netname> is included with this entry from input NET file in List 3.1. If the entry is not TP* than mark all cases of this entry in input NET file. If the entry does not have one of the properties “N/A” or “n/a” or “NOT ASSY” then skip the line.

2. For input file vitg.rep, Section “Fault coverage class 1 nets (fully covered):” Include all Pure Boundary Scan Nets into List 1.2. For each line of input file vitg.rep that begins with “Net named <netname>”:

if “and” entry is found and only one Ux_y entry is found than skip the line;

if “and” entry is NOT found then skip the line;

otherwise include the <netname> in List 1.2.

3. For input NET files, input PN files, and input file vitg.rep, Section “Fault coverage class 4 nets (some opens covered):” Include all Partially (Boundary Scan (BS)+Non Boundary Scan (NBS), with pull-up/pull-down resistors) Boundary Scan Covered Nets into List 2. Include all Boundary Scan Nets connected to Vcc or GND into List 1.3. For each line of input file vitg.rep that begins with “Net named <netname>”:

if <netname> is found in the PN input file than skip the line;

if “No opens” entry is found than include the <netname> in List 2;

if all not-marked entries of the <netname> of input NET file are found here

{if all entries of this line of vitg.rep file are the only non-marked entries that are contained in corresponding <netname> line of input NET file }

than include the <netname> in List 1.3.

otherwise include the <netname> in List 2.

4. For input NET file and input file vitg.rep, section “Fault coverage class 2 nets (partially covered). Include all Boundary Scan Nets connected to Vcc or GND into List 1.3. Include all Flash/RAM/I²C Nets into List 1.4. Include all Cluster Nets into List 1.5. Include all Partially (BS+BS, NBS or BS+NBS, with or without pull-up/pull-down) Boundary Scan Covered Nets into List 2.

For each line of input file vitg.rep that begins with “Net named <netname>”:

if “pullup” or “pulldown” entry is found and “No opens” entries are not found; and

if all non-marked entries of the <netname> of input NET file are found here {if all entries of this line of vitg.rep file are the only non-marked entries that are contained in corresponding <netname> line of input NET file}

than include the <netname> in List 1.3;

if Memories list entry Ux is found in the line then for each Ux_* include the <netname> in List 1.4;

otherwise if Memories list entry Ux_y is found in the line include the <netname> in List 1.4;

if Clusters list entry Ux is found in the line then for each Ux_* include the <netname> in List 1.5;

otherwise if Clusters list entry Ux_y is found in the line than include the <netname> in List 1.5;

otherwise include the <netname> in List 2.

5. For input NET file and Output ICT.rep file mark part of the netlist entries that do not need in-circuit test pads. Include all Nets of Edge Connectors into List 3.2. Include all JTAG Circuitry Nets into List 1.1. Include all Designer Excepted Nets into List 1.6. Delete Nets with ALL entries marked. Insert Net Names in output in-circuit test netlist.

For each line beginning with [number] mark:

each entry Ux_* that is found in No_ICT_Models list as Ux; and

each entry that is found in format J*_* and NOT found in Edge Connector Name Prefix list.

For each line beginning with [number]:

if Edge Connector Name list entry is found in the line then include the <netname> in List 3.2;

if <netname> is found in JTAG Netnames list then include the <netname> in List 1. 1;

if JTAG Circuitry list entry Ux is found in the line then for each Ux_* include the <netname> in List 1.1;

otherwise if JTAG Circuitry list entry Ux_y is found in the line then include the <netname> in List 1.1;

if Design Exceptions list entry Ux is found in the line then for each Ux_* include the <netname> in List 1.6;

otherwise if Design Exceptions list entry Ux_y is found in the line then include the <netname> in List 1.6.

For each line beginning with [number] <name>:

if each entry is found as marked then delete the line; and

include the <name> in output ICT.rep file.

The total is the sum of <name>'s in the output ICT.rep file.

6. Scan thru all Lists 1.1-1.6, 2, 3.1-3.2 for a double net names search.

Delete the doubles in each list, search the doubles between lists:

if double found in List 3.2 and others than delete all except of List 3.2;

if double found in List 3.1 and others than delete all except of List 3.1;

if double found in Lists 1.* and List 2 than delete first in List 2:

if double found in Lists 1.* than delete all except of first found

7. Output ICT.rep file preparation.

For each line of the output ICT.rep file:

if <netname> is found in one of the following: Lists 1.1-1.6, 2 then delete the <netname> from output ICT.rep file.

Note: Suppress errors when trying to delete the <netname> that is deleted yet!

8. Count & Print diagram according to categories, for example:

| | Nets |
|---|---|
| Category | Count Percentage to Total |
| 1. Do not require ICT pads | (The summary of Lists 1.1-1.6) |
| 2. Possibly require ICT pads | (The summary of List 2) |
| 3. ICT pads as TPs and Edge | (The summary of Lists 3.1-3.2) |
| Connector Terminals | |
| 4. Nets that require ICT pads | (The summary of resulting ICT.rep |
| | file minus the summary of Category 3) |

Embodiments of the present invention provide a tool that aids in attaining the following trade-off goals:

acceptable number of in-circuit test pads based on the in-circuit test restrictions;

acceptable meeting of HDIT restrictions; and

acceptable fault coverage level for structural testing.

In order to optimize the number of in-circuit test pads on a specific electronic circuit board a user modifies and updates customer add-ins, such as 101-1 to 101-N, via a customer add-in screen such as screen 300 of FIG. 3. Utilizing the “Generate” option of menu sub screen 202 regenerates the results. Therefore, a designer is able to easily manipulate trade-offs until a desired result is obtained.

The Boundary Scan portion of structural testing fault coverage is defined in input vitg.rep file. As a result, additional fault coverage is achieved as in-circuit test trade-off fault coverage using the in-circuit test optimization generator program 150. In this embodiment, the fault coverage trade-offs are not quantified, but three classes of in-circuit test netlists are quantified—see 212 of FIG. 2.

Embodiments of the present invention are usable by a schematics engineer, a test engineer or the like, during structural test development, board design-for-testability (DFT) level estimation, board layout data preparation for layout editor, in-circuit test adapter data preparation for adaptor producing subcontractor and the like.

What is claimed is:

1. A method of generating optimized netlists, the method comprising:
providing an input mechanism that is adapted to receive selective test report files from one or more circuit board test generation software programs and in-circuit test restriction parameters;
generating netlists based on the received test report files and in-circuit test restriction parameters; and
wherein the netlists comprise one or more of total number of nets for the board, number of nets that do not require in-circuit test pads, number of nets that possibly require in-circuit test pads and number of nets that require in-circuit test pads.

2. The method of claim 1, wherein generating netlists based on the received test report files and in-circuit test restriction parameters comprises generating netlists based on the received test report files, in-circuit test restriction parameters and high-density interconnection technology restriction parameters.

3. The method of claim 1, wherein generating netlists based on the received test report files and in-circuit test restriction parameters comprises generating netlists based on the received test report files, in-circuit test restriction parameters and designer restriction parameters.

4. The method of claim 1, wherein generating netlists based on the received test report files and in-circuit test restriction parameters comprises generating netlists based on the received test report files, in-circuit test restriction parameters, high-density interconnection technology restriction parameters, and designer restriction parameters.

5. The method of claim 1, wherein the number of nets the require in-circuit test pads includes number of in-circuit test pads as test points and edge connector terminals.

6. The method of claim 1, wherein providing an input mechanism that is adapted to receive selective test report files from one or more circuit board test generation software programs comprises and providing an input mechanism that is adapted to receive selective test report files from one or more circuit board test generation software programs and board under test parameters.

7. A method of generating optimized netlists, the method comprising:
receiving a plurality of inputs, including customer add-ins and circuit board test generation software output data;
generating netlists based on the received plurality of inputs; and
wherein the netlists comprise one or more of total number of nets for the board, number of nets that do not require in-circuit test pads, number of nets that possibly require in-circuit test pads, and number of nets that require in-circuit test pads.

8. The method of claim 7, wherein the number of nets that require in-circuit test includes the number of in-circuit test pads as test points and edge connectors.

9. The method of claim 7, wherein receiving a plurality of inputs, including customer add-ins and circuit board test generation software output data comprises receiving a plurality of inputs, including customer add-ins and Teradyne Victory based software output files.

10. The method of claim 7, wherein receiving a plurality of inputs, including customer add-ins and circuit board test generation software output data, wherein customer add-ins include one or more of designer restrictions, high-density interconnection technology restrictions, and in-circuit test restrictions.

11. The method of claim 7, wherein receiving a plurality of inputs, including customer add-ins and circuit board test generation software output data comprises receiving a plurality of inputs, including customer add-ins and boundary scan test software data.

12. The method of claim 7, wherein receiving a plurality of inputs, including customer add-ins and circuit board test generation software output data comprises receiving a plurality of inputs, including customer add-ins, boundary scan test software data and board schematic data.

13. The method of claim 7, further comprising displaying a summary of one or more of the netlists numerically.

14. The method of claim 7, further comprising displaying a summary of one or more the netlists graphically.

15. The method of claim 7, further comprising regenerating netlists based on modifications to the customer add-ins.

16. An in-circuit test optimization generator for a specified circuit board, comprising:
a computer processing unit having an associated storage medium; and
a database, stored on the storage medium, including information on system parameters selectively used by a netlist generator program to generate netlists, the netlists include the total number of nets for a specified system, the number of nets that do not require in-circuit test pads and the number of nets that require in-circuit test pads.

17. The generator of claim 16, wherein the netlist report further includes the number of nets that possibly require in-circuit test pads.

18. The generator of claim 17, wherein the netlist report further includes the number of nets as test points and edge connector terminals.

19. The generator of claim 16, wherein a database, stored on the storage medium, including information on system parameters comprises a database, stored on the storage medium, including customer add-ins and test generation software data for an electronic circuit board.

20. The generator of claim 19, wherein the test generation software data includes Teradyne Victory based test software data.

21. The generator of claim 19, wherein the customer add-ins includes one or more of in-circuit test restrictions, designer restrictions, and high-density interconnection technology restrictions.

22. The generator of claim 21, wherein the customer add-ins further includes one or more of boundary scan test software data and circuit board schematic data.

23. An in-circuit test optimization generator comprising:
a computer processing unit having an associated storage medium;
a database, stored on the storage medium, the database including information on circuit board parameters selectively used by a netlist generator program to generate a netlist report;
wherein the database is adapted to receive test report files from one or more circuit board test generation programs; and
wherein the netlist report includes the total number of nets for a specified circuit board, the number of nets that do not require in-circuit test pads, and the number of nets that require in-circuit test pads.

24. The generator of claim 23, wherein the one or more circuit board test generation programs include Teradyne Victory based test software.

25. The generator of claim 23, wherein the netlist report further includes the number of nets that possibly require in-circuit test pads.

26. The generator of claim 23, wherein the netlist report further includes the number of nets as test points and edge connector terminals.

27. The generator of claim 23, wherein the database is further adapted to receive a plurality of customer add-ins.

28. The generator of claim 27, wherein the plurality of customer add-ins includes one or more of in-circuit test restriction parameters, designer restriction parameters, and high-density interconnection technology restriction parameters.

29. The generator of claim 27, wherein the plurality of customer add-ins includes one or more of boundary scan test software data and circuit board schematic data.

30. An in-circuit test optimization generator comprising:
a computer processing unit having an associated storage medium;
a database, stored on the storage medium, the database including information on circuit board parameters selectively used a netlist generator program to generate a netlist report;
wherein the database is adapted to receive circuit board restrictions;
wherein the circuit board restrictions include one or more of in-circuit test restrictions, designer restrictions and high-density interconnection technology restrictions; and
wherein the netlist report includes the total number of nets for a specified circuit boards, the number of nets that do not require in-circuit test pads, and the number of nets that require in-circuit test pads.

31. The generator of claim 30, wherein the netlist report further includes the number of nets that possibly require in-circuit test pads.

32. The generator of claim 31, wherein the netlist report further includes the number of nets as test points and edge connector terminals.
